(19) United States
(12) Patent Application Publication
(10) Pub. No.: US 2026/0123177 A1
(43) Pub. Date: Apr. 30, 2026

(54) POLYCYCLIC COMPOUND, LIGHT-EMITTING DEVICE INCLUDING THE POLYCYCLIC COMPOUND, ELECTRONIC DEVICE INCLUDING THE LIGHT-EMITTING DEVICE, AND ELECTRONIC APPARATUS INCLUDING THE LIGHT-EMITTING DEVICE

(71) Applicant: Samsung Display Co., Ltd., Yongin-si (KR)

(72) Inventors: Se Ran KIM, Yongin-si (KR); Hyeon Deuk KIM, Yongin-si (KR); Hoi Lim KIM, Yongin-si (KR); Jun Ha PARK, Yongin-si (KR); Seung In BAEK, Yongin-si (KR); Dong Sun YOO, Yongin-si (KR); Seok Gyu YOON, Yongin-si (KR)

(21) Appl. No.: 19/231,675

(22) Filed: Jun. 9, 2025

(30) Foreign Application Priority Data
Oct. 31, 2024 (KR) 10-2024-0151690

(51) Int. Cl. H10K 50/19; C07F 5/02; H10K 50/12; H10K 85/60; H10K 101/20

(52) U.S. Cl. CPC H10K 50/19; C07F 5/027; H10K 50/12; H10K 85/626; H10K 85/633; H10K 85/636; H10K 85/654; H10K 85/6572; H10K 85/6574; H10K 85/6576; H10K 85/658; H10K 2101/20

(57) ABSTRACT

A polycyclic compound, a light-emitting device that includes the polycyclic compound, an electronic device that includes the light-emitting device, and an electronic apparatus that includes the light-emitting device are disclosed. The light-emitting device may include a first electrode, a second electrode, and an emission layer between the first electrode and the second electrode. The emission layer may include a polycyclic compound represented by Chemical Formula 1.

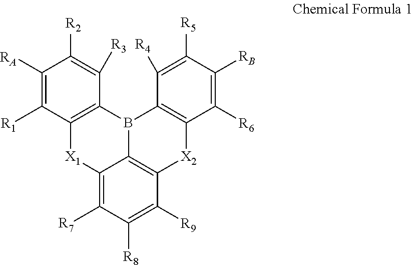

### CROSS-REFERENCE TO RELATED APPLICATION

The present application claims priority to and the benefit of Korean Patent Application No. 10-2024-0151690, filed on Oct. 31, 2024, in the Korean Intellectual Property Office, the entire disclosure of which is incorporated herein by reference.

### BACKGROUND

### 1. Field

One or more embodiments of the present application relate to a polycyclic compound, a light-emitting device including the polycyclic compound, an electronic device including the light-emitting device, and an electronic apparatus including the light-emitting device.

### 2. Description of the Related Art

Organic light-emitting devices have a self-luminous property and may provide improved or enhanced viewing angle and contrast properties. Also, a high response speed and a high luminance may be provided.

The organic light-emitting devices may include an emission layer between a first electrode and a second electrode. A hole transferred from the first electrode and an electron transferred from the second electrode may be recombined in the emission layer to generate an exciton. Light emission properties are implemented as the exciton is shifted from an excited state to a ground state.

The emission layer may include a host material and a dopant material to implement the light emitting mechanism.

### SUMMARY

One or more aspects of embodiments of the present disclosure are directed toward a polycyclic compound having improved or enhanced oxidation stability and/or color purity.

One or more aspects of embodiments of the present disclosure are directed toward a light-emitting device having improved or enhanced light-emitting property and/or life-span property.

One or more aspects of embodiments of the present disclosure are directed toward an electronic device including the light-emitting device.

One or more aspects of embodiments of the present disclosure are directed toward an electronic apparatus including the light-emitting device.

One or more aspects of embodiments of the present disclosure are directed toward a polycyclic compound including a carbazole group introduced into an aromatic ring of a core structure including boron and having enhanced poly-resonance effect. An alicyclic hydrocarbon ring group may be condensed into at least one of the benzene rings fused to both sides of a nitrogen-containing ring of the carbazole group of the polycyclic compound, thereby providing improved or enhanced luminous efficiency and life-span properties.

Additional aspects of embodiments will be set forth in part in the description which follows and, in part, will be apparent from the description or may be learned by practice of the presented embodiments of the disclosure.

A polycyclic compound may be represented by Chemical Formula 1.

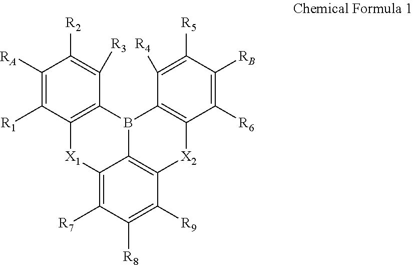

In Chemical Formula 1, X₁ and X₂ are each independently N(R₁₀), S, O, or Se, R₁ to R₁₀ are each independently hydrogen, deuterium, a hydroxyl group, a cyano group, —F, —Cl, —Br, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₆-C₆₀ arylalkyl group, a substituted or unsubstituted C₂-C₆₀ heteroaryl group, a substituted or unsubstituted C₂-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. Two or more adjacent groups selected from among R₁ to R₉ are optionally combined with each other to form a saturated ring or an unsaturated ring. RA and RB are the same as or different from each other and are each independently a substituted or unsubstituted carbazole group, and at least one selected from RA and RB is selected from the group consisting of carbazole groups having a structure in which an alicyclic hydrocarbon ring group is condensed to one or two of two six-membered benzene rings fused at both sides of one five-membered nitrogen-containing ring of the carbazole group.

In one or more embodiments, the alicyclic hydrocarbon ring may be selected from among a 5-membered ring to a 9-membered ring.

In one or more embodiments, the alicyclic hydrocarbon ring group may be selected from among a substituted or unsubstituted cycloalkane, a substituted or unsubstituted bicycloalkane, and a substituted or unsubstituted spiroalkane.

In one or more embodiments, RA may be represented by Chemical Formula 2-1, and RB may be represented by Chemical Formula 2-2.

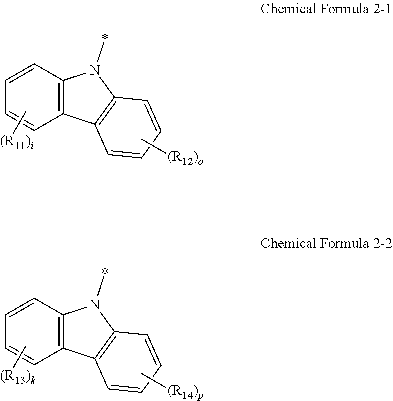

In Chemical Formulae 2-1 and 2-2, R₁₁ to R₁₄ may be the same as or different from each other and may each independently be hydrogen, deuterium, —F, —Cl, —Br, —CD₃, —CD₂H, —CDH₂, —CF₃, —CF₂H, —CFH₂, a substituted or unsubstituted C₁-C₆₀ alkyl group, a substituted or unsubstituted C₃-C₆₀ cycloalkyl group, a substituted or unsubstituted C₆-C₆₀ arylalkyl group, a substituted or unsubstituted C₂-C₆₀ heteroarylalkyl group, or a substituted or unsubstituted silyl group, and i, o, k, and p may each independently be an integer of 0 to 4. Two or more adjacent R₁₁ may optionally be combined with each other to form an alicyclic hydrocarbon ring group, two or more adjacent R₁₂ may optionally be combined with each other to form an alicyclic hydrocarbon ring group, two or more adjacent R₁₃ may optionally be combined with each other to form an alicyclic hydrocarbon ring group, and two or more adjacent R₁₄ may optionally be combined with each other to form an alicyclic hydrocarbon ring group. R_{A} may include at least one selected from the alicyclic hydrocarbon ring group formed by two or more R₁₁ and the alicyclic hydrocarbon ring group formed by two or more R₁₂; R_{B} may include at least one selected from the alicyclic hydrocarbon ring group formed by two or more R₁₃ and the alicyclic hydrocarbon ring group formed by two or more R₁₄; or R_{A} may include at least one selected from the alicyclic hydrocarbon ring group formed by two or more R₁₁ and the alicyclic hydrocarbon ring group formed by two or more R₁₂, and R_{B} may include at least one selected from the alicyclic hydrocarbon ring group formed by two or more R₁₃ and the alicyclic hydrocarbon ring group formed by two or more R₁₄.

In one or more embodiments, at least one selected from among the alicyclic hydrocarbon ring group formed by two or more R₁₁, the alicyclic hydrocarbon ring group formed by two or more R₁₂, the alicyclic hydrocarbon ring group formed by two or more R₁₃, and the alicyclic hydrocarbon ring group formed by two or more R₁₄ may be selected from among a substituted or unsubstituted C₄-C₉ cycloalkane, a substituted or unsubstituted C₅-C₃₀ bicycloalkane, and a substituted or unsubstituted C₈-C₃₀ spiroalkane.

In one or more embodiments, at least one selected from among the alicyclic hydrocarbon ring group formed by two or more R₁₁, the alicyclic hydrocarbon ring group formed by two or more R₁₂, the alicyclic hydrocarbon ring group formed by two or more R₁₃, and the alicyclic hydrocarbon ring group formed by two or more R₁₄ may be selected from the group consisting of a substituted or unsubstituted cyclopentane, a substituted or unsubstituted cyclohexane, a substituted or unsubstituted cycloheptane, a substituted or unsubstituted bicyclo[2.1.0]pentane, a substituted or unsubstituted bicyclo[2.2.0]hexane, a substituted or unsubstituted bicyclo[4.1.0]heptane, a substituted or unsubstituted spiro[5.5]undecane, a substituted or unsubstituted spiro[4.4]nonane, a substituted or unsubstituted spiro[3.4]octane, a substituted or unsubstituted spiro[4.5]decane, and a substituted or unsubstituted spiro[6.6]tridecane.

In one or more embodiments, R_{A} and R_{B} may be the same as or different from each other and may each independently be represented by one selected from among Chemical Formulae 3-1 to 3-6.

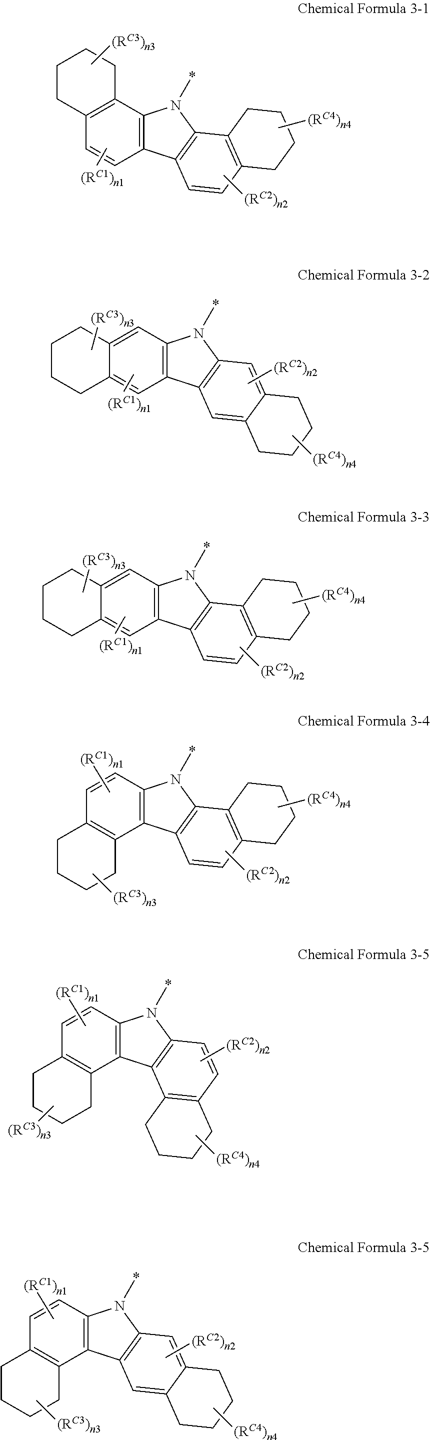

In Chemical Formulae 3-1 to 3-6, R^{c1} and R^{c2} may be the same as or different from each other and may each independently be hydrogen, deuterium, —F, —Cl, —Br, —CD₃, —CD₂H, —CDH₂, —CF₃, —CF₂H, —CFH₂, a substituted or unsubstituted C₁-C₃₀ alkyl group, or a substituted or unsubstituted C₃-C₃₀ cycloalkyl group. R^{c3} and R^{c4} may be the same as or different from each other and may each independently be hydrogen, deuterium, —CD₃, —CD₂H, —CDH₂, a substituted or unsubstituted C₁-C₃₀ alkyl group, or a substituted or unsubstituted C₃-C₃₀ cycloalkyl group. n1 and n2 may be the same as or different from each other and may each independently be an integer of 0 to 2. n3 and n4 may be the same as or different from each other and may each independently be an integer of 0 to 8. Two or more adjacent R^{c3} may optionally be combined with each other to form a saturated ring, and two or more adjacent R^{c4} may optionally be combined with each other to form a saturated ring.

In one or more embodiments, R_{A} and R_{B} may be the same as or different from each other and may each independently be represented by one selected from the Chemical Formulae 3-2 and 3-3.

In one or more embodiments, the polycyclic compound represented by Chemical Formula 1 may be represented by one selected from among Chemical Formulae 1-1 to 1-6.

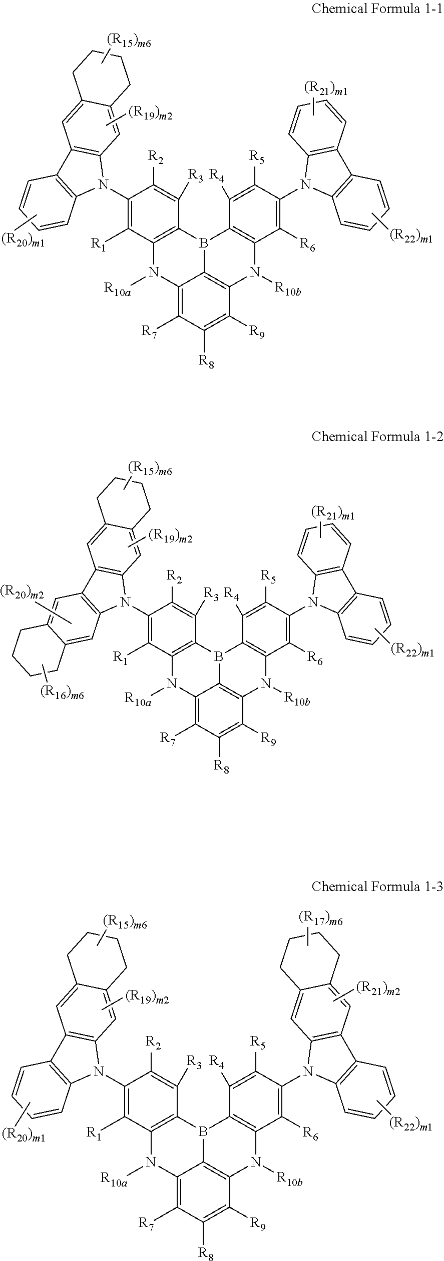

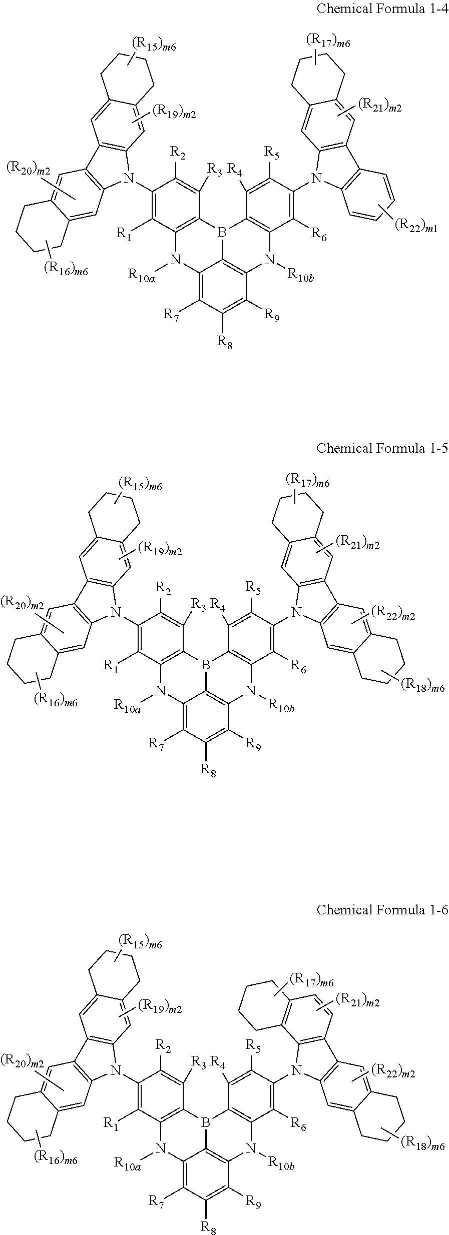

In Chemical Formulae 1-1 to 1-6, R₁ to R₉, R₁₀ₐ, and R_{10b} may each independently be hydrogen, deuterium, a hydroxyl group, a cyano group, —F, —Cl, —Br, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₆-C₆₀ arylalkyl group, a substituted or unsubstituted C₂-C₆₀ heteroaryl group, a substituted or unsubstituted C₂-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. Two or more adjacent groups selected from among R₁ to R₉ may optionally be combined with each other to form a saturated ring or an unsaturated ring. R₁₅ to R₁₈ may be the same as or different from each other and may each independently be hydrogen, deuterium, —CD₃, —CD₂H, —CDH₂, a substituted or unsubstituted C₁-C₃₀ alkyl group, or a substituted or unsubstituted C₃-C₃₀ cycloalkyl group. R₁₉ to R₂₂ may be the same as or different from each other and may each independently be hydrogen, deuterium, —F, —Cl, —Br, —CD₃, —CD₂H, —CDH₂, a substituted or unsubstituted C₁-C₃₀ alkyl group, or a substituted or unsubstituted C₃-C₃₀ cycloalkyl group. A plurality of m1 may each independently be an integer of 0 to 4, a plurality of m2 may each independently be an integer of 0 to 2, and a plurality of m6 may each independently be an integer of 0 to 8. Two or more adjacent R₁₅ may optionally be combined with each other to form a saturated ring, two or more adjacent R₁₆ may optionally be combined with each other to form a saturated ring, two or more adjacent R₁₇ may optionally be combined with each other to form a saturated ring, and two or more adjacent R₁₈ may optionally be combined with each other to form a saturated ring.

In one or more embodiments, the polycyclic compound may be represented by one selected from the Chemical Formulae 1-5 and 1-6.

In one or more embodiments, R₁₀ₐ and R_{10b} may each independently be represented by one selected from among Chemical Formulae 4-1 to 4-12.

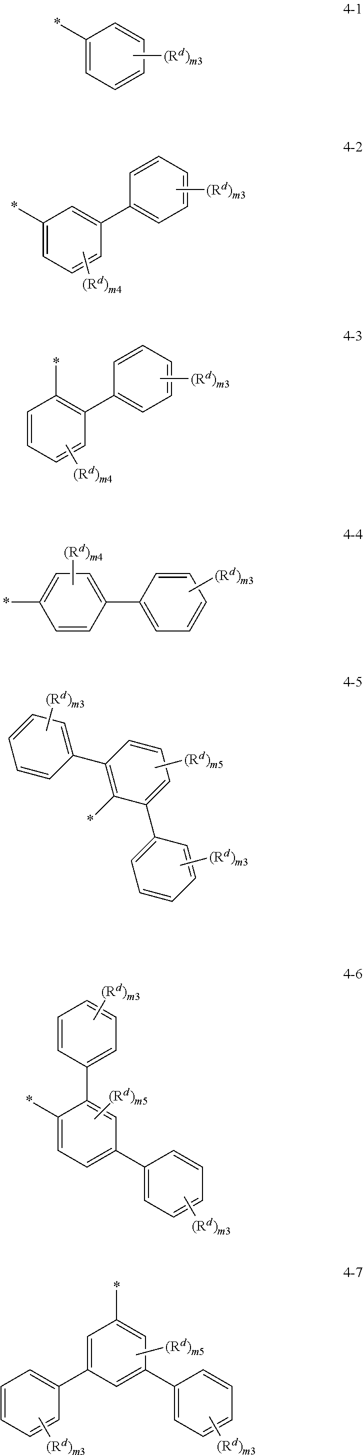

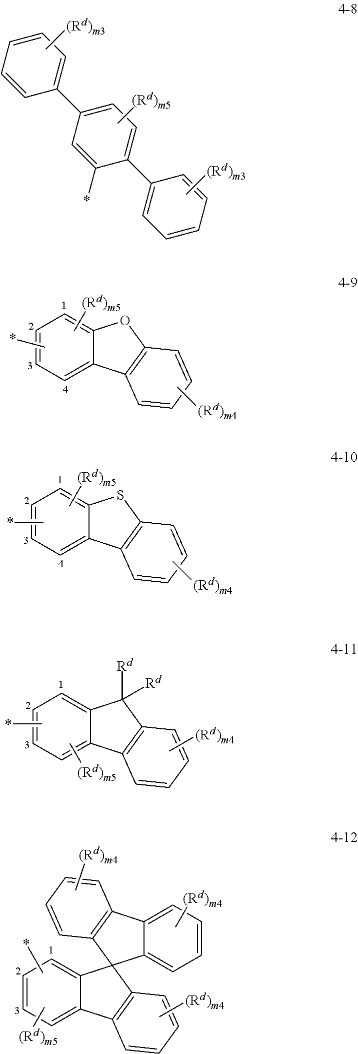

In Chemical Formulae 4-1 to 4-12, a plurality of m3 may be the same as or different from each other and may each independently be an integer of 0 to 5, a plurality of m4 may be the same as or different from each other and may each independently be an integer of 0 to 4, and a plurality of m5 may be the same as or different from each other and may each independently be an integer of 0 to 3. A single R^{d} may be or two or more of R^{d} being the same as or different from each other may each independently be hydrogen, deuterium, —CD₃, —CD₂H, —CDH₂, —CN, a substituted or unsubstituted C₁-C₁₀ alkyl group, a substituted or unsubstituted C₂-C₁₀ alkenyl group, a substituted or unsubstituted C₃-C₁₀ cycloalkyl group, or a substituted or unsubstituted C₆-C₁₀ aryl group. If (e.g., when) a plurality of R^{d} is included, two adjacent ones selected from among the plurality of R^{d} may optionally be combined with each other to form a saturated or unsaturated ring, and *- binding site in Chemical Formulae 4-9 to 4-11 may be one selected from among carbons designated as the numbers of 1 to 4, and *- binding site in Chemical Formula 4-12 may be one selected from among carbons designated as the numbers of 1 to 3.

In one or more embodiments, K_{RISC} of the polycyclic compound may be about 1.00×10⁵ s⁻¹ or more.

In one or more embodiments, an oscillator intensity (f) of the polycyclic compound may be about 0.36 or greater, and ΔE_{ST} of the polycyclic compound may be about 0.39 eV or less.

A light-emitting device may include a first electrode, a second electrode; and an emission layer between the first electrode and the second electrode. The emission layer may include a polycyclic compound represented by Chemical Formula 1 as described in one or more embodiments.

In one or more embodiments, the light-emitting device may further include a charge generation layer between the first electrode and the second electrode. The emission layer may further include a plurality of emission layers, and the charge generation layer may be between adjacent emission layers. At least one selected from among the plurality of emission layers may include the polycyclic compound of Chemical Formula 1.

In one or more embodiments, the polycyclic compound may be included as a thermally activated delayed fluorescence (TADF) dopant, a host for a phosphorescent device, or a fluorescent host.

In one or more embodiments, the emission layer may have a maximum emission wavelength in a range from about 440 nm to about 490 nm.

In one or more embodiments, R_{A} may be represented by Chemical Formula 2-1 as described in one or more embodiments, and R_{B} may be represented by Chemical Formula 2-2 as described in one or more embodiments.

An electronic device may include the light-emitting device as described in one or more embodiments.

An electronic apparatus may include the light-emitting device as described in one or more embodiments. The electronic apparatus may be one selected from among a flat panel display, a curved display, a computer monitor, a medical monitor, a television, a billboard, a light for indoor lighting, a light for outdoor lighting, a light for signals, a head-up display, a fully transparent display, a partially transparent display, a flexible display, a rollable display, a foldable display, a stretchable display, a laser printer, a phone, a mobile phone, a tablet, a phablet, a personal information terminal (e.g., personal digital assistant (PDA)), a wearable device, a laptop computer, a digital camera, a camcorder, a viewfinder, a micro display, a 3D display, a virtual reality display, an augmented reality display, a vehicle, a video wall including two or more displays tiled together, a theater screen, a stadium screen, a phototherapy device, and a signboard.

The polycyclic compound according to one or more embodiments of the present disclosure may provide improved or enhanced oxidation stability and color purity.

The light-emitting device including the polycyclic compound, an electronic device including the light-emitting device, and an electronic apparatus including the light-emitting device may have improved or enhanced light-emitting and life-span properties.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1 to 6 are schematic cross-sectional views illustrating light-emitting devices according to one or more embodiments.

FIG. 7 is a schematic cross-sectional view illustrating a display device according to one or more embodiments.

FIG. 8 is a schematic cross-sectional view illustrating a display device according to one or more embodiments.

FIG. 9 is a schematic cross-sectional view illustrating a stack construction of light-emitting structure in a display device according to one or more embodiments.

FIG. 10 is a schematic cross-sectional view illustrating a display device according to one or more embodiments.

FIG. 11 is a schematic cross-sectional view illustrating a display device according to one or more embodiments.

FIG. 12 is a block diagram of an electronic device according to one or more embodiments.

FIG. 13 is a view of electronic devices according to one or more embodiments.

FIG. 14 is a schematic exploded perspective view illustrating an electronic device according to one or more embodiments.

FIG. 15 is a view illustrating a vehicle in which electronic devices according to one or more embodiments are provided.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the specification.

It will also be understood that if (e.g., when) an element or a layer is referred to as being “on” another element or layer, it may be directly on the other element or layer, or intervening elements or layers may also be present therebetween. In contrast, if (e.g., when) an element or a layer is referred to as being “directly on” another element or layer, there may be no intervening elements or layers present therebetween.

The same reference numbers indicate substantially the same components throughout the specification.

It will be understood that, although the terms “first,” “second,” and/or the like may be used herein to describe one or more suitable elements, these elements should not be limited by these terms. These terms are only used to distinguish one element from another element. For instance, a first element discussed in one or more embodiments may be termed a second element without departing from the spirit and scope of the present disclosure. Similarly, the second element may also be termed the first element.

The terminology used herein is for the purpose of describing particular embodiments only and is not intended to be limiting.

As used herein, “a”, “an,” “the,” and “at least one” do not denote a limitation of quantity and are intended to include both the singular and the plural, unless the context clearly indicates otherwise. For example, “an element” has substantially the same meaning as “at least one element,” unless the context clearly indicates otherwise. “At least one” is not to be construed as limiting “a” or “an.”

“Or” refers “and/or.” As used herein, the term “and/or” includes any and all combinations of one or more of the associated listed items.

It will be further understood that the terms “has” and/or “having,” or “includes” and/or “including” if (e.g., when) used in this specification, specify the presence of stated features, regions, integers, steps, operations, elements, and/or components, but do not preclude the presence or addition of one or more other features, regions, integers, steps, operations, elements, components, and/or groups thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Furthermore, relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if (e.g., when) the device in one of the drawings is turned over, elements described as being on the “lower” side of other elements may then be oriented on “upper” sides of the other elements. The term “lower,” may therefore, encompasses both an orientation of “lower” and “upper,” depending on the particular orientation of the drawing. Similarly, if (e.g., when) the device in one of the drawings is turned over, elements described as “below” or “beneath” other elements may then be oriented “above” the other elements. The term “below” or “beneath” may, therefore, encompass both an orientation of above and below.

Features of each of one or more embodiments of the present disclosure may be partially or entirely combined with each other and may technically suitably interwork with each other, and respective embodiments may be implemented independently of each other or may be implemented together in association with each other.

“About” or “approximately” as used herein is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations or within ±30%, 20%, 10%, or ±5% of the stated value.

### Definition of Terminology

In the present disclosure, the term “substituted or unsubstituted” may refer to being substituted or unsubstituted by one or more substituent selected from the group consisting of, for example, a deuterium atom, a halogen atom, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group (e.g., a C₁-C₆₀ alkyl group, a C₁-C₁₀ alkyl group, and/or the like), an alkenyl group (e.g., a C₂-C₆₀ alkenyl group, a C₂-C₁₀ alkenyl group, and/or the like), an alkynyl group (e.g., a C₂-C₆₀ alkynyl group, a C₂-C₁₀ alkynyl group, and/or the like), an alkoxy group (e.g., a C₁-C₆₀ alkoxy group, a C₁-C₁₀ alkoxy group, and/or the like), a hydrocarbon ring group, an aryl group (e.g., a C₆-C₆₀ aryl group and/or the like), and a heterocyclic group (e.g., a C₁-C₆₀ heterocyclic group and/or the like). For example, the term “substituted alkyl group” may refer to a group in which at least one selected from among hydrogen atoms of the alkyl group is substituted with the substituent as described in one or more embodiments, and thus the substituent may be further bonded to a carbon atom of the alkyl group.

The substituent may include a combination of substituents selected from among the groups as described in one or more embodiments. For example, at least one hydrogen atom in the alkyl group, the aryl group, and/or the like included as a substituent may be substituted with a deuterium atom, a halogen atom, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group, an alkenyl group, an alkynyl group, a hydrocarbon ring group, an aryl group, a heterocyclic group, or a combination thereof.

In the substituents as described in one or more embodiments, a multivalent substituent, such as an amino group, a phosphine sulfide group, a phosphine oxide group, a sulfinyl group, a sulfonyl group, an oxy group, a carbonyl group, an ester group, and/or the like, may each independently be substituted with a C₁-C₁₀ alkyl group, a C₂-C₁₀ alkenyl group, a C₁-C₁₀ alkynyl group, or a C₆-C₁₀ aryl group.

In the present disclosure, in the term “substituted or unsubstituted Cₐ-C_{b} Y group,” the range of a to b refers to the number of carbon atoms in an unsubstituted Y group and may not include the number of carbon atoms of a substituent.

In the present disclosure, an alkyl group may be a monovalent hydrocarbon group in which one hydrogen atom is removed from a linear or branched hydrocarbon group. Examples of an alkyl group may include a methyl group, an ethyl group, a propyl group, a sec-butyl group, a tert-butyl group, an iso-butyl group, a pentyl group, a neopentyl group, a 2-ethyl butyl group, a 3,3-dimethyl butyl group, a hexyl group, a heptyl group, an octyl group, and/or the like.

In the present disclosure, an alkylene group may be a divalent hydrocarbon group in which two hydrogen atoms are removed from a linear or branched hydrocarbon group.

In the present disclosure, an alkenyl group may have substantially the same skeleton as that of an alkyl group and may be a monovalent hydrocarbon group that includes at least one carbon-carbon double bond. In the present disclosure, an alkenylene group may be a divalent hydrocarbon group in which one hydrogen atom is further removed from an alkenyl group.

In the present disclosure, an alkynyl group may have substantially the same skeleton as that of an alkyl group and may be a monovalent hydrocarbon group that includes at least one carbon-carbon triple bond. In the present disclosure, an alkynylene group may be a divalent hydrocarbon group in which one hydrogen atom is further removed from an alkynyl group.

In the present disclosure, an aryl group may be a monovalent hydrocarbon group in which one hydrogen atom is removed from a hydrocarbon group having an aromatic structure. The definition of an aryl group may also encompass a group in which two or more aromatic rings are directly connected, such as a biphenyl group. Examples of an aryl group may include, for example, a phenyl group, a naphthyl group, an anthracenyl group, a phenanthrenyl group, a pyrenyl group, a fluorenyl group, a tetracenyl group, a biphenyl group, a terphenyl group, a quaterphenyl group, a chrysenyl group, and/or the like.

In the present disclosure, a group in which two or more aryl rings are condensed to each other or linked to each other by an alicyclic hydrocarbon ring group, such as a fluorenyl group, may be encompassed in the definition of an aryl group.

For example, a biphenyl group may be interpreted as an aryl group or may be interpreted as a phenyl group that is substituted with a phenyl group.

In the present disclosure, an arylene group may be a divalent hydrocarbon group in which two hydrogen atoms are removed from an aryl group.

In the present disclosure, a heteroaryl group may be a monovalent group having an aromatic structure that includes at least one heteroatom, such as B, O, P, S, and Si, as a ring-forming atom. In the present disclosure, a heteroarylene group may be a divalent group having an aromatic structure that includes at least one heteroatom, such as B, O, P, S, and Si, as a ring-forming atom. If (e.g., when) a heteroaryl group or a heteroarylene group includes two or more heteroatoms, the two or more heteroatoms may be the same as or different from each other.

In the present disclosure, a group in which two or more aryl rings are condensed or linked to a non-aromatic heterocyclic ring, such as a carbazole group, may also be encompassed in the definition of a heteroaryl group.

In the present disclosure, the term “cyclic group” may encompass a monocyclic group or a polycyclic group and may also encompass an alicyclic ring or an aromatic ring.

In the present disclosure, the term “polycyclic group” may be a group in which two or more rings are connected to each other or condensed to each other through one or more atoms. For example, a polycyclic structure may include a bicyclic structure through a bridge carbon, a spiro structure, a fused structure, and/or the like.

In the present disclosure, the term “condensed group” or “condensed ring structure” may each be a group in which two or more adjacent rings share two or more atoms selected from among the polycyclic structures as described in one or more embodiments. Examples of a condensed ring structure may include naphthalene, anthracene, phenanthrene, fluorene, pyrene, benzopyrene, pentacene, polyacene, helicene, and/or the like.

In the present disclosure, the term “carbocyclic group (e.g., C₃-C₆₀ carbocyclic group and/or the like)” may be a cyclic group in which carbon atoms are the only ring-forming atoms. In the present disclosure, a heterocyclic group (e.g., a C₁-C₆₀ heterocyclic group and/or the like) may be a cyclic group that includes at least one heteroatom as a ring-forming atom, in addition to carbon atoms.

In the present disclosure, a carbocyclic group and a heterocyclic group may each independently be a monocyclic group that consists of (e.g., includes) one ring or a polycyclic group in which two or more rings are condensed with each other.

### Polycyclic Compound

The polycyclic compound according to one or more embodiments may be represented by Chemical Formula 1:

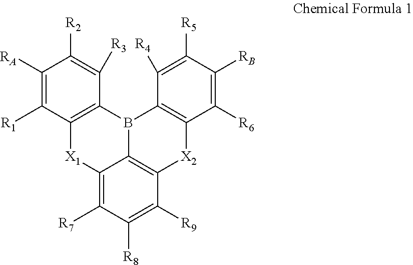

In Chemical Formula 1, X₁ and X₂ may each independently be N(R₁₀), S, O, or Se.

R₁ to R₁₀ may each independently be hydrogen, deuterium, a hydroxyl group, a cyano group, —F, —Cl, —Br, —CDs, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₆-C₆₀ arylalkyl group, a substituted or unsubstituted C₂-C₆₀ heteroaryl group, a substituted or unsubstituted C₂-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group.

Two or more adjacent groups selected from among R₁ to R₉ may optionally be combined with each other to form a saturated ring or an unsaturated ring.

R_{A} and R_{B} may be the same as or different from each other and may each independently represent a substituted or unsubstituted carbazole group, and at least one selected from R_{A} and R_{B} may be selected from the group consisting of carbazole groups having a structure in which an alicyclic hydrocarbon ring group is condensed to one or two of two six-membered benzene rings fused at both sides of one five-membered nitrogen-containing ring of the carbazole group. For example, at least one carbazole group selected from R_{A} and R_{B} is condensed with an alicyclic hydrocarbon ring group on one or two of two six-membered benzene rings fused at both sides of one five-membered nitrogen-containing ring of the carbazole group.

In the polycyclic compound, at least one selected from among the substituted or unsubstituted carbazole groups bonded to an aromatic ring of a core structure containing boron may have an alicyclic hydrocarbon ring group fused at one or two of the two benzene rings in the carbazole group, thereby suppressing or reducing energy transfer between triple excitons due to a Dexter energy transfer and inducing a Foster energy transfer.

Accordingly, the carbazole group may be introduced into the polycyclic compound, so that two or more resonance effect may be enhanced and color purity may be improved or enhanced. In one or more embodiments, at least one selected from among the benzene rings in the carbazole group may be protected by the alicyclic hydrocarbon ring group, so that deterioration of a light-emitting device may be prevented (or a degree or occurrence of deterioration of a light-emitting device may be reduced), and luminous efficiency and life-span properties may be improved or enhanced.

In one or more embodiments, the saturated ring may be selected from among a 5-membered ring, a 6-membered ring, and a 7-membered ring, and the ring may be a hydrocarbon ring or a heteroatom-containing ring. The saturated ring may be unsubstituted or substituted with at least one selected from the group consisting of deuterium, —F, —Cl, —CD₃, —CD₂H, —CDH₂, a C₁-C₁₀ straight-chain alkyl group, a C₃-C₁₀ branched alkyl group, a C₂-C₁₀ straight-chain alkenyl group, a C₃-C₁₀ branched alkenyl group, and a C₆-C₁₀ aryl group.

In one or more embodiments, the unsaturated ring may be selected from among a 5-membered ring, a 6-membered ring, and a 7-membered ring, and the ring may be a hydrocarbon ring or a heteroatom-containing ring. The unsaturated ring may be, for example, a cycloalkene or an aromatic ring containing a C═C unsaturated double bond. The unsaturated rings may be unsubstituted or substituted with at least one selected from the group consisting of deuterium, —F, —Cl, —CDs, —CD₂H, —CDH₂, a C₁-C₁₀ straight-chain alkyl group, a C₃-C₁₀ branched alkyl group, a C₂-C₁₀ straight-chain alkenyl group, a C₃-C₁₀ branched alkenyl group, and a C₅-C₁₀ aryl group.

In one or more embodiments, for example, the substituted or unsubstituted C₈-C₆₀ condensed polycyclic group may be a condensed polycyclic group in which a C₄-C₁₀ aliphatic hydrocarbon ring and a C₆-C₅₀ aromatic hydrocarbon ring are condensed. For example, the substituted or unsubstituted C₈-C₆₀ condensed polycyclic group may have a structure in which one C₄-C₆ aliphatic hydrocarbon ring is condensed between two C₆-C₁₅ aromatic hydrocarbon rings. For example, the condensed polycyclic group may be a substituted or unsubstituted carbazole group, a substituted or unsubstituted fluorene group, or a spiro-bifluorene group.

In one or more embodiments, the silyl group may be —Si(R₂₆)(R₂₇)(R₂₈), and R₂₆, R₂₇ and R₂₈ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, or a substituted or unsubstituted C₈-C₆₀ condensed polycyclic group. The condensed polycyclic group may refer to a group as described in one or more embodiments.

In one or more embodiments, the alicyclic hydrocarbon ring group may be selected from among a 5-membered ring to a 9-membered ring. For example, the alicyclic hydrocarbon ring group may be selected from among a 5-membered to a 7-membered ring.

In one or more embodiments, the alicyclic hydrocarbon ring group may be a 5-membered ring, a 6-membered ring, or a 7-membered ring.

In one or more embodiments, the alicyclic hydrocarbon ring group may be a substituted or unsubstituted cycloalkane, a substituted or unsubstituted bicycloalkane, and a substituted or unsubstituted spiroalkane. The alicyclic hydrocarbon ring group may be a ring devoid of an unsaturated bond and may include a cycloalkane structure, a bicycloalkane structure, or a spiroalkane structure.

Cycloalkane refers to a saturated ring compound in which carbon atoms are connected by a single bond (e.g., a single covalent bond). Bicycloalkane refers to a ring compound in which two saturated rings are connected by sharing two carbon atoms and may include, for example, a fused bicyclic compound or a bridged bicyclic compound. Spiroalkane refers to a spiro compound in which two saturated rings are connected by sharing one carbon atom.

For example, at least one selected from among the alicyclic hydrocarbon ring groups may be selected from the group consisting of a substituted or unsubstituted cyclopentane, a substituted or unsubstituted cyclohexane, a substituted or unsubstituted cycloheptane, a substituted or unsubstituted bicyclo[2.1.0]pentane, a substituted or unsubstituted bicyclo[2.2.0]hexane, a substituted or unsubstituted bicyclo[4.1.0]heptane, a substituted or unsubstituted spiro[5.5]undecane, a substituted or unsubstituted spiro[4.4]nonane, a substituted or unsubstituted spiro[3.4]octane, a substituted or unsubstituted spiro[4.5]decane, and a substituted or unsubstituted spiro[6.6]tridecane.

In one or more embodiments, R_{A} may be represented by Chemical Formula 2-1, and R_{B} may be represented by Chemical Formula 2-2.

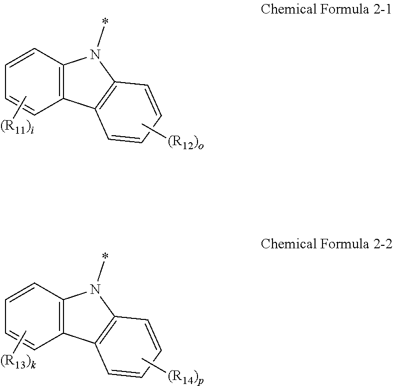

In Chemical Formulae 2-1 and 2-2, R₁₁ to R₁₄ may be the same as or different from each other and may each independently be hydrogen, deuterium, —F, —Cl, —Br, —CDs, —CD₂H, —CDH₂, —CF₃, —CF₂H, —CFH₂, a substituted or unsubstituted C₁-C₆₀ alkyl group, a substituted or unsubstituted C₃-C₆₀ cycloalkyl group, a substituted or unsubstituted C₆-C₆₀ arylalkyl group, a substituted or unsubstituted C₂-C₆₀ heteroarylalkyl group, or a substituted or unsubstituted silyl group. i, o, k, and p may each independently be an integer of 0 to 4.

Two or more adjacent R₁₁ may optionally be combined with each other to form an alicyclic hydrocarbon ring group. Two or more adjacent R₁₂ may optionally be combined with each other to form an alicyclic hydrocarbon ring group. Two or more adjacent R₁₃ may optionally be combined with each other to form an alicyclic hydrocarbon ring group. Two or more adjacent R₁₄ may optionally be combined with each other to form an alicyclic hydrocarbon ring group.

In one or more embodiments, R_{A} may include at least one selected from an alicyclic hydrocarbon ring group formed by two or more R₁₁ and an alicyclic hydrocarbon ring group formed by two or more R₁₂. R_{B} may include at least one selected from an alicyclic hydrocarbon ring group formed by two or more R₁₃ and an alicyclic hydrocarbon ring group formed by two or more R₁₄.

In one or more embodiments, R_{A} may include at least one selected from an alicyclic hydrocarbon ring group formed by two or more R₁₁ and an alicyclic hydrocarbon ring group formed by two or more R₁₂, and R_{B} may include at least one selected from an alicyclic hydrocarbon ring group formed by two or more R₁₃ and an alicyclic hydrocarbon ring group formed by two or more R₁₄.

In one or more embodiments, at least one selected from among the alicyclic hydrocarbon ring group formed by two or more R₁₁, the alicyclic hydrocarbon ring group formed by two or more R₁₂, the alicyclic hydrocarbon ring group formed by two or more R₁₃, and the alicyclic hydrocarbon ring group formed by two or more R₁₄ may each independently be selected from among a substituted or unsubstituted C₄-C₉ cycloalkane, a substituted or unsubstituted C₅-C₃₀ bicycloalkane, and a substituted or unsubstituted C₈-C₃₀ spiroalkane.

In one or more embodiments, at least one selected from among the alicyclic hydrocarbon ring group formed by two or more R₁₁, the alicyclic hydrocarbon ring group formed by two or more R₁₂, the alicyclic hydrocarbon ring group formed by two or more R₁₃, and the alicyclic hydrocarbon ring group formed by two or more R₁₄ may each independently be selected from the group consisting of a substituted or unsubstituted cyclopentane, a substituted or unsubstituted cyclohexane, a substituted or unsubstituted cycloheptane, a substituted or unsubstituted bicyclo[2.1.0]pentane, a substituted or unsubstituted bicyclo[2.2.0]hexane, a substituted or unsubstituted bicyclo[4.1.0]heptane, a substituted or unsubstituted spiro[5.5]undecane, a substituted or unsubstituted spiro[4.4]nonane, a substituted or unsubstituted spiro[3.4]octane, a substituted or unsubstituted spiro[4.5]decane, and a substituted or unsubstituted spiro[6.6]tridecane.

In one or more embodiments, R_{A} and R_{B} may be the same as or different from each other and may each independently be represented by any one selected from among Chemical Formulae 3-1 to 3-6.

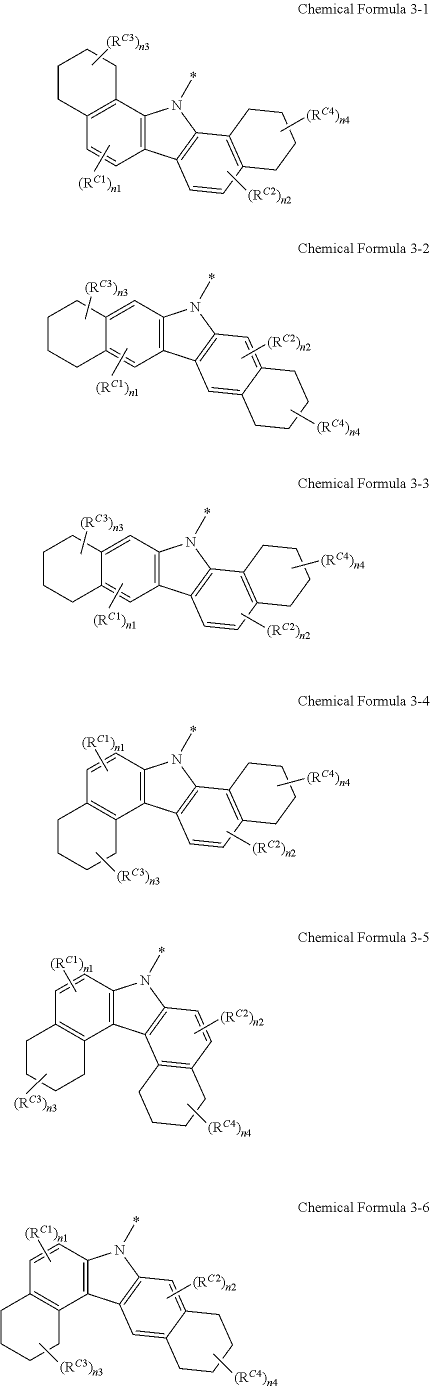

In Chemical Formulae 3-1 to 3-6, R^{c1} and R^{c2} may be the same as or different from each other and may each independently be hydrogen, deuterium, —F, —Cl, —Br, —CDs, —CD₂H, —CDH₂, —CF₃, —CF₂H—, —CFH₂, a substituted or unsubstituted C₁-C₃₀ alkyl group, or a substituted or unsubstituted C₃-C₃₀ cycloalkyl group.

R^{c3} and R^{c4} may be the same as or different from each other and may each independently be hydrogen, deuterium, —CDs, —CD₂H, —CDH₂, a substituted or unsubstituted C₁-C₃₀ alkyl group, or a substituted or unsubstituted C₃-C₃₀ cycloalkyl group.

n1 and n2 may be the same as or different from each other and may each independently be an integer of 0 to 2. n3 and n4 may be the same as or different from each other and may each independently be an integer of 0 to 8.

Two or more adjacent R^{c3} may optionally be combined with each other to form a saturated ring. Two or more adjacent R^{c4} may optionally be combined with each other to form a saturated ring.

In one or more embodiments, R_{A} and R_{B} may be the same as or different from each other and may each independently be represented by one selected from Chemical Formulae 3-2 and 3-3.

Accordingly, a distance between the benzene ring of the carbazole group of the polycyclic compound and neighboring compounds may not become excessively or substantially small in an emission layer so that an energy transfer between singlet excitons by the Foster energy transfer may be induced and energy transfer between triplet excitons due to the Dexter energy transfer may be effectively or suitably suppressed or reduced.

For example, in any one selected from among Chemical Formulae 3-1 to 3-6, the saturated ring may each independently be selected from among a 5-membered hydrocarbon ring, a 6-membered hydrocarbon ring, and a 7-membered hydrocarbon ring, and the hydrocarbon ring may be unsubstituted or substituted with at least one selected from the group consisting of deuterium, —CDs, a C₁-C₁₀ straight-chain alkyl group, a C₃-C₁₀ branched alkyl group, a C₂-C₁₀ straight-chain alkenyl group, and a C₃-C10 branched alkenyl group.

In one or more embodiments, the polycyclic compound represented by Chemical Formula 1 may be represented by any one selected from among the following Chemical Formulae 1-1 to 1-6.

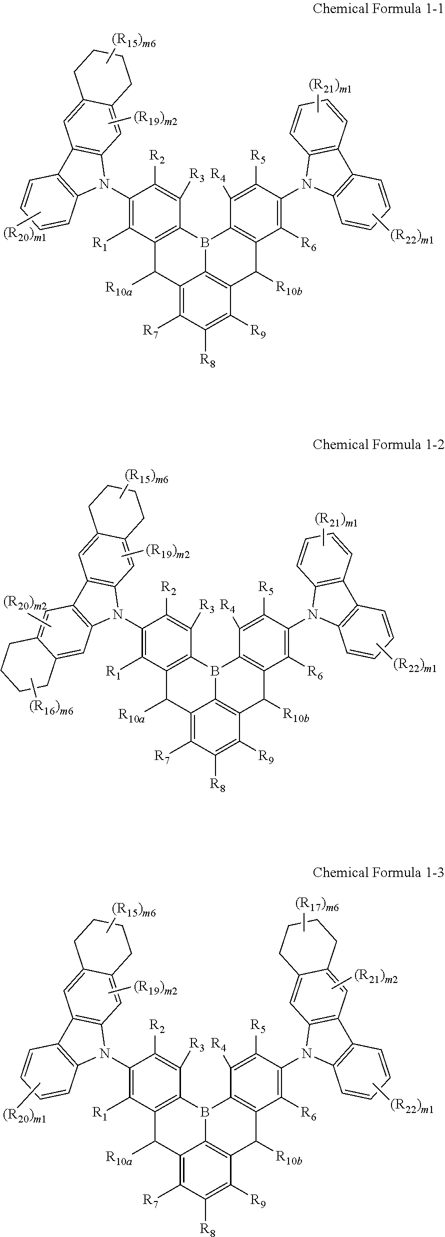

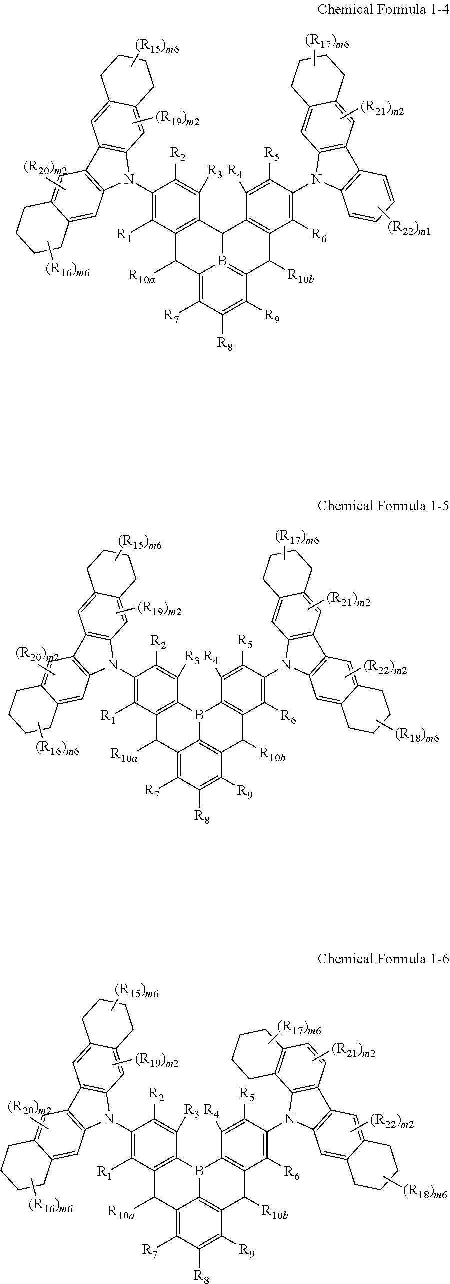

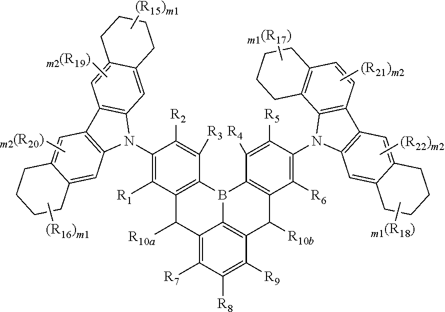

In Chemical Formulae 1-1 to 1-6, R₁ to R₉, R₁₀ₐ, and R_{10b} may each independently be hydrogen, deuterium, a hydroxyl group, a cyano group, —F, —Cl, —Br, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₆-C₆₀ arylalkyl group, a substituted or unsubstituted C₂-C₆₀ heteroaryl group, a substituted or unsubstituted C₂-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group, and two or more adjacent groups selected from among R₁ to R₉ may optionally be combined with each other to form a saturated ring or an unsaturated ring.

R₁₅ to R₁₈ may be the same as or different from each other and may each independently be hydrogen, deuterium, —CDs, —CD₂H, —CDH₂, a substituted or unsubstituted C₁-C₃₀ alkyl group, or a substituted or unsubstituted C₃-C₃₀ cycloalkyl group.

R₁₉ to R₂₂ may be the same as or different from each other and may each independently be hydrogen, deuterium, —F, —Cl, —Br, —CDs, —CD₂H, —CDH₂, a substituted or unsubstituted C₁-C₃₀ alkyl group, or a substituted or unsubstituted C₃-C₃₀ cycloalkyl group.

A plurality of m1 may each independently be an integer of 0 to 4, plurality of m2 may each independently be an integer of 0 to 2, and a plurality of m6 may each independently be an integer of 0 to 8.

Two or more adjacent R₁₅ may optionally be combined with each other to form a saturated ring, two or more adjacent R₁₆ may optionally be combined with each other to form a saturated ring, two or more adjacent R₁₇ may optionally be combined with each other to form a saturated ring, and two or more adjacent R₁₈ may optionally be combined with each other to form a saturated ring.

For example, in any one selected from among Chemical Formulae 1-1 to 1-6, the saturated ring may be selected from a 5-membered hydrocarbon ring, a 6-membered hydrocarbon ring, and a 7-membered hydrocarbon ring, and the hydrocarbon ring may be unsubstituted or substituted with at least one selected from the group consisting of deuterium, —CD₃, a C₁-C₁₀ straight-chain alkyl group, a C₃-C₁₀ branched alkyl group, a C₂-C₁₀ straight-chain alkenyl group, and a C₃-C₁₀ branched alkenyl group.

In one or more embodiments, the polycyclic compound may be represented by one selected from Chemical Formulae 1-5 and 1-6.

Accordingly, the polycyclic compound may have improved or enhanced oxidation stability, and reliability and operational stability of a light-emitting device including the polycyclic compound, a display device including the polycyclic compound, an electronic device including the polycyclic compound, and an electronic apparatus including the polycyclic compound may be improved or enhanced.

In one or more embodiments, the polycyclic compound may improve or enhance light-emitting and life-span properties of the light-emitting device through compatibility of exciton generation efficiency and oxidation stability in an emission layer.

In one or more embodiments, R₁₀ₐ and R_{10b} may each independently be represented by one selected from among Chemical Formulae 4-1 to 4-12.

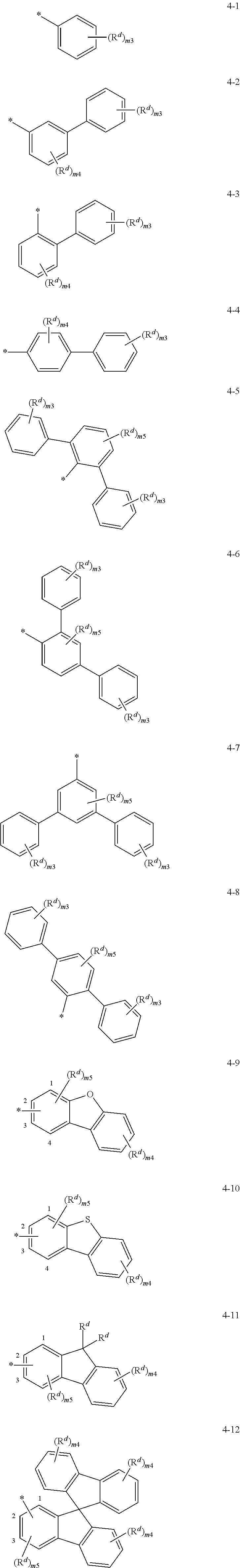

In Chemical Formulae 4-1 to 4-12, a plurality of m3 may be the same as or different from each other and may each independently be an integer of 0 to 5. A plurality of m4 may be the same as or different from each other and may each independently be an integer of 0 to 4. A plurality of m5 may be the same as or different from each other and may each independently be an integer of 0 to 3.

A single R^{d} may be or two or more of R^{d} being the same as or different from each other may each independently be hydrogen, deuterium, —CD₃, —CD₂H, —CDH₂, —CN, a substituted or unsubstituted C₁-C₁₀ alkyl group, a substituted or unsubstituted C₂-C₁₀ alkenyl group, a substituted or unsubstituted C₃-C₁₀ cycloalkyl group, or a substituted or unsubstituted C₆-C₁₀ aryl group.

If (e.g., when) a plurality of R^{d} is included, two adjacent ones selected from among the plurality of R^{d} may optionally be combined with each other to form a saturated or unsaturated ring. The saturated or unsaturated ring may be the same as defined in Chemical Formula 1.

In Chemical Formulae 4-9 to 4-11, the *- binding site may be one selected from among carbons designated as the numbers of 1 to 4. In Chemical Formula 4-12, the *- binding site may be one selected from among carbons designated as the numbers of 1 to 3.

In one or more embodiments, R₁₀ₐ and R_{10b} may each independently be represented by any one selected from among Chemical Formulae 4-5 to 4-12.

In one or more embodiments, R₁₀ₐ and R_{10b} may each independently be represented by Chemical Formula 4-5. Accordingly, aggregation between the polycyclic compounds may be prevented (or a degree or occurrence of aggregation between the polycyclic compounds may be reduced) more effectively or suitably.

For example, the group represented by Chemical Formula 4-5 may be unsubstituted or substituted with —CD₃, —CD₂H, —CDH₂, —CN, a substituted or unsubstituted phenyl group, a substituted or unsubstituted biphenyl group, or a t-butyl group at a para position with respect to the *- bond of a middle benzene ring.

In one or more embodiments, R₇ to R₉ may each independently be hydrogen, deuterium, —CD₃, —CD₂H, —CDH₂, —CN, a substituted or unsubstituted C₁-C₂₀ alkyl group, a substituted or unsubstituted C₆-C₂₀ aryl group, or a substituted or unsubstituted C₆-C₂₀ heteroaryl group.

R₈ may be, for example, hydrogen, deuterium, —CD₃, —CD₂H, —CDH₂, —CN, a t-butyl group, a substituted or unsubstituted dibenzofuran group, a substituted or unsubstituted phenyl group, a substituted or unsubstituted biphenyl group, a substituted or unsubstituted naphthyl group, a substituted or unsubstituted pyridinyl group, a substituted or unsubstituted pyrimidinyl group, or a terphenyl group.

In one or more embodiments, the polycyclic compound may be any one selected from among the compounds represented by Chemical Formulae 1 to 128.

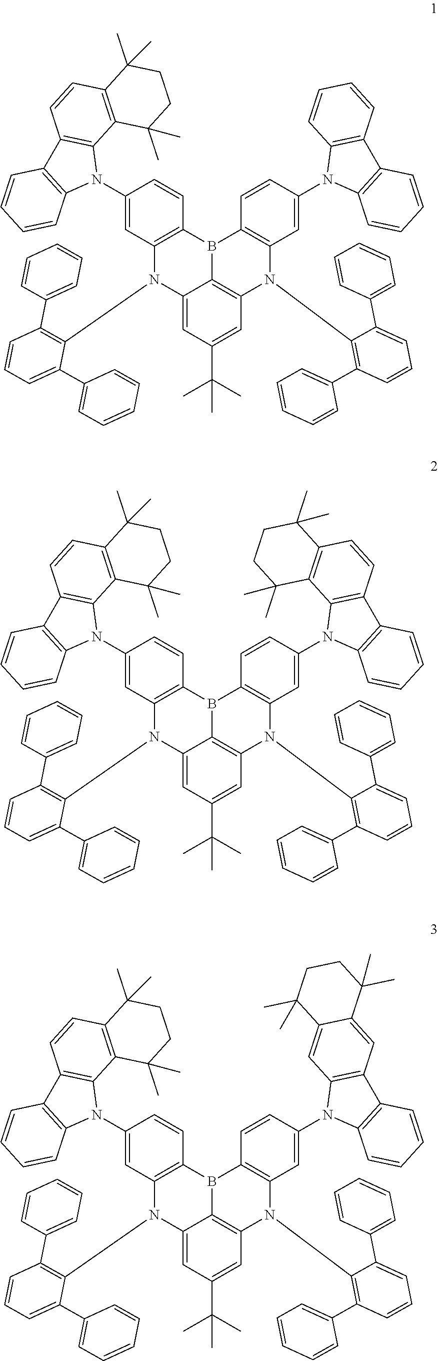

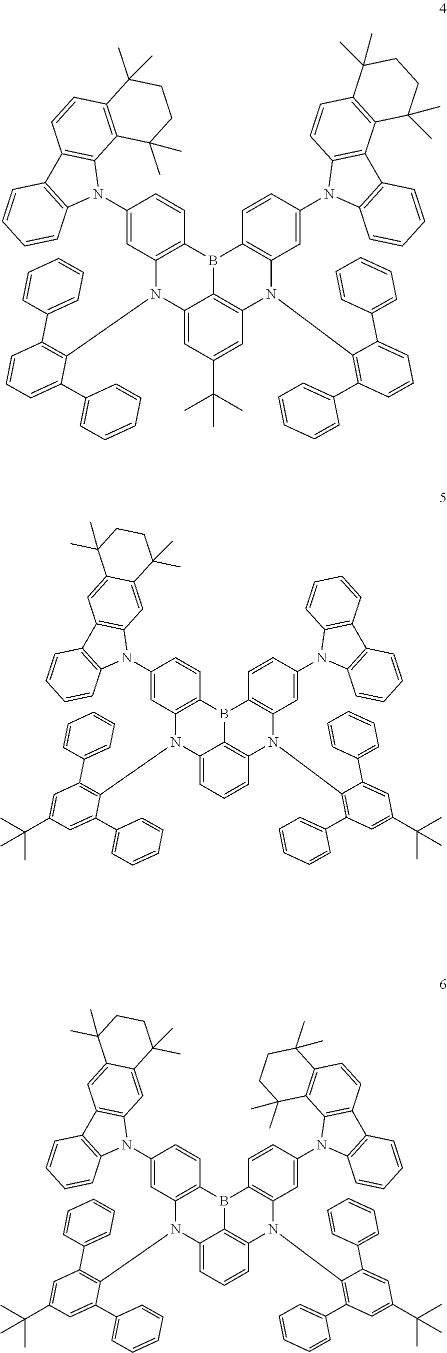

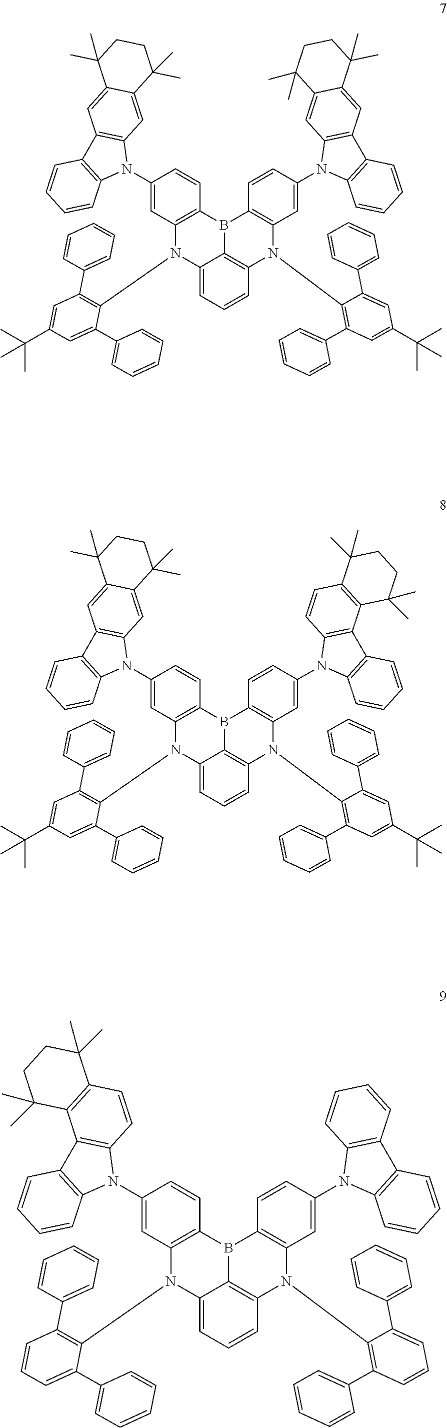

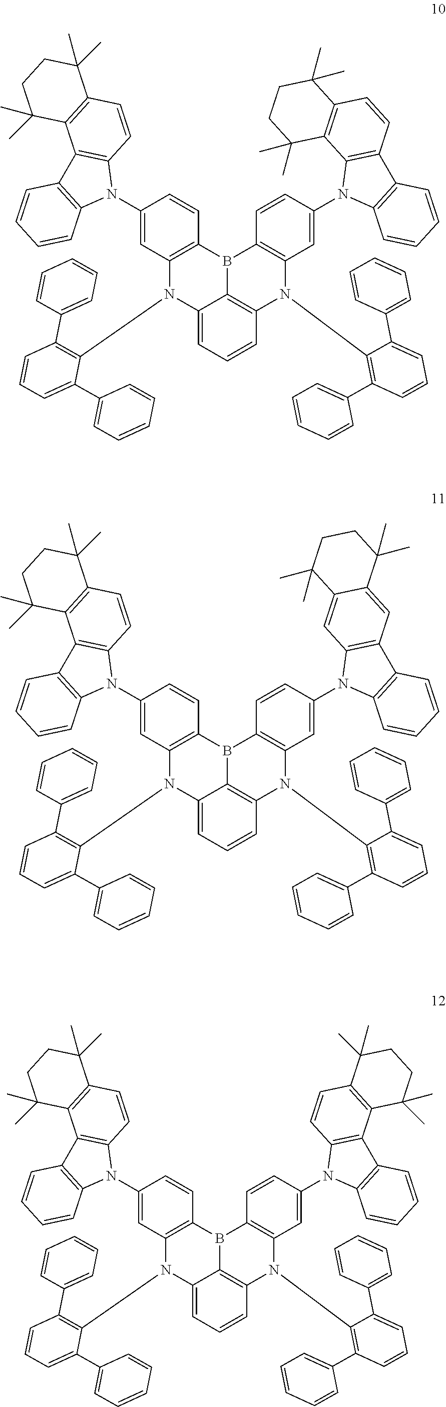

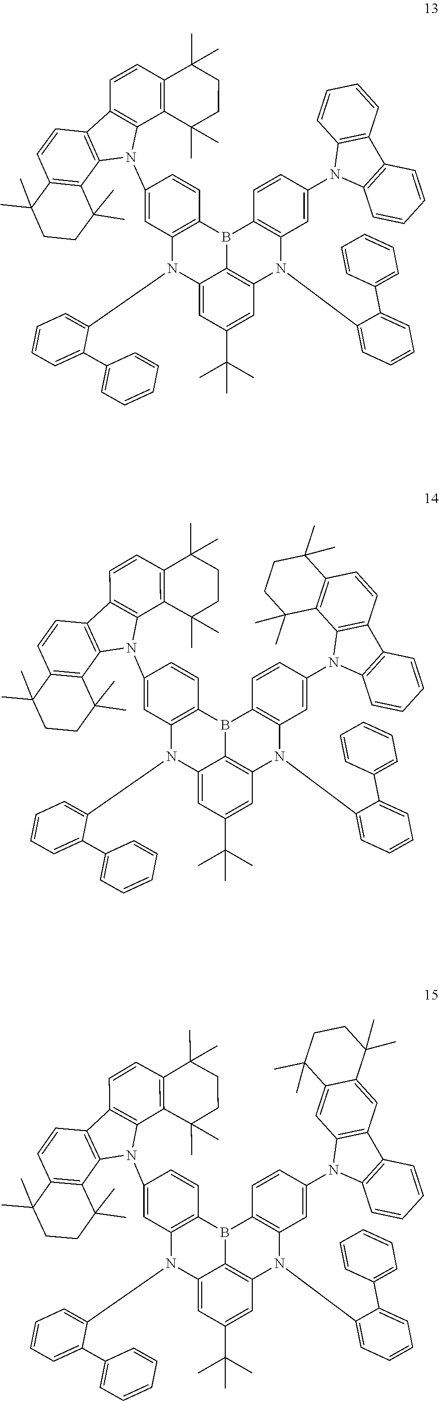

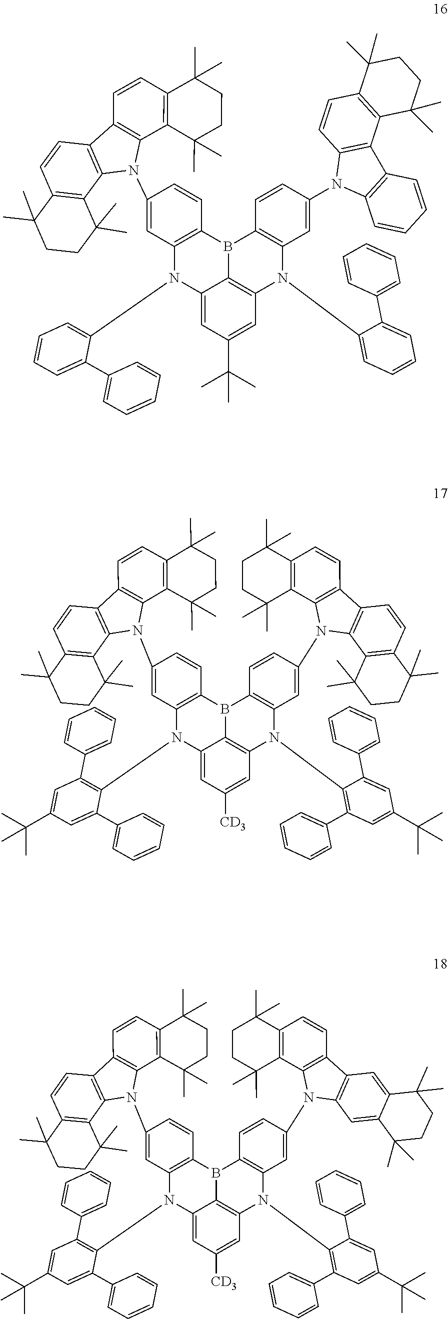

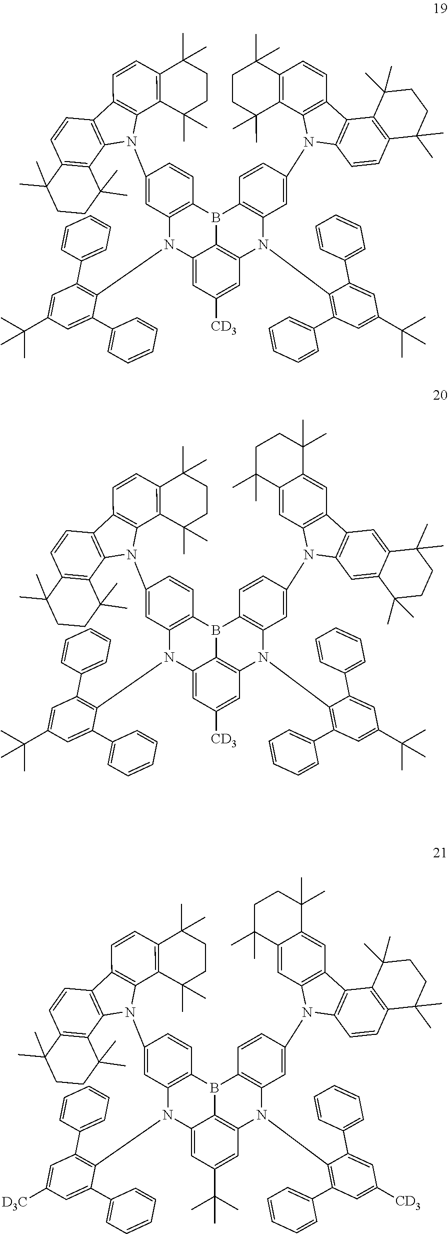

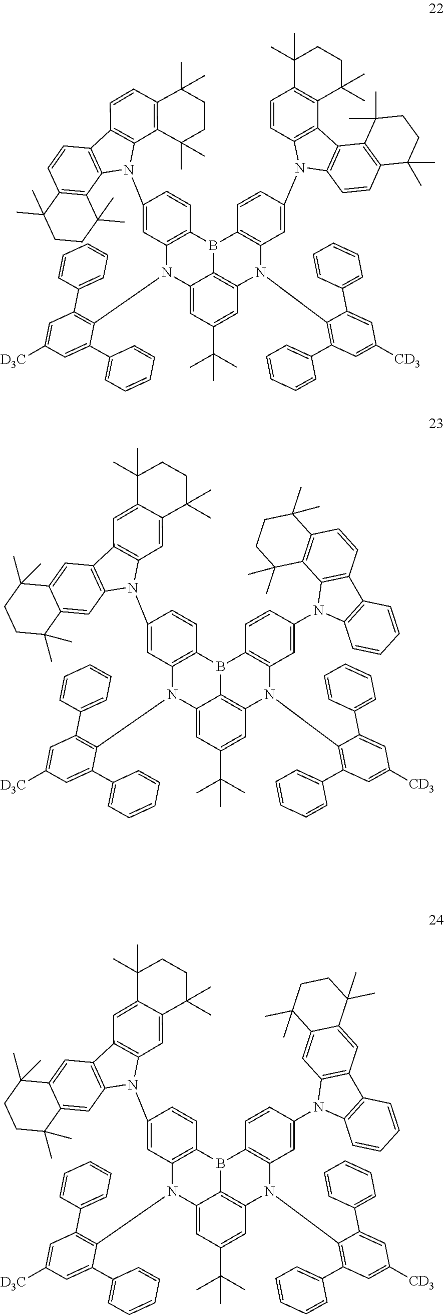

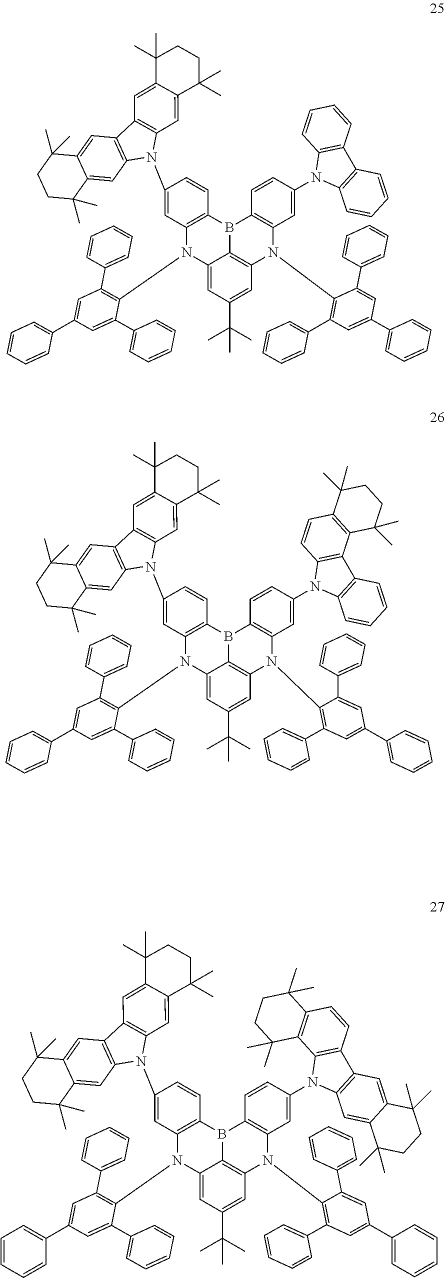

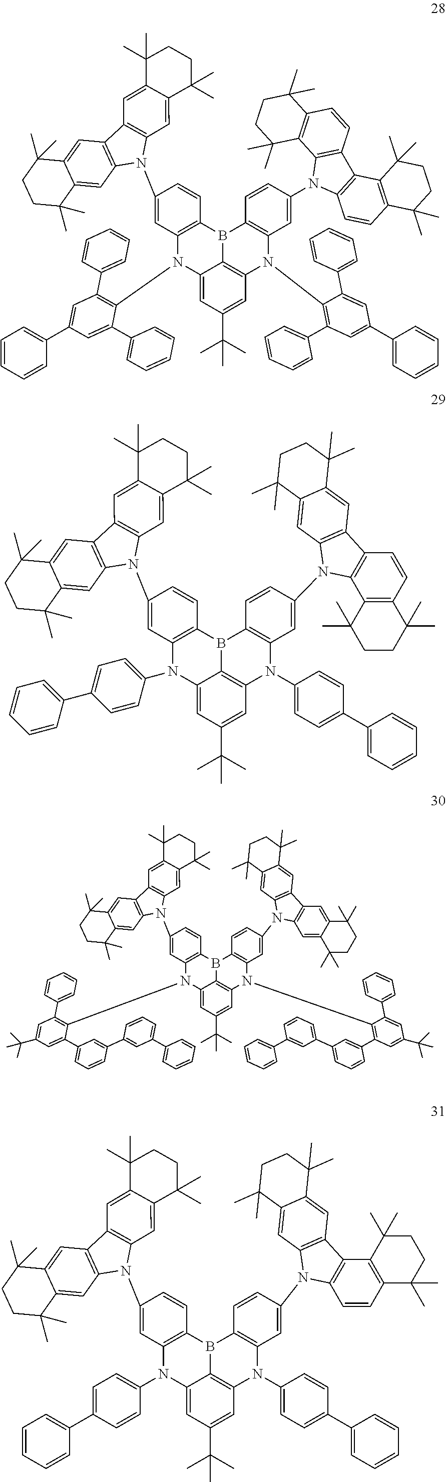

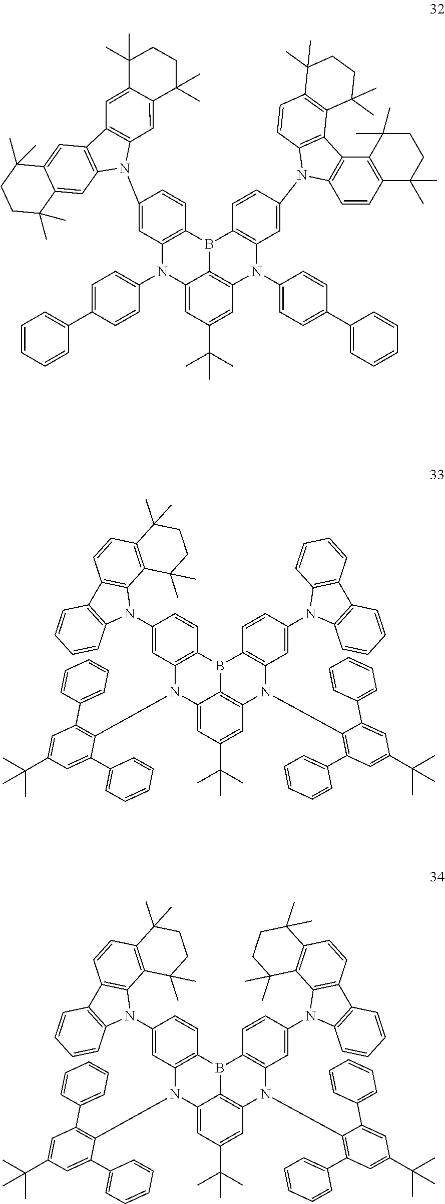

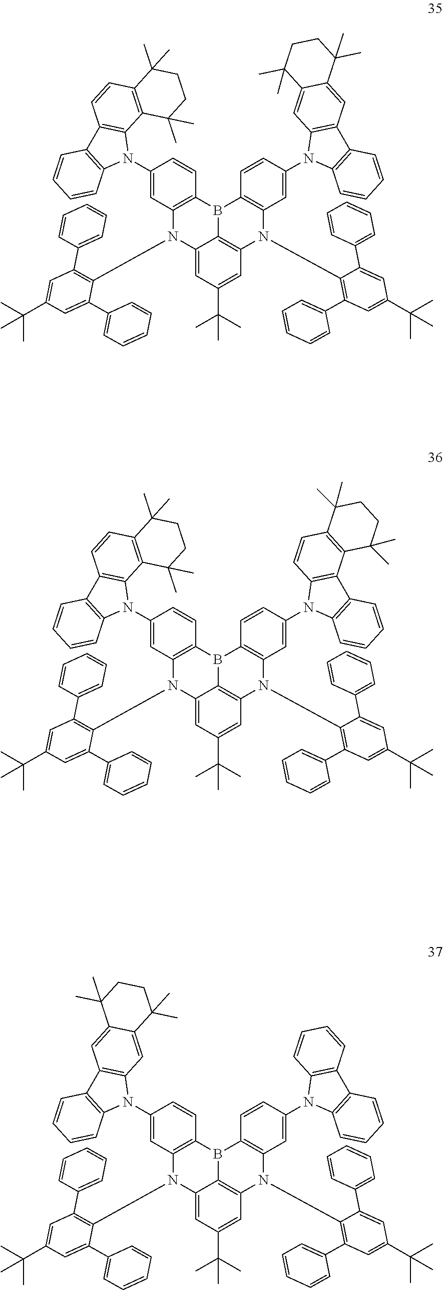

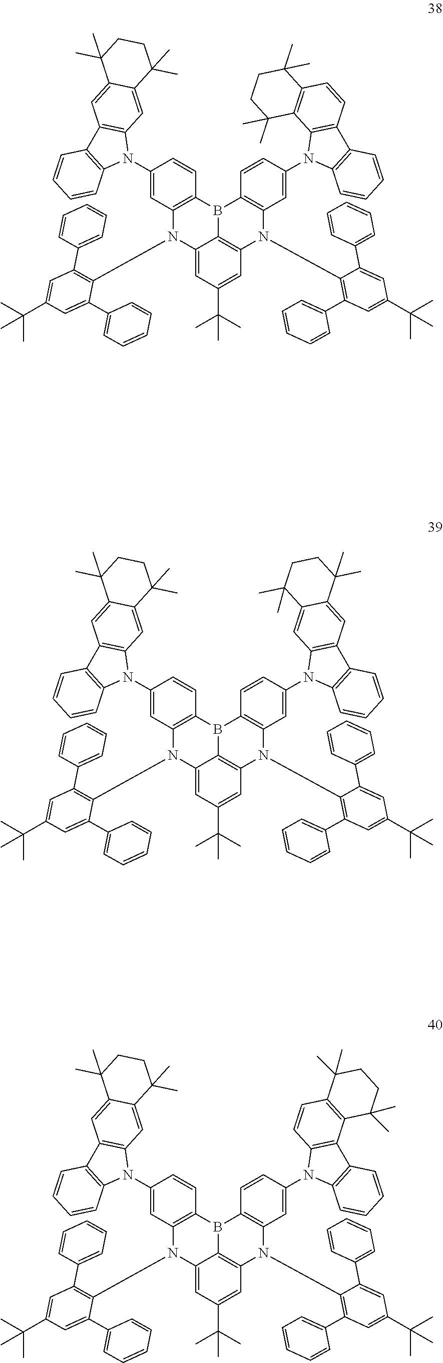

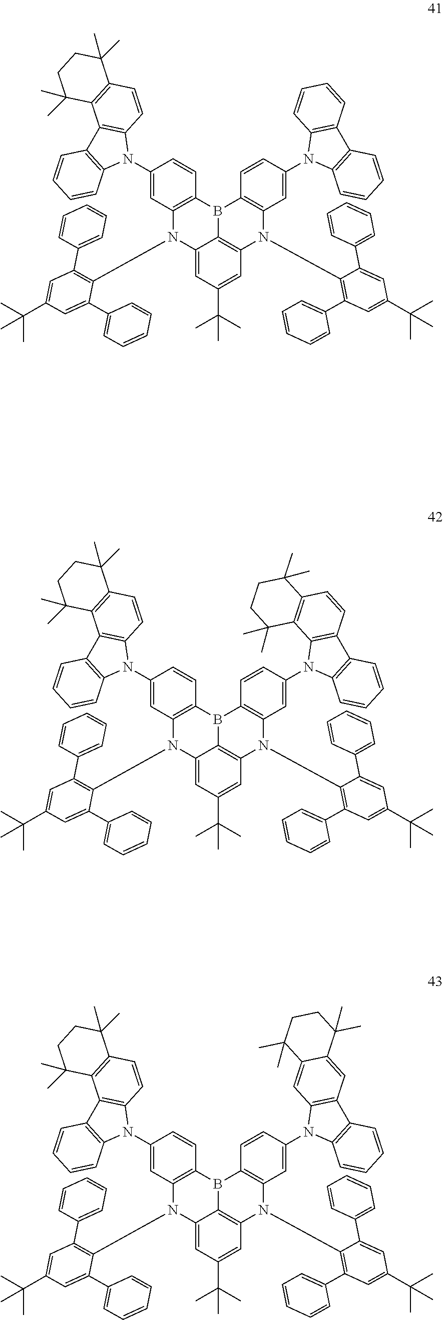

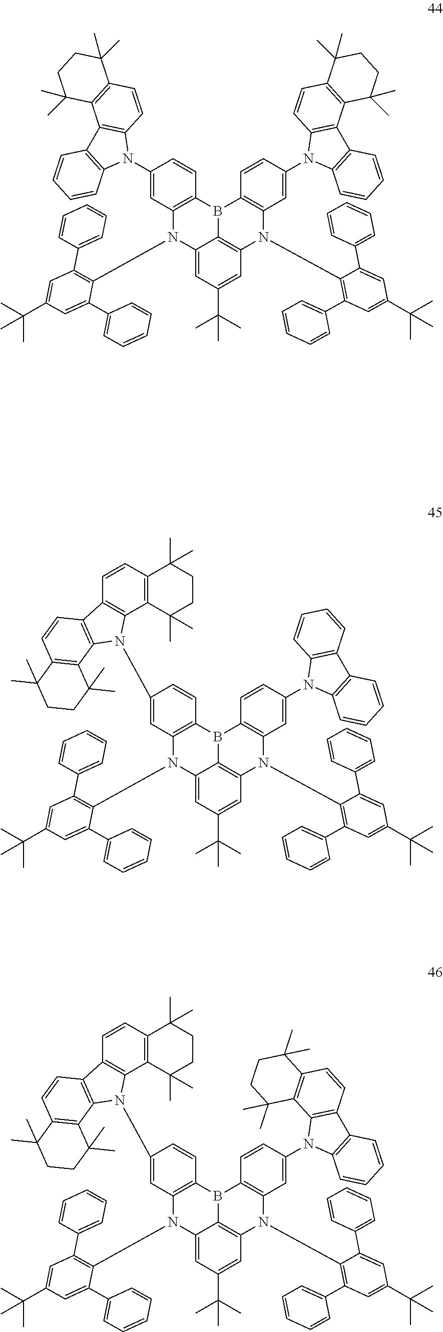

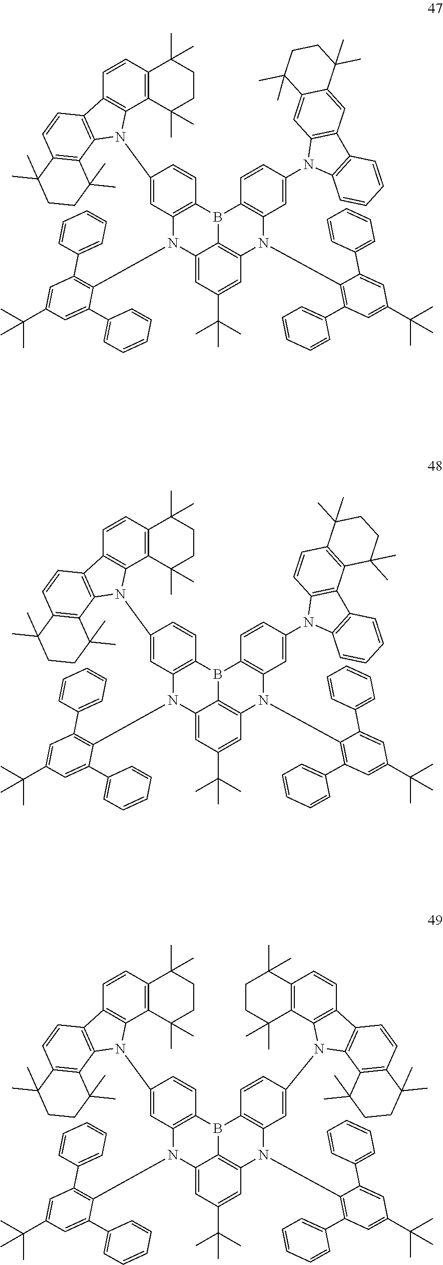

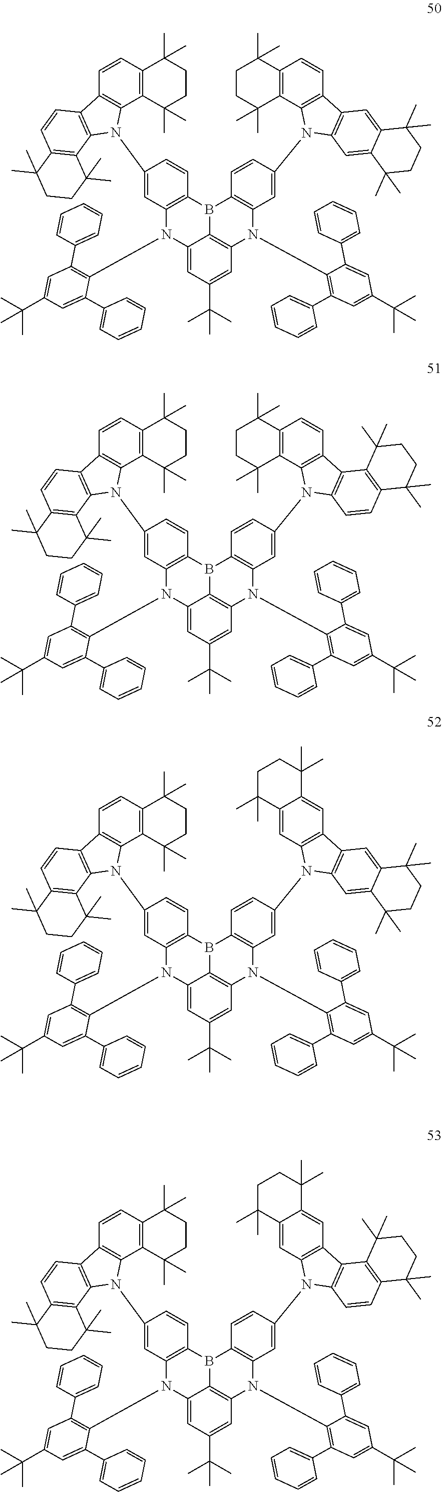

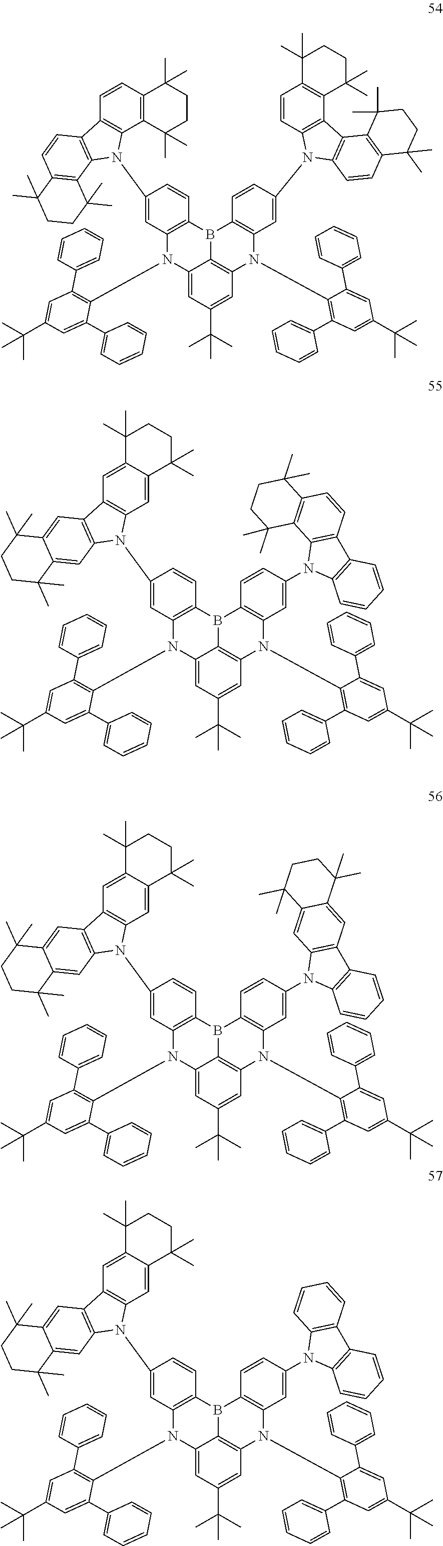

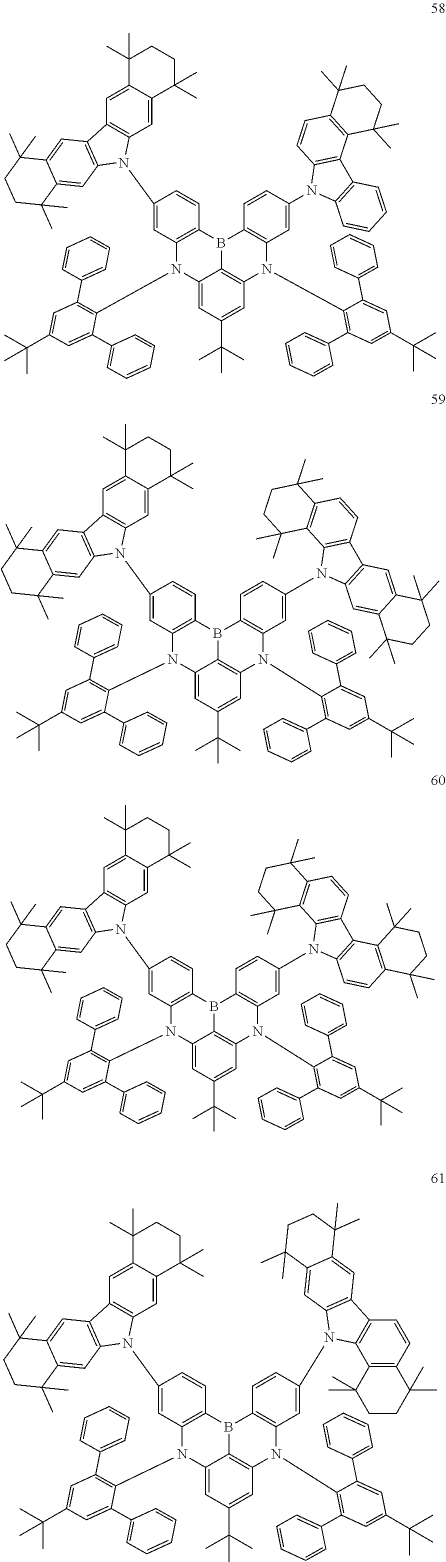

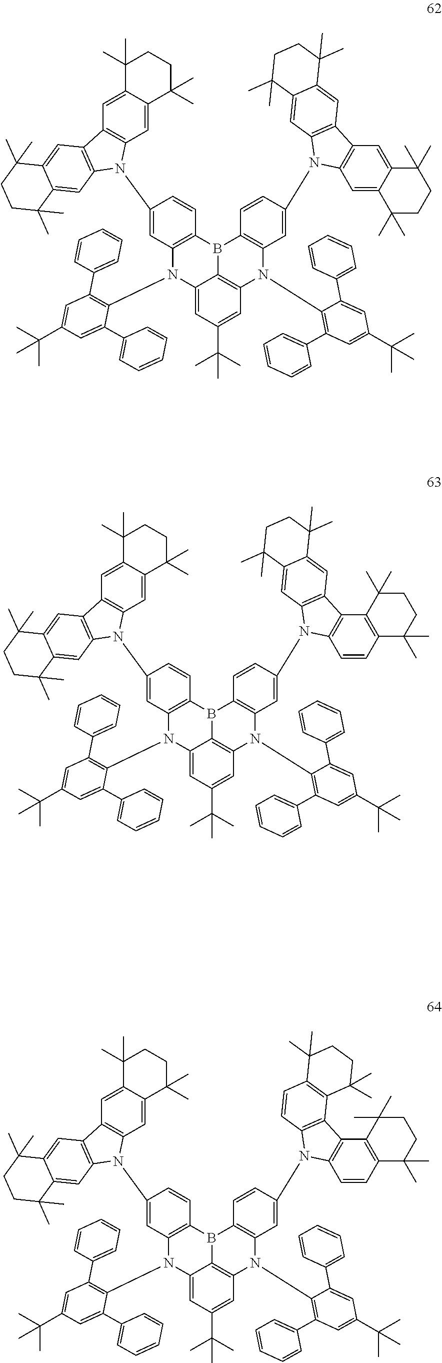

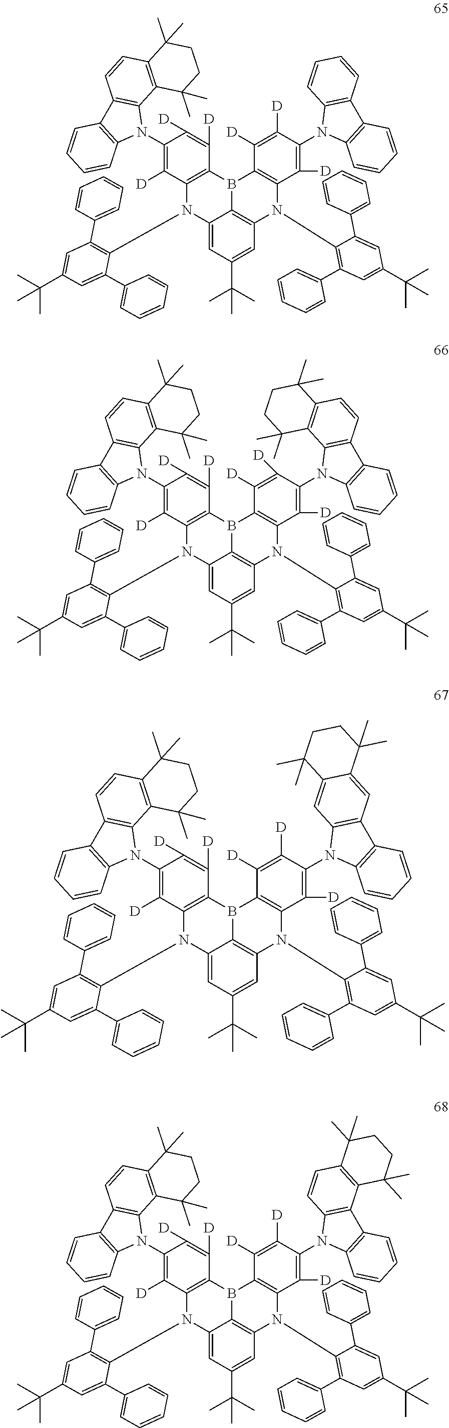

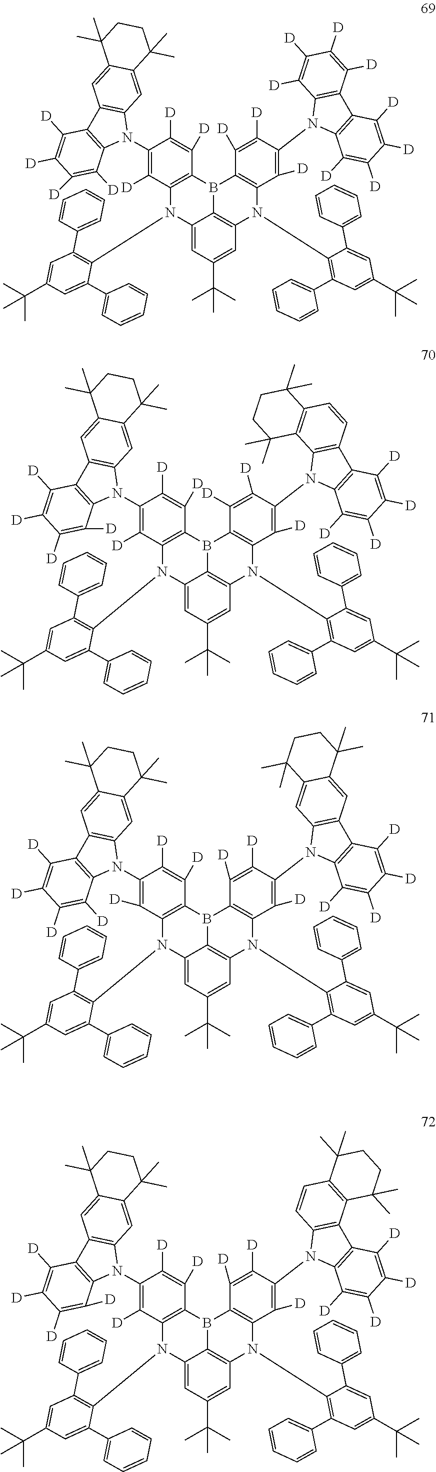

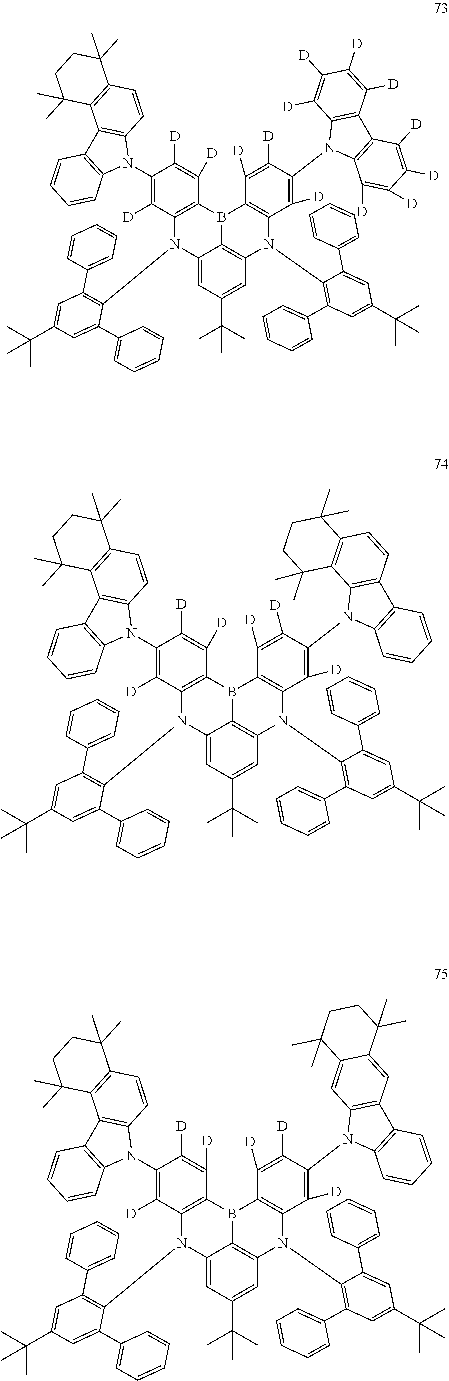

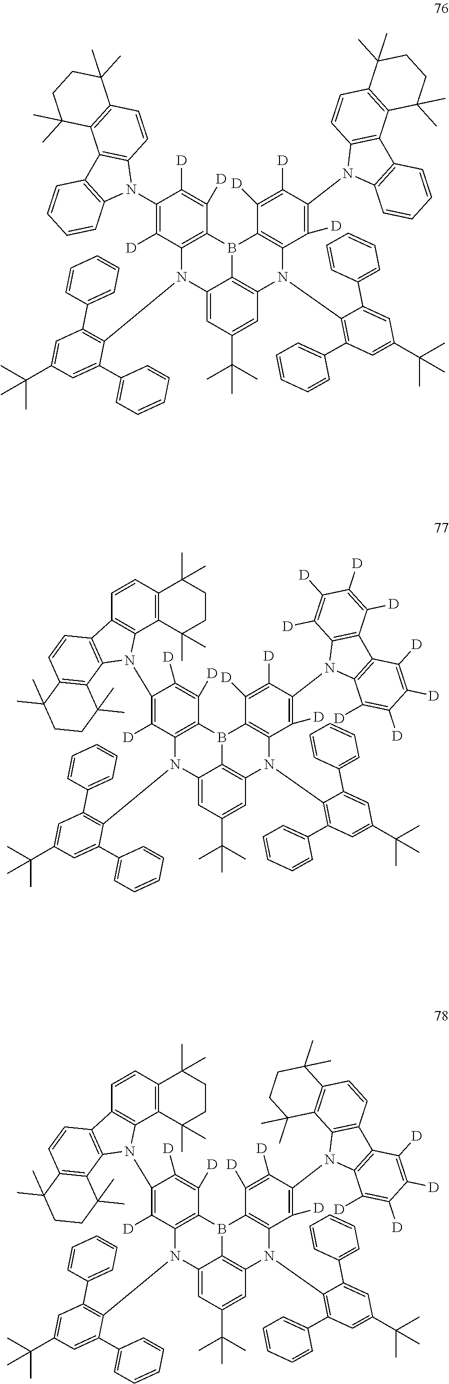

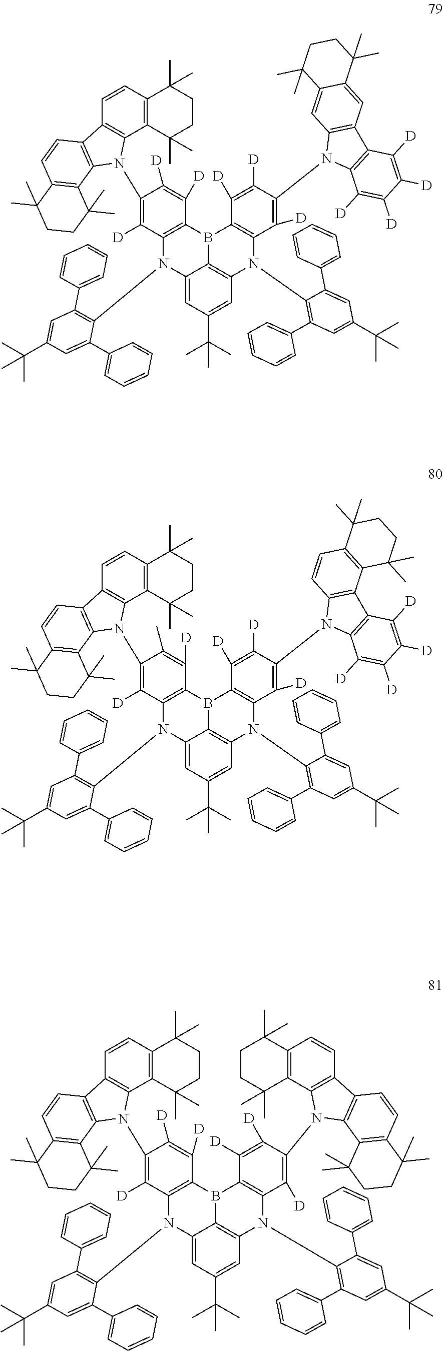

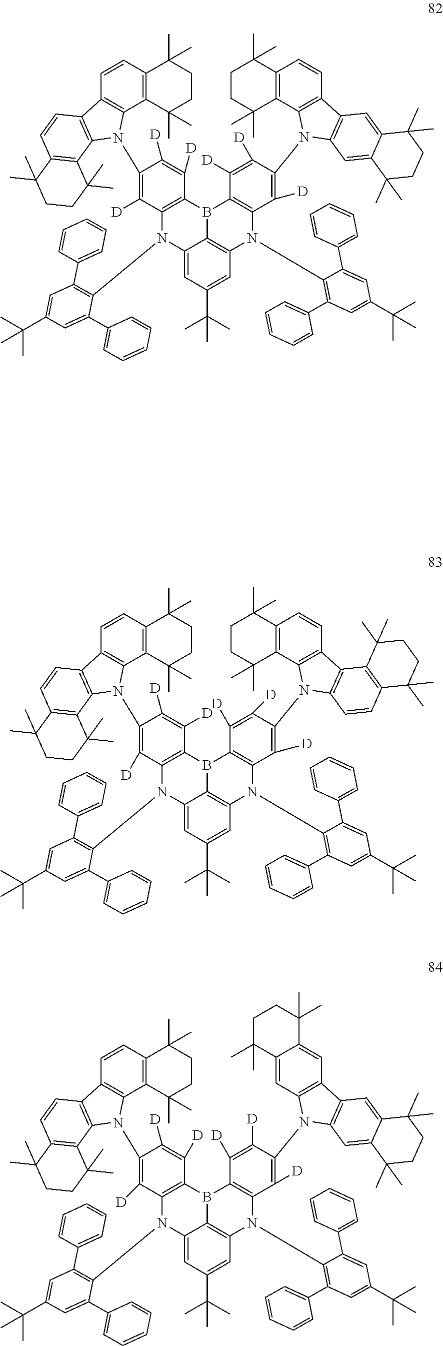

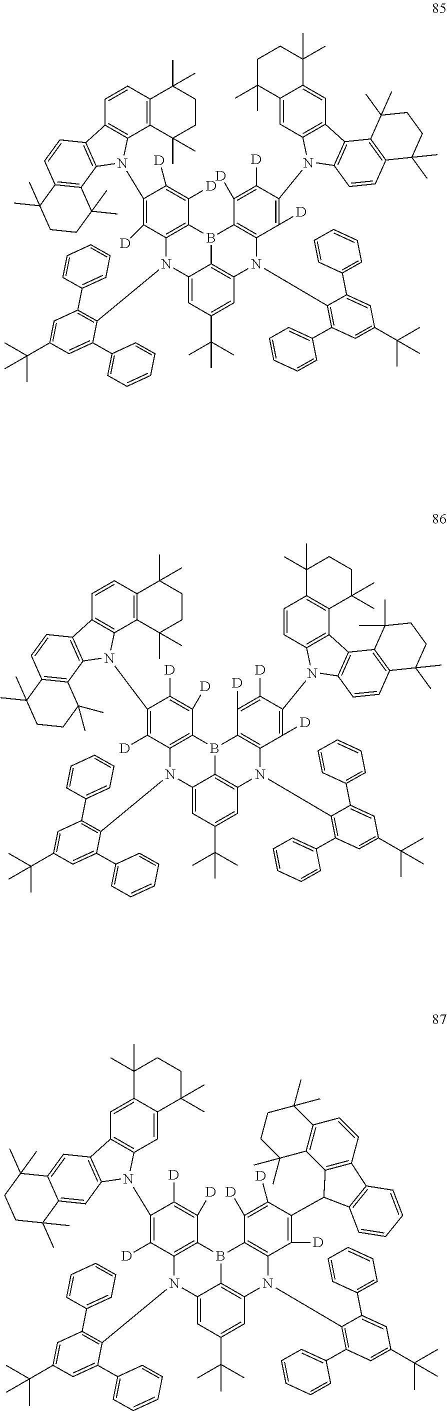

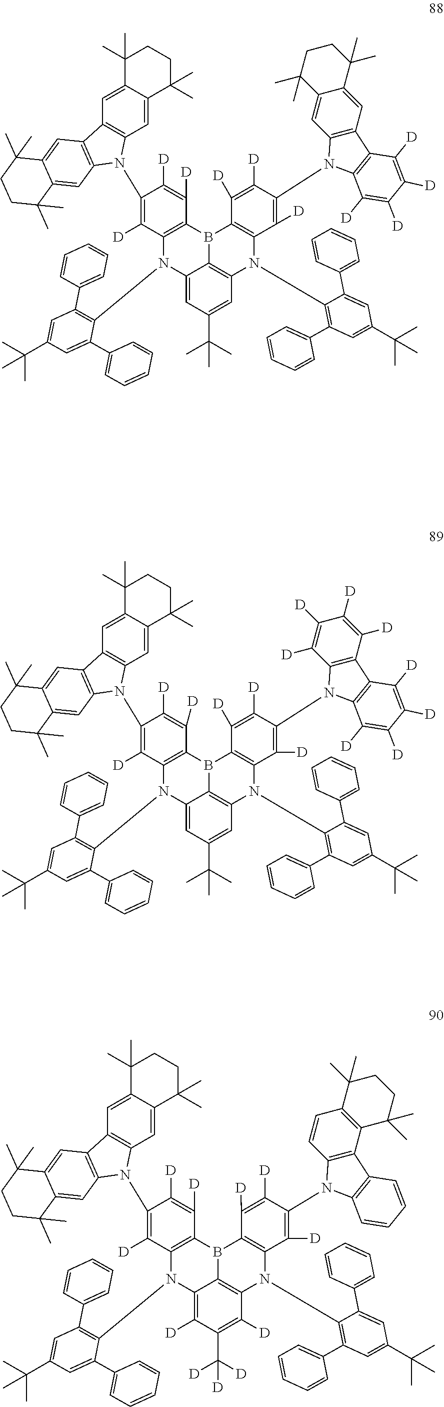

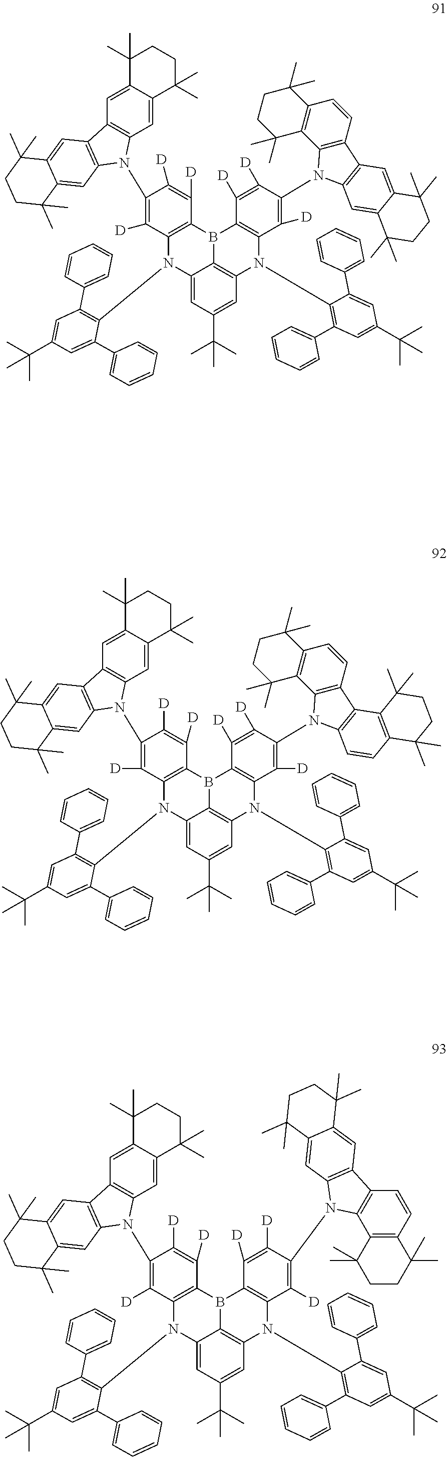

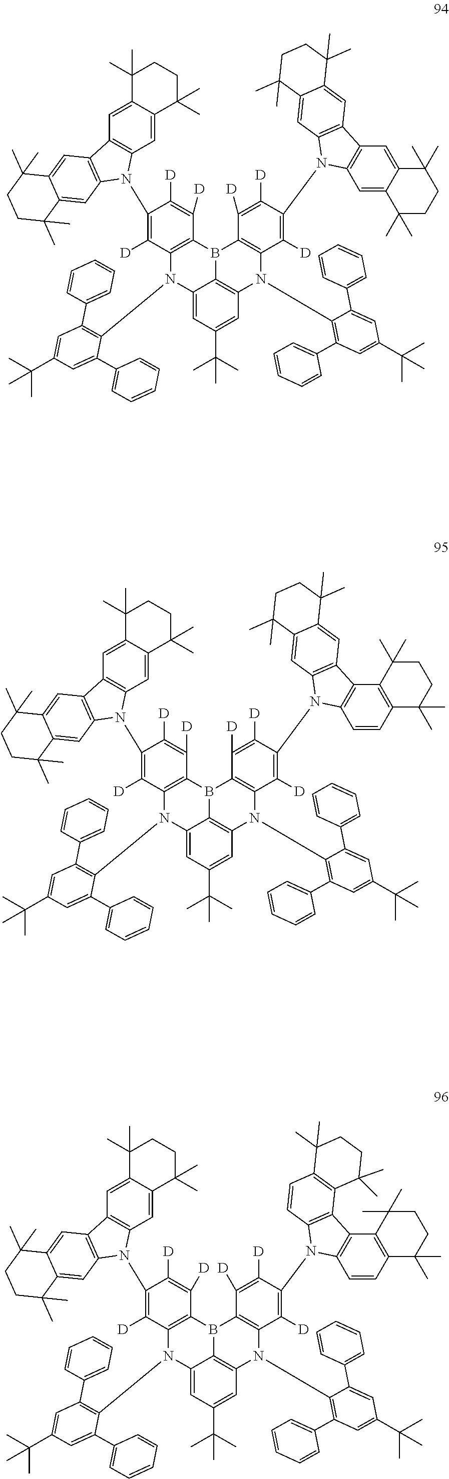

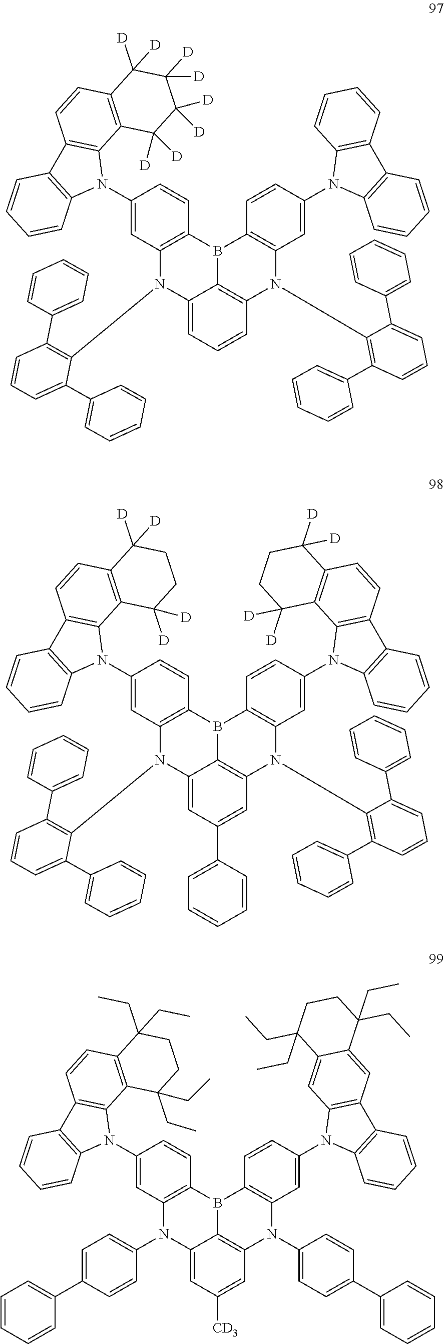

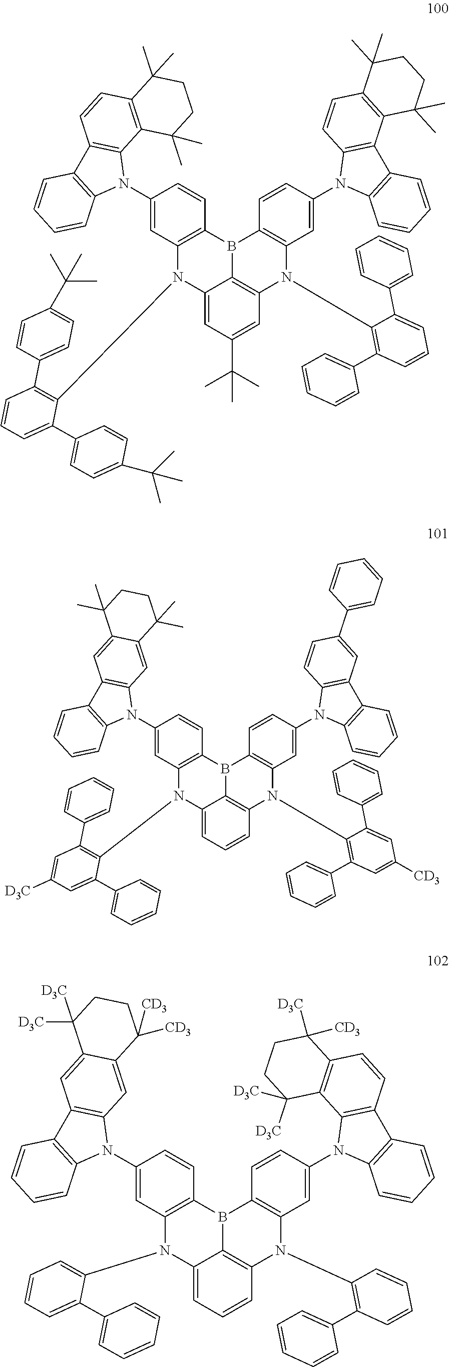

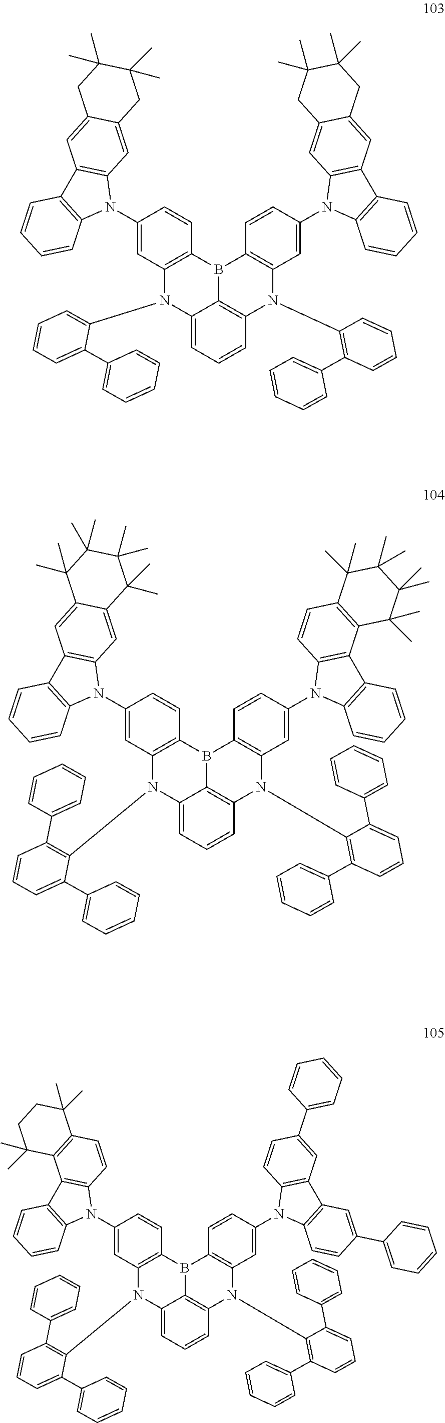

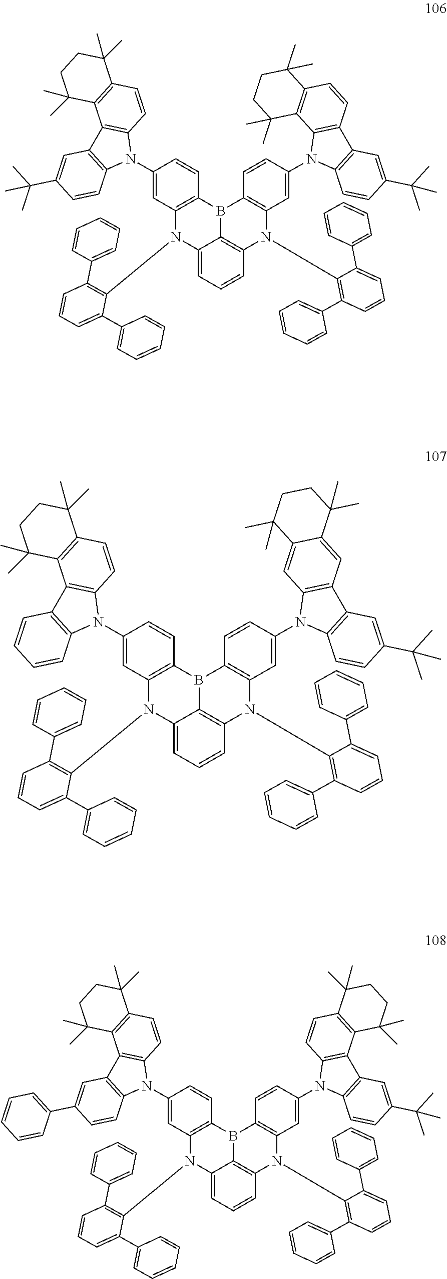

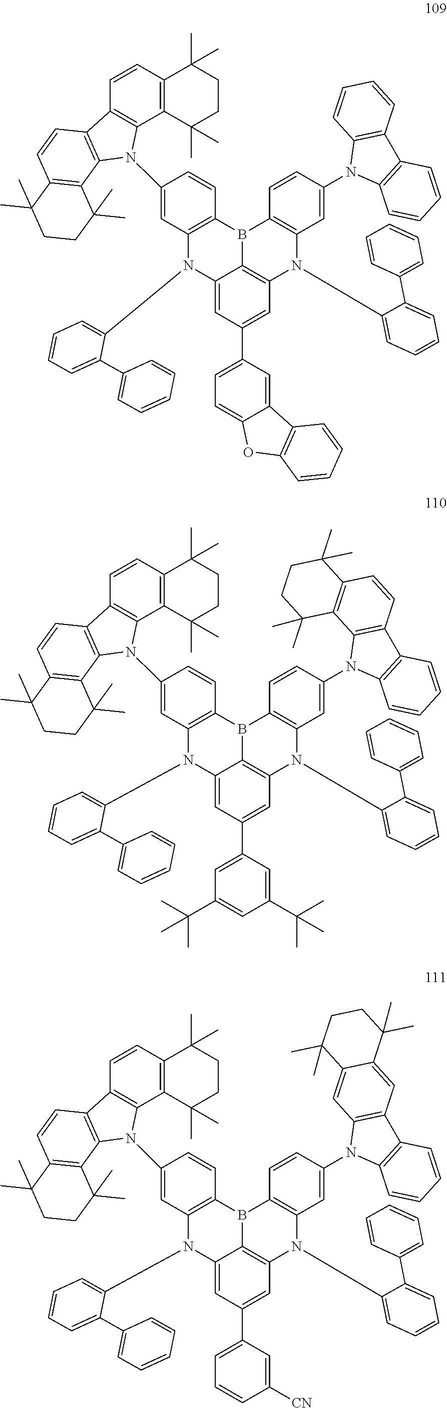

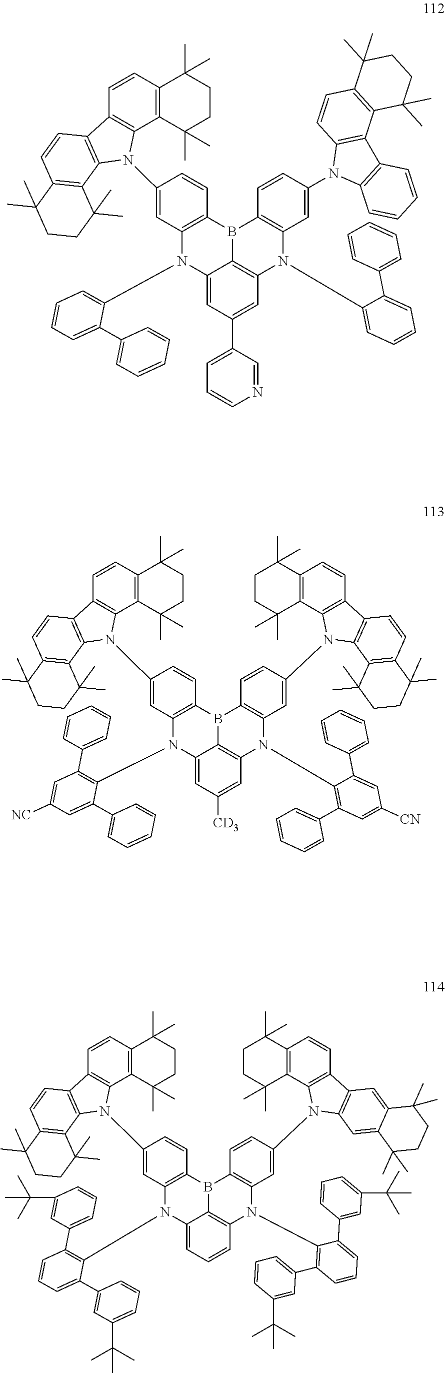

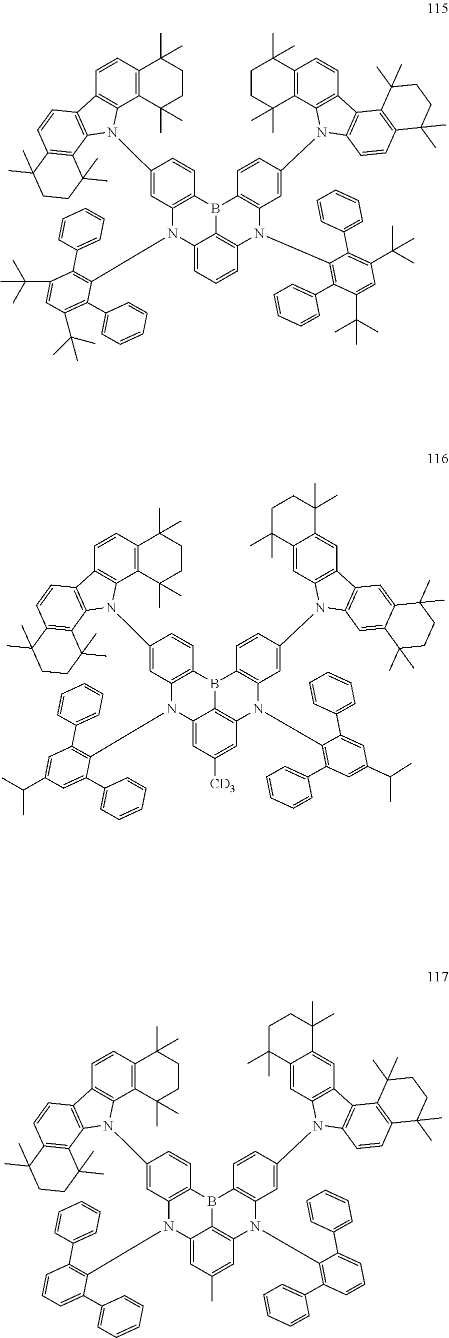

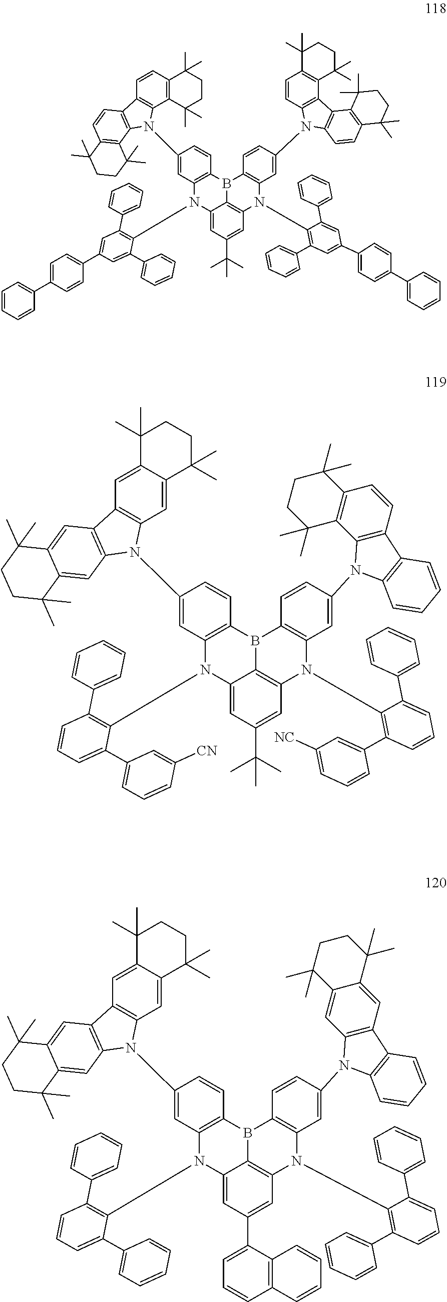

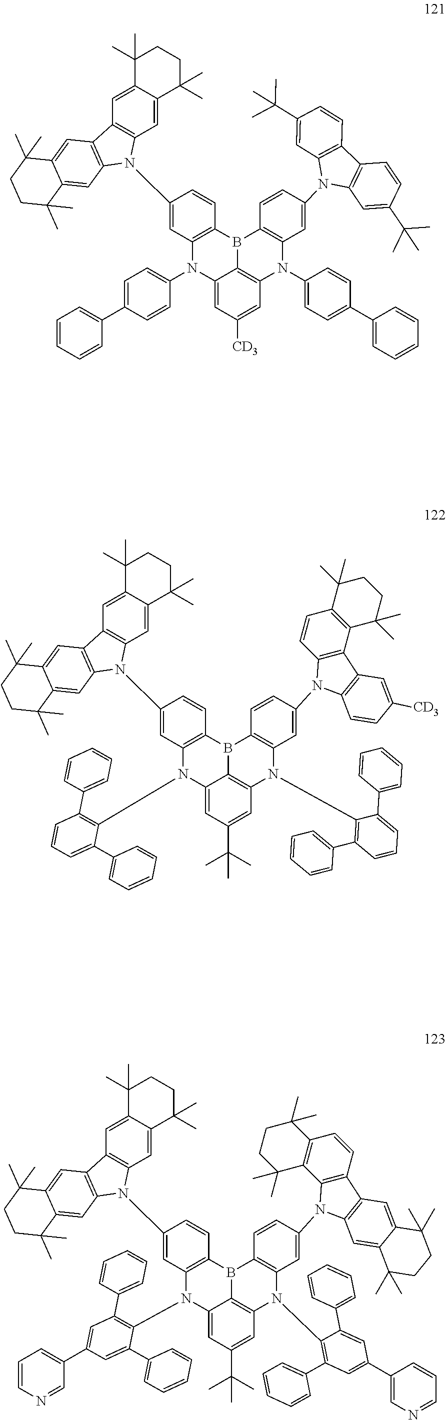

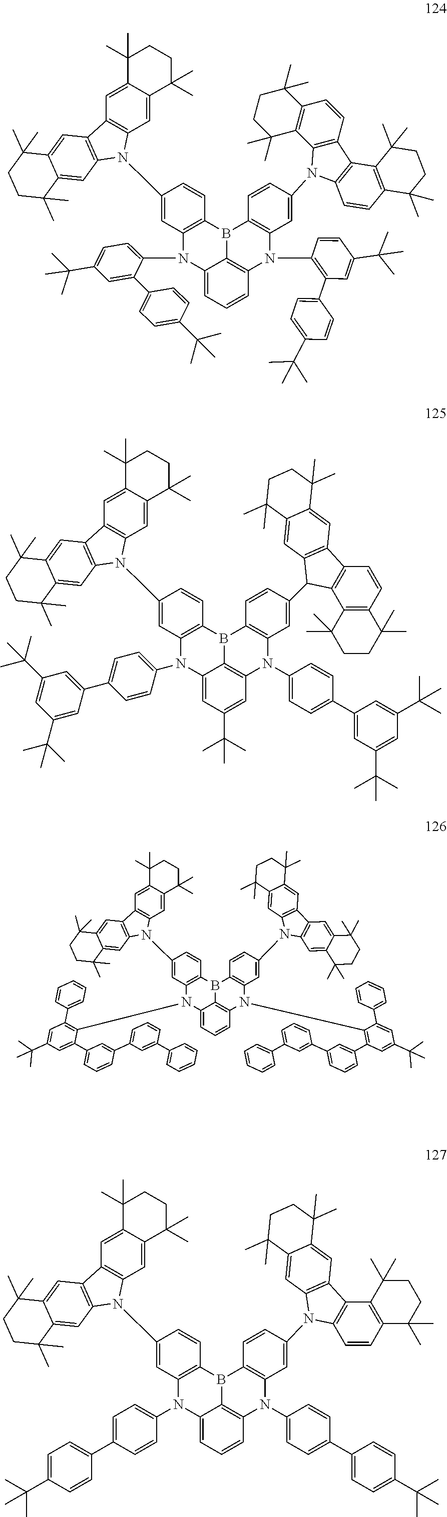

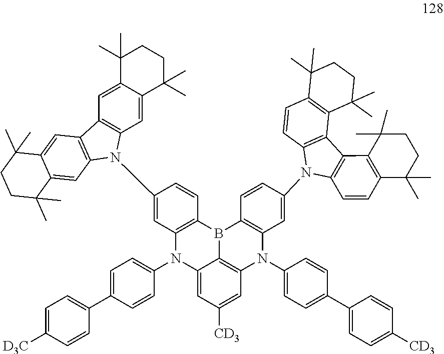 [SMILES: [2H]C([2H])([2H])c1ccc(-c2ccc(N3c4cc(-n5c6cc7c(cc6c6cc8c(cc65)C(C)(C)CCC8(C)C)C(C)(C)CCC7(C)C)ccc4B4c5ccc(-n6c7ccc8c(c7c7c9c(ccc76)C(C)(C)CCC9(C)C)C(C)(C)CCC8(C)C)cc5N(c5ccc(-c6ccc(C([2H])([2H])[2H])cc6)cc5)c5cc(C([2H])([2H])[2H])cc3c54)cc2)cc1]

In one or more embodiments, an absolute value (ΔEₛₜ) of a difference between an energy level of the lowest singlet excited state (S1 level) and an energy level of the lowest triplet excited state (T1 level) of the polycyclic compound may be about 0.39 eV or less. ΔEₛₜ may be, for example, about 0.39 eV or less, about 0.38 eV or less, or about 0.37 eV or less.

In one or more embodiments, a reverse inter-system crossover constant (K_{RISC}) of the polycyclic compound may be about 1.0×10⁵ s⁻¹ or more. The K_{RISC} may be, for example, about 1.8×10⁵ s⁻¹ or more, about 3.0×10⁵ s⁻¹ or more, or about 4.0×10⁵ s⁻¹ or more.

The K_{RISC} may be calculated, for example, based on a photoluminescence quantum yield of a prompt emission component, a life-span of the prompt emission component, a life-span of a delayed emission component, and/or a radiative decay rate constant from S1 to SO measured from a transient electroluminescence spectrum of the polycyclic compound.

In one or more embodiments, an oscillator strength (f) of the polycyclic compound may be about 0.36 or more. The oscillator strength (f) may be, for example, about 0.39 or more or about 0.40 or more.

The oscillator strength (f) may be calculated, for example, based on a non-empirical molecular orbital method and may be calculated using, for example, a Gaussian 09 program from Gaussian, Inc.

In one or more embodiments, the polycyclic compound may be used as a thermally activated delayed fluorescence (TADF) dopant, a host for a phosphorescent-emitting device, or a fluorescent host.

The polycyclic compound may further improve or enhance the luminous and life-span properties of the light-emitting device.

The polycyclic compound may provide improved or enhanced color purity from a narrow half-width due to the enhanced two or more resonance effect.

In one or more embodiments, the polycyclic compound may be used as a blue light-emitting dopant. In one or more embodiments, a maximum emission wavelength of the blue light may be, for example, in a range from about 430 nm to about 490 nm, from about 440 nm to about 480 nm, from about 440 nm to about 465 nm, or from about 445 nm to about 456 nm.

In one or more embodiments, an emission half-width of the blue light may be about 30 nm or less, about 28 nm or less, or about 25 nm or less or in a range from about 10 nm to about 30 nm or from about 10 nm to about 28 nm.

### Light-Emitting Device

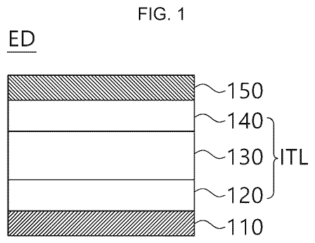

FIGS. 1 to 6 are schematic cross-sectional views illustrating light-emitting devices according to one or more embodiments.

Referring to FIG. 1, a light-emitting device ED may include a first electrode 110, a second electrode 150, and an emission layer 130 between the first electrode 110 and the second electrode 150. The emission layer 130 may include the polycyclic compound of Chemical Formula 1 as described in one or more embodiments and may have improved or enhanced color properties, luminous efficiency, and life-span properties.

The light-emitting device ED may include an intermediate layer ITL including the emission layer 130 between the first electrode 110 and the second electrode 150. The intermediate layer ITL may further include a hole transfer region 120 and an electron transfer region 140.

In one or more embodiments, a plurality of the emission layers 130 may be between the first electrode 110 and the second electrode 150, and a charge generation layer may be between adjacent emission layers. At least one selected from among the emission layers may include the polycyclic compound of Chemical Formula 1 as described in one or more embodiments. Accordingly, the light-emitting device ED may have improved or enhanced color properties, luminous efficiency, and life-span properties.

The light-emitting device ED may include two or more light-emitting structures, each of which may include the emission layer between the first electrode 110 and the second electrode 150. The light-emitting structure may include, for example, a stacked structure of the hole transfer region 120, the emission layer 130, and the electron transfer region 140. The charge generation layer may include, for example, a positive type or kind (p-type or kind) charge generation layer and/or a negative type or kind (n-type or kind) charge generation layer.

In one or more embodiments, the light-emitting device ED may be a light-emitting device of a tandem structure which may include m light-emitting structures (m may be an integer of 2 or higher) between the first electrode 110 and the second electrode 150 and (m−1) charge generation layers between the adjacent light-emitting structures.

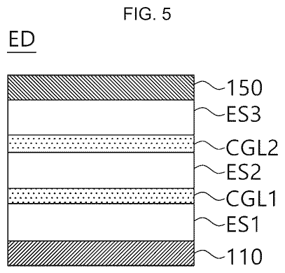

In FIG. 5, a 3-stack tandem structure including three light-emitting structures is provided, but the light-emitting device ED may have a tandem structure of two stacks, four stacks, five stacks, or more of the stacked number (e.g., a 2-stack tandem structure, a 4-stack tandem structure, a 5-stack tandem structure, or more).

The first electrode 110 may be an anode or a cathode. In one or more embodiments, the first electrode 110 may be an anode and may serve as a pixel electrode. In one or more embodiments, the first electrode 110 may include a conductive (e.g., electrically conductive) material with a high work function that promotes or enhances hole injection.

In one or more embodiments, the first electrode 110 may be a transmissive electrode. The first electrode 110 may include a transparent (e.g., substantially transparent) conductive (e.g., electrically conductive) oxide, such as indium tin oxide (ITO), indium zinc oxide (IZO), zinc oxide (e.g., ZnO), indium tin zinc oxide (ITZO), and/or the like.

In one or more embodiments, the first electrode 110 may be a translucent electrode or a reflective electrode. The first electrode 110 may include at least one selected from among silver (Ag), magnesium (Mg), copper (Cu), aluminum (AI), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), zinc (Zn), and an alloy containing at least two therefrom. For example, the first electrode 110 may include Li, Ca, LiF/Ca (a stacked structure of LiF and Ca), LiF/AI (a stacked structure of LiF and Al), a mixture of Ag and Mg, and/or the like.

The first electrode 110 may have a single-layered structure or a multi-layered structure. For example, the first electrode 110 may have a triple-layered structure of ITO/Ag/ITO.

A thickness of the first electrode 110 may be in a range of about 700 Å to about 10,000 Å. For example, the thickness of the first electrode 110 may be in a range of about 1,000 Å to about 3,000 Å.

The second electrode 150 may be a cathode or an anode. In one or more embodiments, the second electrode 150 may serve as an electron injection electrode or as a cathode. The second electrode 150 may include a metal, an alloy, an electrically conductive compound, and/or the like having a low work function.

For example, the second electrode 150 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, and/or the like. The second electrode 150 may include one selected from among the materials as described in one or more embodiments or a combination thereof.

The second electrode 150 may be a transmissive electrode, a translucent electrode, or a reflective electrode. The second electrode 150 may have a single-layered structure or a multi-layered structure.

The emission layer 130 may include the polycyclic compound of Chemical Formula 1 as described in one or more embodiments.

The polycyclic compound may be included as a host or a dopant in the emission layer 130. The polycyclic compound may serve as, for example, a thermally activated delayed fluorescence (TADF) dopant, a host for a phosphorescent light-emitting device, or a fluorescent host.

In one or more embodiments, the polycyclic compound may serve as the TADF dopant.

Accordingly, the emission layer 130 may have improved or enhanced color purity and oxidation stability.

In one or more embodiments, the polycyclic compound may include at least one selected from among the compounds represented by Chemical Formulae 1-1 to 1-6 as described in one or more embodiments.

In a non-limiting example, the emission layer 130 may include a dopant in an amount of about 0.01 parts by weight to about 15.00 parts by weight or about 0.01 parts by weight to about 12.00 parts by weight, based on 100 parts by weight of the host.

The emission layer 130 may emit a red light, a green light, a blue light, and/or a white light. For example, the emission layer 130 may emit a blue light.

In one or more embodiments, the emission layer 130 may emit a light having a maximum emission wavelength in a range from about 430 nm to about 490 nm. The maximum emission wavelength may be in a range from about 440 nm to about 480 nm, from about 440 nm to about 465 nm, or from about 445 nm to about 456 nm.

In one or more embodiments, an emission half width of the blue light may be about 30 nm or less, about 28 nm or less, about 25 nm or less or in a range from about 10 nm to about 30 nm or from about 10 nm to about 28 nm.

The emission layer 130 may further include a host material and/or a dopant as will be described herein.

For example, the emission layer 130 may further include a host material that is generally available or generally used in the related art, such as an anthracene derivative, a pyrene derivative, a fluoranthene derivative, a chrysene derivative, a dihydrobenzanthracene derivative, a triphenylene derivative, and/or the like.

In one or more embodiments, the emission layer 130 may include, for example, a host material represented by Chemical Formula FH. For example, the compound represented by Chemical Formula FH may be used as a fluorescent host material.

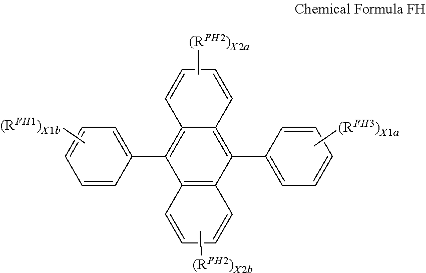

In Chemical Formula FH, R^{FH1} to R^{FH4} may each independently be a hydrogen atom, a deuterium atom, a halogen atom, a substituted or unsubstituted silyl group, a substituted or unsubstituted thio group, a substituted or unsubstituted oxy group, a substituted or unsubstituted C₁-C₁₀ alkyl group, a substituted or unsubstituted C₂-C₁₀ alkenyl group, a substituted or unsubstituted C₆-C₃₀ aryl group, a substituted or unsubstituted C₆-C₃₀ heteroaryl group, or a cyclic group formed through a combination thereof. In one or more embodiments, in Chemical Formula FH, at least one selected from among R^{FH1} to R^{FH4} may form a condensed ring with a bonded benzene ring.

In Chemical Formula FH, x1a and x1b may each independently be an integer of 0 to 5; and x2a and x2b may each independently be an integer of 0 to 4. If (e.g., when) x1a, x1 b, x2a, and x2b are each 2 or more, two or more of each of R^{FH1} to R^{FH4} may be the same as or different from each other.

In one or more embodiments, the emission layer 130 may include, for example, a host material represented by Chemical Formula PH. For example, the compound represented by Chemical Formula PH may be used as a host material for a phosphorescent device.

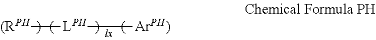

In Chemical Formula PH, R^{PH} may be a substituted or unsubstituted carbazole group. L^{PH} may be a direct linkage, a substituted or unsubstituted C₆-C₃₀ arylene group, or a substituted or unsubstituted C₂-C₃₀ heteroarylene group. Ar^{PH} may be a substituted or unsubstituted C₆-C₃₀ aryl group or a substituted or unsubstituted C₂-C₃₀ heteroaryl group.

As described in one or more embodiments, the term “C₆-C₃₀ aryl group” may encompass a group in which two or more aryl rings are condensed or bonded through a cyclic group (e.g., an alicyclic hydrocarbon ring group). For example, a C₆-C₃₀ aryl group may be a fluorenyl group.

As described in one or more embodiments, the term “C₂-C₃₀ heteroaryl group” may encompass a group in which two or more aryl rings are condensed or bonded through a heterocyclic ring. For example, a C₂-C₃₀ heteroaryl group may be a carbazole group, a dibenzofuran group, a dibenzothiophene group, and/or the like. In one or more embodiments, a C₂-C₃₀ heteroaryl group may be a group in which two or more aryl rings are condensed or bonded to each other through the same or different heterocyclic rings.

In one or more embodiments, a substituent included in Ar^{PH} may be a silyl group represented by —Si(R^{sa})(R^{sb})(R^{sc}); and R^{sa}, R^{sb}, and R^{sc} may each independently be hydrogen, a halogen, a hydroxyl group, a C₁-C₆₀ alkyl group, a C₁-C₆₀ alkoxy group, a C₆-C₆₀ aryl group, or a C₂-C₃₀ heteroaryl group. At least one selected from among R^{sa}, R^{sb}, and R^{sc} may be a C₆-C₆₀ aryl group or a C₂-C₃₀ heteroaryl group. For example, R^{sa}, R^{sb}, and R^{sc} may each independently be a C₆-C₆₀ aryl group or a C₂-C₃₀ heteroaryl group.

In Chemical Formula PH, Ix may be an integer of 0 to 10. If (e.g., when) Ix is 2 or more, two or more of L^{PH} may be the same as or different from each other.

The emission layer 130 may include, for example, bis(4-(9H-carbazol-9-yl) phenyl) diphenylsilane (BCPDS), (4-(1-(4-(diphenylamino)phenyl)cyclohexyl)phenyl) diphenyl-phosphine oxide) (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2,8-bis(diphenylphosphoryl) dibenzo[b,d]furan (PPF), 4,4′,4″-tris(carbazol-9-yl)-triphenylamine (TCTA), 1,3,5-tris(1-phenyl-1H-benzo[d]imidazole-2-yl)benzene (TPBi), tris(8-hydroxyquinolino) aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO3), octaphenylcyclotetrasiloxane (DPSiO4), and/or the like, as a host material.

In one or more embodiments, in the emission layer 130, the host may include one selected from among the materials as described in one or more embodiments or any combination thereof.

Non-limiting examples of compounds represented by Chemical Formula PH are as follows.

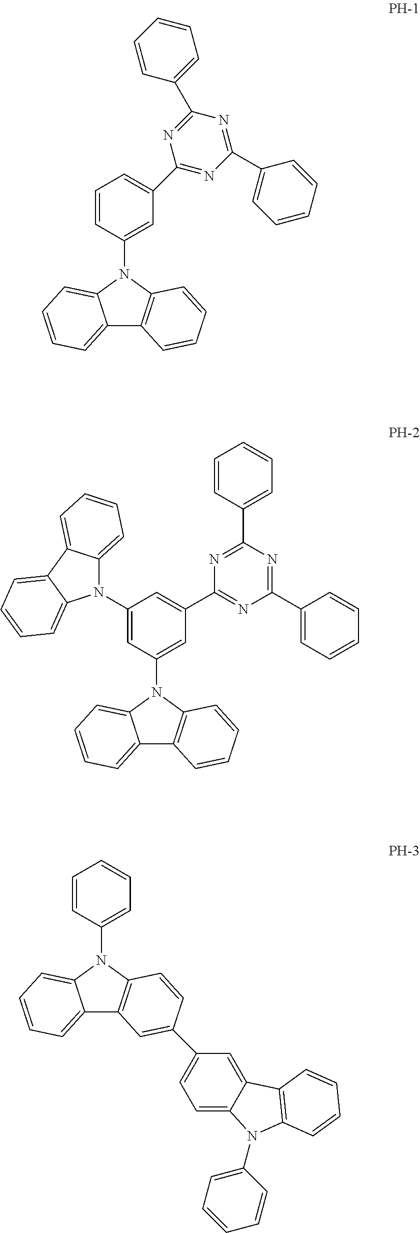 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1ccc(-n2c3ccccc3c3cc(-c4ccc5c(c4)c4ccccc4n5-c4ccccc4)ccc32)cc1]

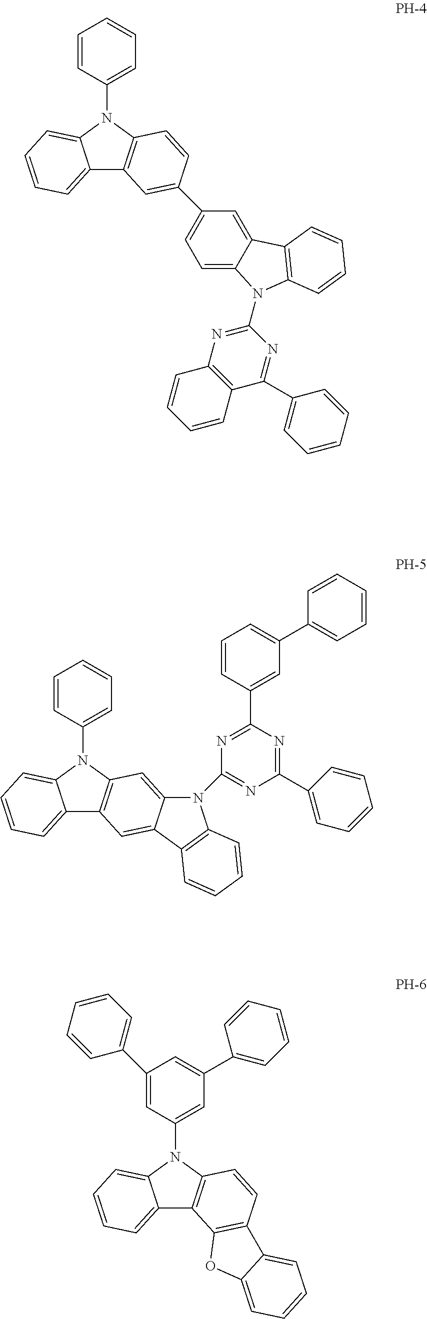 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-c3ccccc3)cc(-n3c4ccccc4c4c5oc6ccccc6c5ccc43)c2)cc1]

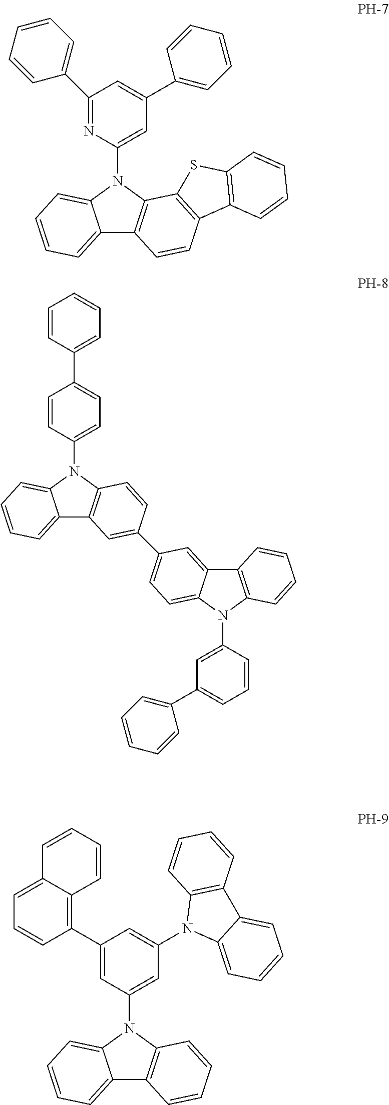

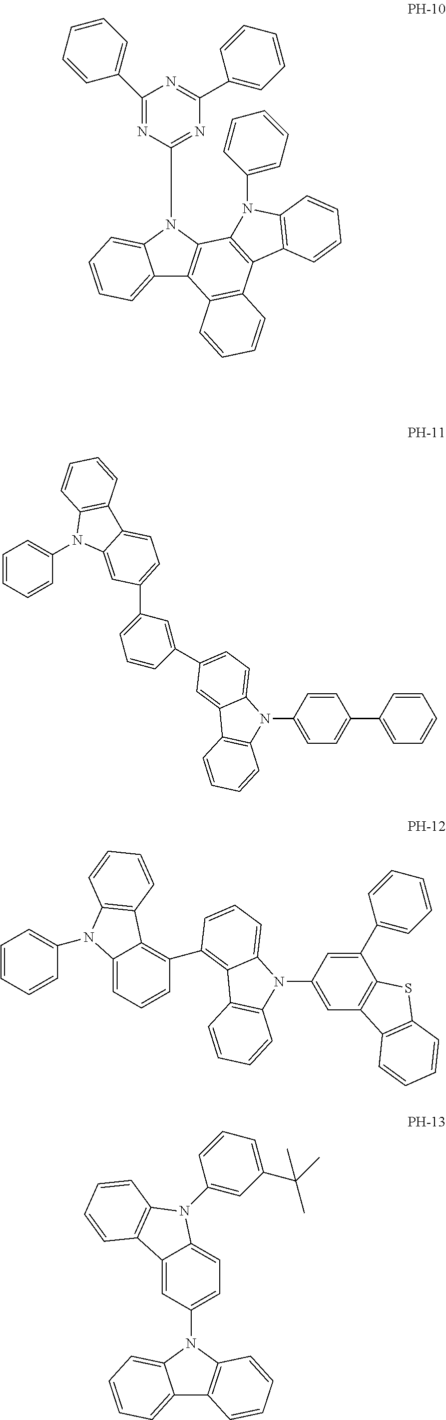 [SMILES: c1ccc(-c2nc(-c3ccccc3)nc(-n3c4ccccc4c4c5ccccc5c5c6ccccc6n(-c6ccccc6)c5c43)n2)cc1 ; c1ccc(-c2ccc(-n3c4ccccc4c4cc(-c5cccc(-c6ccc7c8ccccc8n(-c8ccccc8)c7c6)c5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; CC(C)(C)c1cccc(-n2c3ccccc3c3cc(-n4c5ccccc5c5ccccc54)ccc32)c1]

The emission layer 130 may further include a dopant that interacts with the host.

In one or more embodiments, the emission layer 130 may include a dopant represented by Chemical Formula FD. For example, the compound represented by Chemical Formula FD may be used as a fluorescent dopant.

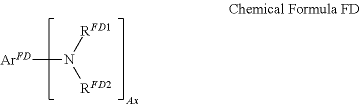

In Chemical Formula FD, Ar^{FD}, R^{FD1}, and R^{FD2} may each independently be a substituted or unsubstituted C₃-C₆₀ carbocyclic group or a substituted or unsubstituted C₁-C₆₀ heterocyclic group. Ax may be an integer of 1 to 6.

In one or more embodiments, Ar^{FD} may include a condensed ring structure in which three or more aryl rings or benzene rings are condensed together (e.g., an anthracene group, a chrysene group, a pyrene group, and/or the like).

In one or more embodiments, the emission layer 130 may include a dopant for a phosphorescent device. The dopant for the phosphorescent device may include an organometallic compound that includes a central metal and at least one ligand bonded to the central metal via a coordination bond. The central metal may include, for example, a transition metal, and the ligand may include, for example, a monodentate ligand, a bidentate ligand, a tridentate ligand, a tetradentate ligand, a pentadentate ligand, a hexadentate ligand, or a combination thereof.

The dopant for the phosphorescent device may include, for example, a compound represented by Chemical Formula PD.

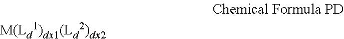

In Chemical Formula PD, M may be a transition metal atom, for example, iridium (Ir), platinum (Pt), palladium (Pd), osmium (Os), titanium (Ti), gold (Au), hafnium (Hf), europium (Eu), terbium (Tb), rhodium (Rh), rhenium (Re), ruthenium (Ru), copper (Cu), or thulium (Tm).

In Chemical Formula PD, L_{d}¹ may be a ligand represented by Chemical Formula LD1.

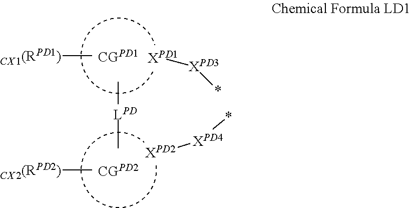

In Chemical Formula LD1, X^{PD1} and X^{PD2} may each independently be C or N.

In one or more embodiments, one selected from X^{PD1} and X^{PD2} may be C, and the other may be N. In one or more embodiments, X^{PD1} and X^{PD2} may each be N.

In Chemical Formula LD1, CG^{PD1} and CG^{PD2} may each independently be a substituted or unsubstituted C₃-C₆₀ carbocyclic group or a substituted or unsubstituted C₁-C⁶⁰ heterocyclic group.

For example, CG^{PD1} and CG^{PD2} may each independently be a pyrrole group, a pyrazole group, an imidazole group, a triazole group, an oxazole group, an isoxazole group, a thiazole group, an isothiazole group, an oxadiazole group or a thiadiazole group, a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinapthofuran group, an azadinapthothiophene group, an azadibenzocarbazole group, an azadibenzofluorene group, or an azadinapthosilole group.

In Chemical Formula LD1, L^{PD} may be a single bond (e.g., a single covalent bond), a substituted or unsubstituted methylene group, a substituted or unsubstituted ethylene group, *—O—*′, *—S—*′, *—C(═O)—*′, *—N(R^{PD3})—*′, *—C(R^{PD4})═*′ or *═C(R^{PD5})—*′.

In Chemical Formula LD1, X^{PD3} and X^{PD4} may each independently be a chemical bond, O, S, N(R^{PD6}), B(R^{PD7}), P(R^{PD8}), C(R^{PD8})(R^{PD9}), or Si(R^{PD10})(R^{PD11}). The chemical bond may be, for example, a covalent bond or a coordination bond.

In Chemical Formula LD1, R^{PD1} and R^{PD2} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, a substituted or unsubstituted silyl group, a substituted or unsubstituted amine group, a substituted or unsubstituted aniline group, —B(R^{PD12})(R^{PD13}), —C(═O)(R^{PD14}), —S(═O)₂(R^{PD15}), or —P(═O)(R^{PD16})(R^{PD17}). The silyl group may be represented by —Si(R^{sa})(R^{sb})(R^{sc}), as described in one or more embodiments.

R^{PD3} to R^{PD17} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, or a substituted or unsubstituted C₈-C₆₀ condensed polycyclic group.

In Chemical Formula LD1, cx1 and cx2 may each independently be an integer of 0 to 10. If (e.g., when) at least one selected from cx1 and cx2 is 2 or more, two or more of R^{PD1} or two or more of R^{PD2} may be the same as or different from each other.

The symbols -* and -*′ each represent a binding site where the ligand represented by Chemical Formula LD1 bonds to M.

In Chemical Formula PD, dx1 may be an integer of 1 to 3. If (e.g., when) dx1 is 2 or 3, two or three of L_{d}¹ may be the same as or different from each other. Among two or three of L_{d}¹, CG^{PD1}, and/or CG^{PD2} adjacent to each other may be connected to each other through a connecting group, such as L^{PD1}, L^{PD2}, and/or the like. The connecting group, such as L^{PD1}, L^{PD2}, and/or the like, may each independently be the same as defined with respect to L^{PD}.

In Chemical Formula PD, L_{d}² may be an organic ligand. L_{d}² may include, for example, a halogen group, CO, NO, CS, picolinate, acetate, oxalate, a diketone group, an isonitrile group, isothiocyanato-N, thiosulphato-S, an alkyl phosphine, phenylphosphine, an aryl phosphine, phosphine oxide, phosphite, or a combination thereof.

In Chemical Formula PD, dx2 may be an integer of 1 to 4. If (e.g., when) dx2 is 2 or more, two or more of L_{d}² may be the same as or different from each other.

Non-limiting examples of the compound represented by Chemical Formula PD are as follows.

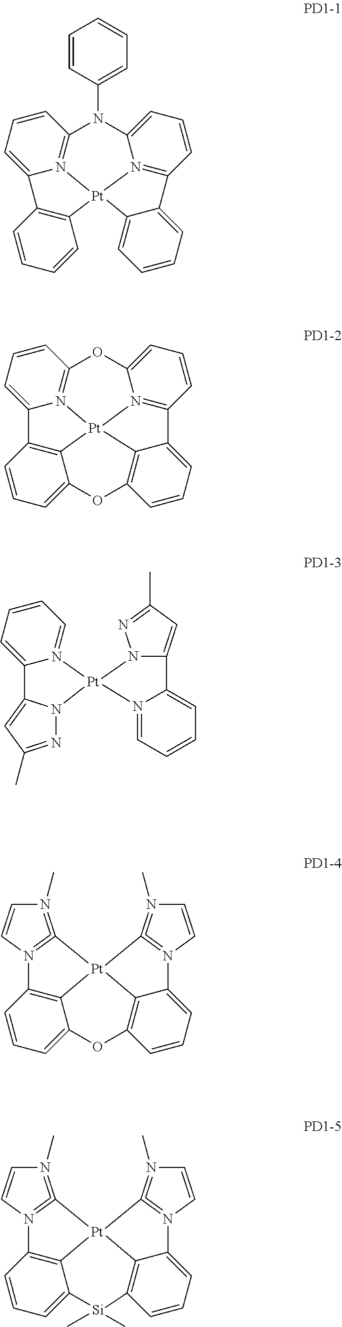

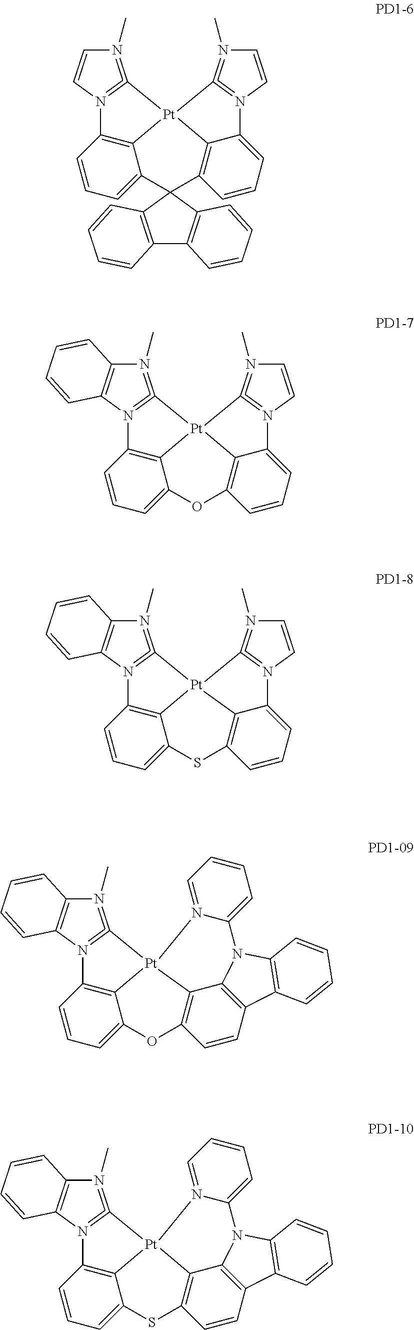

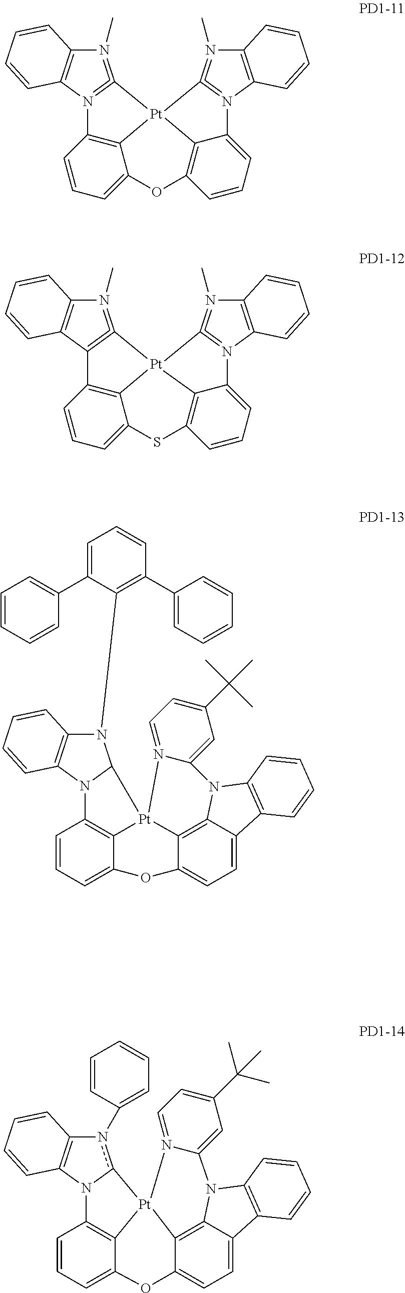

In one or more embodiments, the emission layer 130 may include a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (NBDAVBi), and/or the like), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP) and/or the like), pyrene or a derivative thereof (e.g., 1,1-dipyrene, 1,4-dipyrenylbenzene, 1,4-bis(N,N-diphenylamino)pyrene), and/or the like), and/or the like, as a fluorescent dopant material.

The emission layer 130 may include a metal complex that includes iridium (Ir), platinum (Pt), osmium (Os), gold (Au), titanium (Ti), zirconium (Zr), hafnium (Hf), europium (Eu), terbium (Tb), and/or thulium (Tm) as a phosphorescent dopant, in addition to the materials as described in one or more embodiments. For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Flr6), platinum octaethyl porphyrin (PtOEP), and/or the like may be used as a phosphorescent dopant.

In one or more embodiments, the emission layer 130 may include a boron-containing dopant represented by Chemical Formula BD.

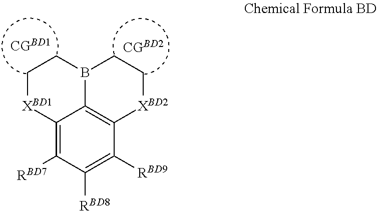

In Chemical Formula BD, X^{BD1} and X^{BD2} may each independently be N(R^{BD1}), P(R^{BD2}), C(R^{BD3})(R^{BD4}), Si(R^{BD5})(R^{BD6}), S or O. In one or more embodiments, X^{BD1} and X^{BD2} may each be N(R^{BD1}). R^{BD1} to R^{BD6} may each independently be hydrogen, deuterium, a substituted or unsubstituted C₁-C₂₀ alkyl group, a substituted or unsubstituted C₆-C₃₀ aryl group, or a substituted or unsubstituted C₂-C₃₀ heteroaryl group. R^{BD7}, R^{BD8}, and R^{BD9} may each independently be hydrogen, deuterium, halogen, a cyano group, a substituted or unsubstituted amine group, a substituted or unsubstituted boryl group, a substituted or unsubstituted oxy group, a substituted or unsubstituted thio group, a substituted or unsubstituted C₁-C₂₀ alkyl group, a substituted or unsubstituted C₆-C₆₀ aryl group, or a substituted or unsubstituted C₂-C₃₀ heteroaryl group. R^{BD7}, R^{BD8}, and/or R^{BD9} may be bonded to an adjacent group to form a ring.

In Chemical Formula BD, CG^{BD1} and CG^{BD2} represent a cyclic group, and CG^{BD1} and CG^{BD2} may each independently be a substituted or unsubstituted C₃-C₆₀ carbocyclic group or a substituted or unsubstituted C₁-C₆₀ heterocyclic group. In one or more embodiments, CG^{BD1} and CG^{BD2} may each independently be a substituted or unsubstituted C₆-C₃₀ aryl group or a substituted or unsubstituted C₂-C₃₀ heteroaryl group.

In one or more embodiments, CG^{BD1} and CG^{BD2} may each independently be a substituted or unsubstituted benzene ring. In one or more embodiments, the boron-containing dopant may serve as a thermally activated delayed fluorescence (TADF) dopant.

In one or more embodiments, one selected from CG^{BD1} and CG^{BD2} may be a non-condensed aryl group or a non-condensed heteroaryl group, and the other one thereof may be a condensed polycyclic aryl group or a condensed polycyclic heteroaryl group. In one or more embodiments, the boron-containing dopant may serve as a fluorescent dopant.

In one or more embodiments, the emission layer 130 may include one selected from among the dopant materials as described in one or more embodiments or any combination thereof.

In one or more embodiments, the emission layer 130 may include two or more host materials. For example, the emission layer 130 may include a hole transporting host and an electron transporting host. In one or more embodiments, the emission layer 130 may include a hole transporting host, an electron transporting host, a photosensitive agent, and a dopant. In one or more embodiments, the hole transporting host and the electron transporting host may form an exciplex, and energy may be transferred from the exciplex to the photosensitive agent and from the photosensitive agent to the dopant, thereby inducing a light emission.

Non-limiting examples of the hole transporting host may include a compound represented by Chemical Formula HT as described in one or more embodiments. Non-limiting examples of the electron transporting host may include a compound represented by Chemical Formula ET as described in one or more embodiments.

In one or more embodiments, the emission layer 130 may include quantum dots. A quantum dot may include Examples of a Group II-VI compound, a Group III-VI compound, a Group I-III-VI compound, a Group III-V group compound, a Group III-II-V group compound, a Group IV-VI compound, a Group IV element, a Group IV compound, or a combination thereof.

The quantum dot may include a core that includes the compound as described in one or more embodiments, and a shell around (e.g., surrounding) the core. The shell may include an inorganic oxide and/or a semiconductor compound. Examples of the semiconductor compound may include CdS, CdSe, CdTe, ZnS, ZnSe, ZnTe, ZnSe, ZnTeS, GaAs, GaP, GaSb, HgS, HgSe, HgTe, InAs, InP, InGaP, InSb, AlAs, AlP, AlSb, and/or the like.

In one or more embodiments, a color of light from a quantum dot may be adjusted according to a particle size of the quantum dot. The quantum dot may be a blue quantum dot, a red quantum dot, or a green quantum dot.

The hole transfer region 120 may be between the first electrode 110 and the emission layer 130. The hole transfer region 120 may have a single-layered structure or a multi-layered structure including different materials.

The hole transfer region 120 may include a hole injection layer, a hole transport layer, and/or an electron blocking layer and may further include an auxiliary emission layer.

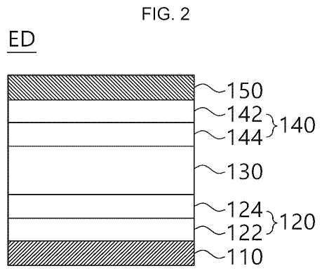

In one or more embodiments, as illustrated in FIG. 2, the hole transfer region 120 may include a hole injection layer 122 and a hole transport layer 124, sequentially stacked from the first electrode 110.

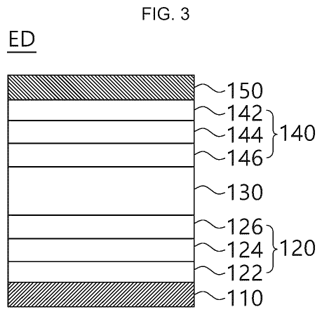

In one or more embodiments, as illustrated in FIG. 3, the hole transfer region 120 may include a hole injection layer 122, a hole transport layer 124, and an electron blocking layer 126, sequentially stacked from the first electrode 110. The electron blocking layer 126 may block electrons from the electron transfer region 140 to the hole transfer region 120. Accordingly, the generation of excitons in the emission layer 130 may be increased or enhanced, and light-emission efficiency may be further increased or enhanced.

For example, the hole transfer region 120 may include a compound represented by Chemical Formula HT.

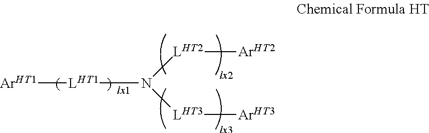

In Chemical Formula HT, L^{HT1}, L^{HT2}, and L^{HT3} may each independently be a direct linkage, a substituted or unsubstituted C₆-C₃₀ arylene group, or a substituted or unsubstituted C₂-C₃₀ heteroarylene group.

In Chemical Formula HT, Ix1 to Ix3 may each independently be an integer of 0 to 10. If (e.g., when) Ix1, Ix2, or Ix3 is 2 or more, two or more of each of L^{HT3}, L^{HT1}, or L^{HT2}, respectively, may be directly connected by, for example, carbon atoms (e.g., sp2 carbons) of each aryl ring, to form a substituted or unsubstituted C₆-C₃₀ arylene group or a substituted or unsubstituted C₂-C₃₀ heteroarylene group.

In Chemical Formula HT, Ar^{HT1} and Ar^{HT2} may each independently be a substituted or unsubstituted C₆-C₃₀ aryl group or a substituted or unsubstituted C₂-C₃₀ heteroaryl group. Ar^{HT3} may be a substituted or unsubstituted C₆-C₃₀ aryl group.

In one or more embodiments, the compound represented by Chemical Formula HT may be a monoamine compound. In one or more embodiments, the compound represented by Chemical Formula HT may be a diamine compound in which at least one selected from among Ar^{HT1} to Ar^{HT3} includes an amine group as a substituent.

In one or more embodiments, the compound represented by Chemical Formula HT may be a carbazole-based compound in which at least one selected from Ar^{HT1} and Ar^{HT2} includes a substituted or unsubstituted carbazole group or a fluorene-based compound in which at least one selected from Ar^{HT1} and Ar^{HT2} includes a substituted or unsubstituted fluorene group.

In one or more embodiments, two adjacent groups selected from among Ar^{HT1} to Ar^{HT3} may be condensed together to form a ring.

Non-limiting examples of the compound represented by the formula HT are as follows.

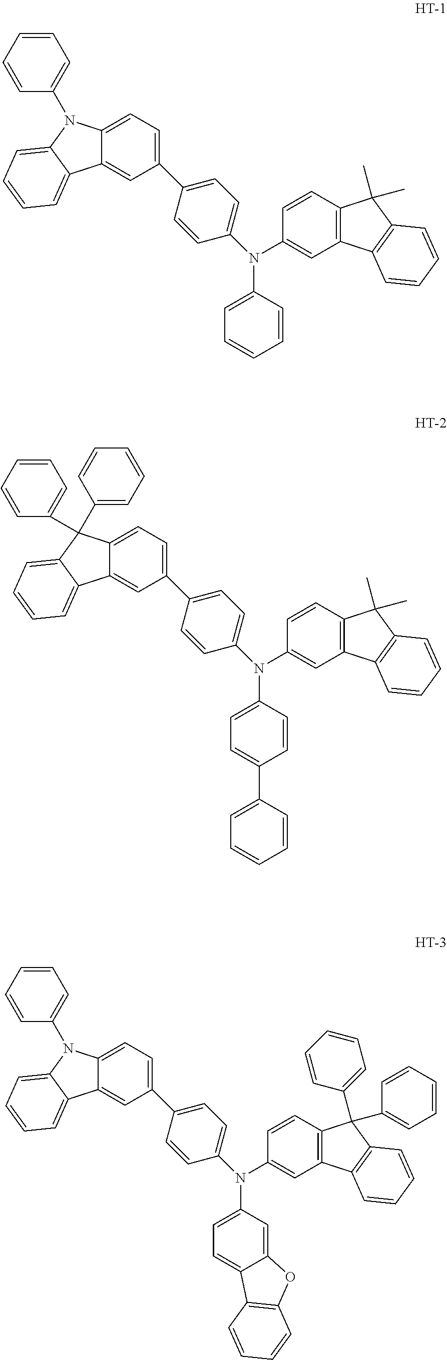 [SMILES: CC1(C)c2ccccc2-c2cc(N(c3ccccc3)c3ccc(-c4ccc5c(c4)c4ccccc4n5-c4ccccc4)cc3)ccc21 ; CC1(C)c2ccccc2-c2cc(N(c3ccc(-c4ccccc4)cc3)c3ccc(-c4ccc5c(c4)-c4ccccc4C5(c4ccccc4)c4ccccc4)cc3)ccc21 ; c1ccc(-n2c3ccccc3c3cc(-c4ccc(N(c5ccc6c(c5)-c5ccccc5C6(c5ccccc5)c5ccccc5)c5ccc6c(c5)oc5ccccc56)cc4)ccc32)cc1]

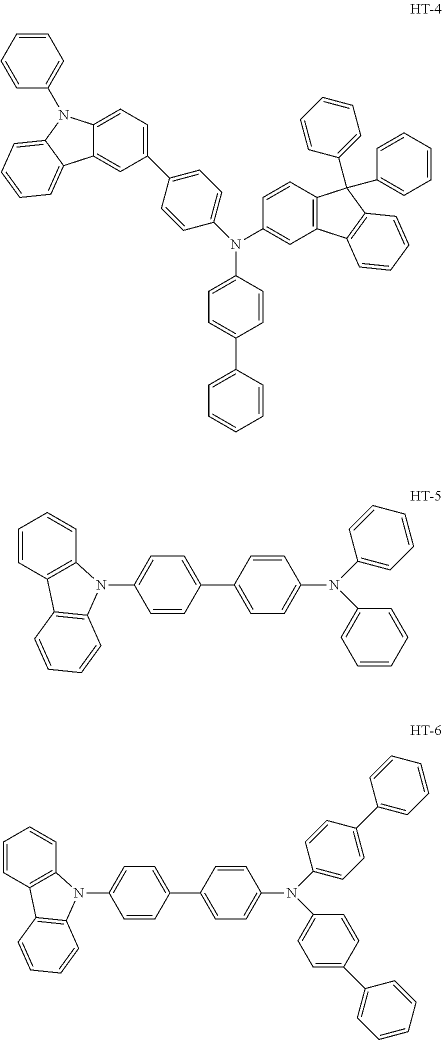 [SMILES: c1ccc(-c2ccc(N(c3ccc(-c4ccc5c(c4)c4ccccc4n5-c4ccccc4)cc3)c3ccc4c(c3)-c3ccccc3C4(c3ccccc3)c3ccccc3)cc2)cc1 ; c1ccc(N(c2ccccc2)c2ccc(-c3ccc(-n4c5ccccc5c5ccccc54)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

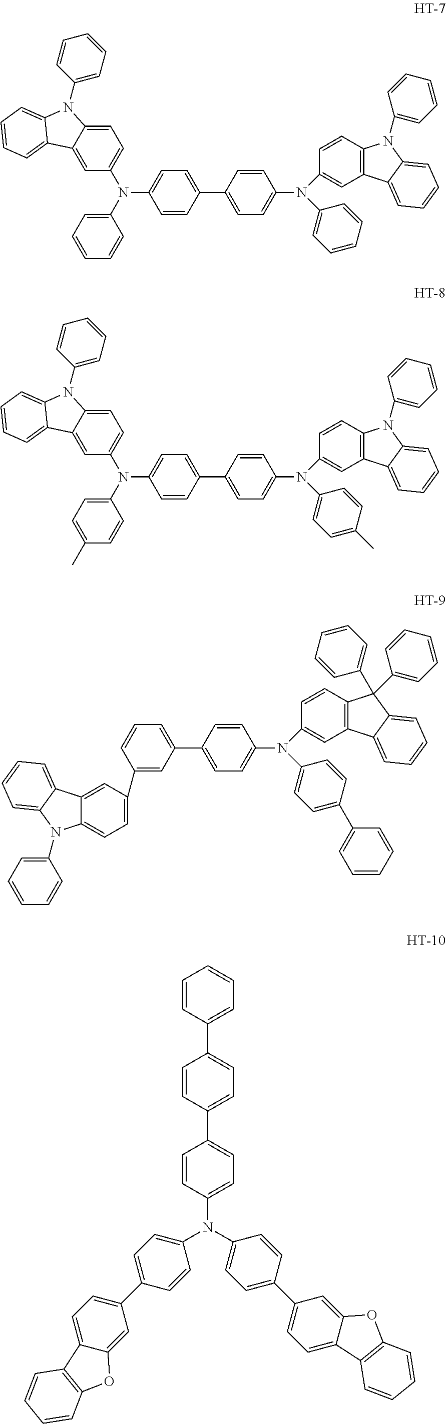 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; c1ccc(-c2ccc(N(c3ccc(-c4cccc(-c5ccc6c(c5)c5ccccc5n6-c5ccccc5)c4)cc3)c3ccc4c(c3)-c3ccccc3C4(c3ccccc3)c3ccccc3)cc2)cc1 ; c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1]

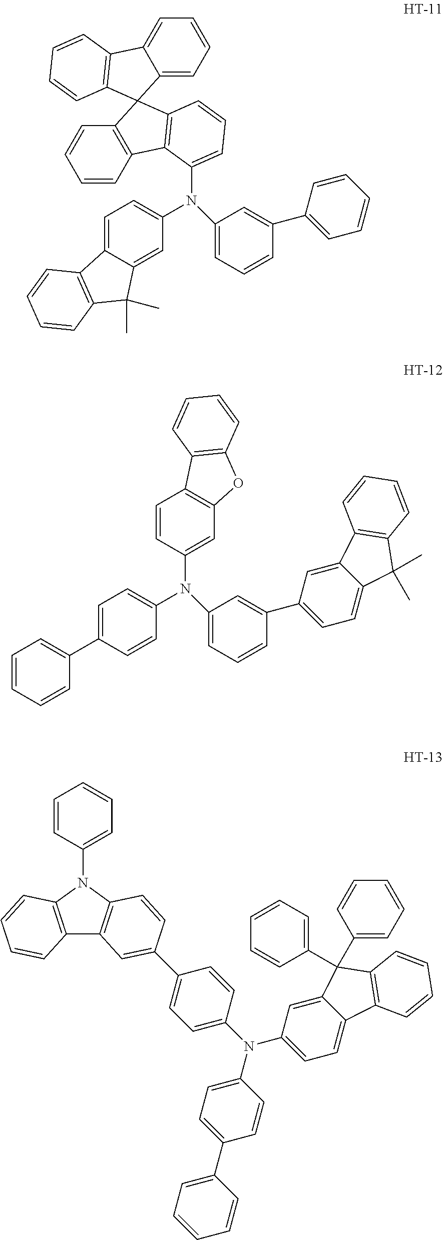 [SMILES: CC1(C)c2ccccc2-c2ccc(N(c3cccc(-c4ccccc4)c3)c3cccc4c3-c3ccccc3C43c4ccccc4-c4ccccc43)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

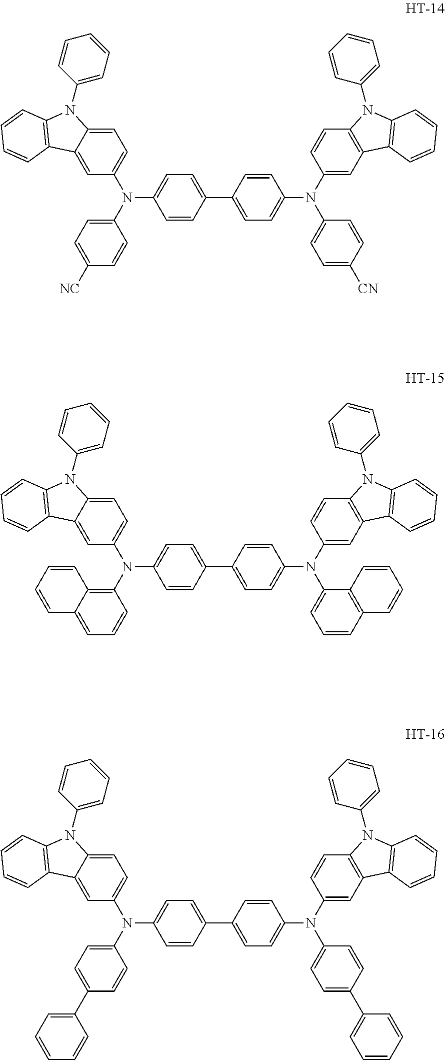 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

For example, the hole transfer region 120 may include 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), N,N′-di(naphthalene-1-yl)-N,N′-diphenyl-benzidine (NPB), N,N′-bis(3-methylphenyl)-N,N′-diphenyl-[1,1′-biphenyl]-4,4′-diamine (TPD), Spiro-TPD, Spiro-NPB, N¹,N^{1′}-([1,1′-biphenyl]-4,4′-diyl)bis(N¹-phenyl-N⁴,N⁴-di-m-tolylbenzene-1,4-diamine (DNTPD), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a phthalocyanine compound, a carbazole compound (e.g., N-phenylcarbazole, polyvinylcarbazole, and/or the like), a fluorene compound, and/or the like. The hole transfer region 120 may include one selected from among the hole transfer materials as described in one or more embodiments or a combination thereof.

The hole transfer materials as described in one or more embodiments may be included in at least one selected from among the hole injection layer 122, the hole transport layer 124, and the electron blocking layer 126.

The hole transfer region 120 may further include a charge generating material. The charge generating material may be a dopant material, such as a p-dopant, so that conductivity (e.g., electrical conductivity) of the hole transfer region 120 may be improved or enhanced.

Examples of dopant materials may include a halogenated metal compound, such as LiF, NaCl, CsF, RbCl, RbI, CuI, and/or KI; a quinone derivative, such as tetracyanoquinodimethane (TCNQ), 2,3,5,6-tetrafluoro-7,7,8,8-tetracyanoquinodimethane (F4-TCNQ), and/or the like; a cyano-containing compound, such as dipyrazino[2,3-f: 2′,3′-h]quinoxaline-2,3,6,7,10,11-hexacarbonitrile (HATCN), 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like; a tungsten (W) oxide; a molybdenum (Mo) oxide; and/or the like. The hole transfer region 120 may include one selected from among the dopant materials as described in one or more embodiments or a combination thereof.

A thickness of the hole transfer region 120 may be in a range of about 100 Å to about 10,000 Å. For example, the thickness of the hole transfer region 120 may be in a range of about 100 Å to about 1,500 Å.

If (e.g., when) the hole transfer region 120 includes the hole injection layer 122 or the hole transport layer 124, a thickness of the hole injection layer 122 may be in a range from about 100 Å to about 9,000 Å, from about 100 Å to about 3,000 Å, or from about 100 Å to about 1,000 Å. A thickness of the hole transport layer 124 may be in a range from 50 Å to about 2,000 Å, from about 100 Å to about 1,500 Å, from about 100 Å to about 1,000 Å, or from about 100 Å to about 600 Å.

In the thickness ranges as described in one or more embodiments, hole transfer properties may be enhanced even at a low voltage operation, and a life-span of the device may be further improved or enhanced.

Each layer of the hole transfer region 120 may be formed or provided by a process, such as a vacuum deposition, a spin coating, an inkjet printing, a laser printing, a casting, a laser thermal transfer, and/or the like.

The electron transfer region 140 may be between the second electrode 150 and the emission layer 130. The electron transfer region 140 may have a single-layered structure or a multi-layered structure including different materials.

The electron transfer region 140 may include an electron injection layer, an electron transport layer, and/or a hole blocking layer and may further include an auxiliary emission layer.

In one or more embodiments, as illustrated in FIG. 2, the electron transfer region 140 may include an electron injection layer 142 and an electron transport layer 144, stacked from the second electrode 150 to the emission layer 130.

In one or more embodiments, as illustrated in FIG. 3, the electron transfer region 140 may include an electron injection layer 142, an electron transport layer 144, and a hole blocking layer 146, stacked from the second electrode 150 to the emission layer 130. The hole blocking layer 146 may block or suppress (or reduce) holes from the hole transfer region 120. Accordingly, emission energy and luminescence efficiency in the emission layer 130 may be further improved or enhanced.

For example, the hole transfer region 140 may include a compound represented by Chemical Formula ET.

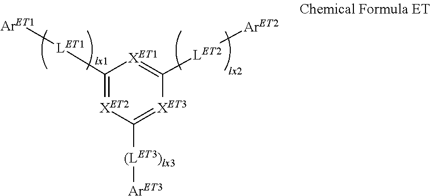

In Chemical Formula ET, at least one selected from among X^{ET1} to X^{ET3} may be N; and the remainder of X^{ET1} to X^{ET3} may each independently be C(R_{ET}). R_{ET} may be a hydrogen atom, a deuterium atom, a substituted or unsubstituted C₁-C₂₀ alkyl group, a substituted or unsubstituted C₆-C₆₀ aryl group, or a substituted or unsubstituted C₂-C₆₀ heteroaryl group.

If (e.g., when) one selected from among X^{ET1} to X^{ET3} is N, the compound represented by Chemical Formula ET may include a pyridine group. If (e.g., when) two selected from among X^{ET1} to X^{ET3} are N, the compound represented by Chemical Formula ET may include a pyrimidine group. If (e.g., when) X^{ET1} to X^{ET3} are each N, the compound represented by Chemical Formula ET may include a triazine group.

In Chemical Formula ET, Ix1 to Ix3 may each independently be an integer of 0 to 10. L^{ET1} to L^{ET3} may each independently be a direct linkage, a substituted or unsubstituted C₆-C₃₀ arylene group, or a substituted or unsubstituted C₂-C₃₀ heteroarylene group.

If (e.g., when) Ix1, Ix2, or Ix3 is 2 or more, two or more of each of L^{ET}1, L^{ET2}, or L^{ET3}, respectively, may be directly linked together, for example, by carbon atoms of each aryl ring (e.g., sp2 carbons), to form a substituted or unsubstituted C₆-C₃₀ arylene group or a substituted or unsubstituted C₂-C₃₀ heteroarylene group.

In Chemical Formula ET, Ar^{ET1} to Ar^{ET3} may each independently be a hydrogen atom, a deuterium atom, a substituted or unsubstituted C₁-C₂₀ alkyl group, a substituted or unsubstituted C₆-C₃₀ aryl group, or a substituted or unsubstituted C₂-C₃₀ heteroaryl group. For example, Ar^{ET1} to Ar^{ET3} may each independently be a substituted or unsubstituted phenyl group, a substituted or unsubstituted carbazole group, a substituted or unsubstituted fluorene group, or a substituted or unsubstituted silyl group. The silyl group may be represented by —Si(R^{sa})(R^{sb})(R^{sc}), as described in one or more embodiments.

Non-limiting examples of compounds represented by the formula ET are as follows.

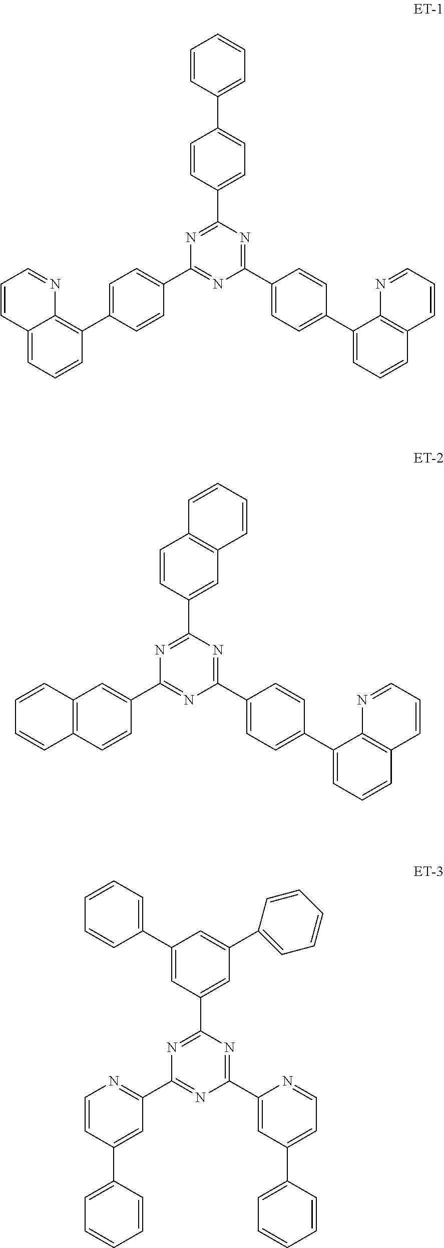 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; c1ccc(-c2cc(-c3ccccc3)cc(-c3nc(-c4cc(-c5ccccc5)ccn4)nc(-c4cc(-c5ccccc5)ccn4)n3)c2)cc1]

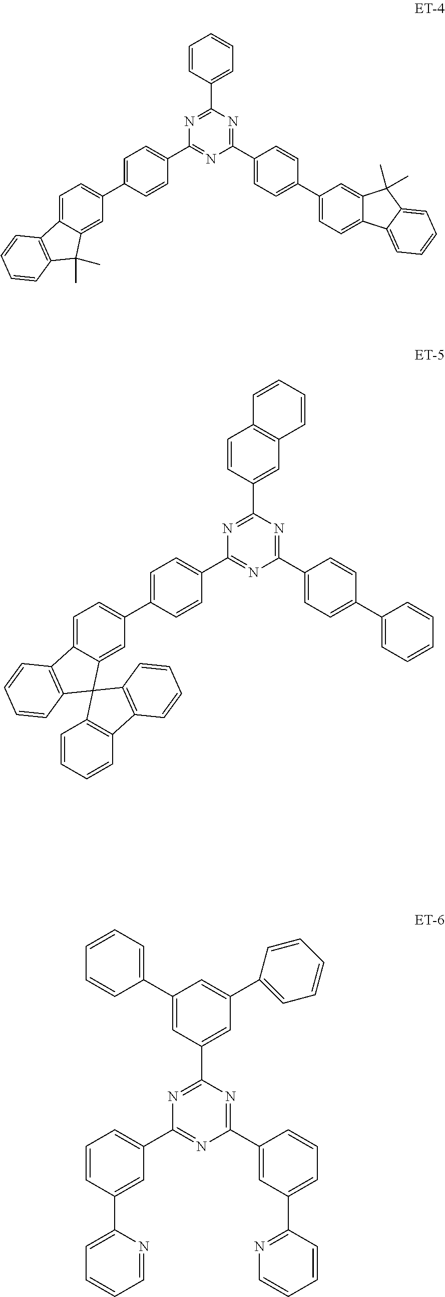 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc(-c5ccc6c(c5)C5(c7ccccc7-c7ccccc75)c5ccccc5-6)cc4)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

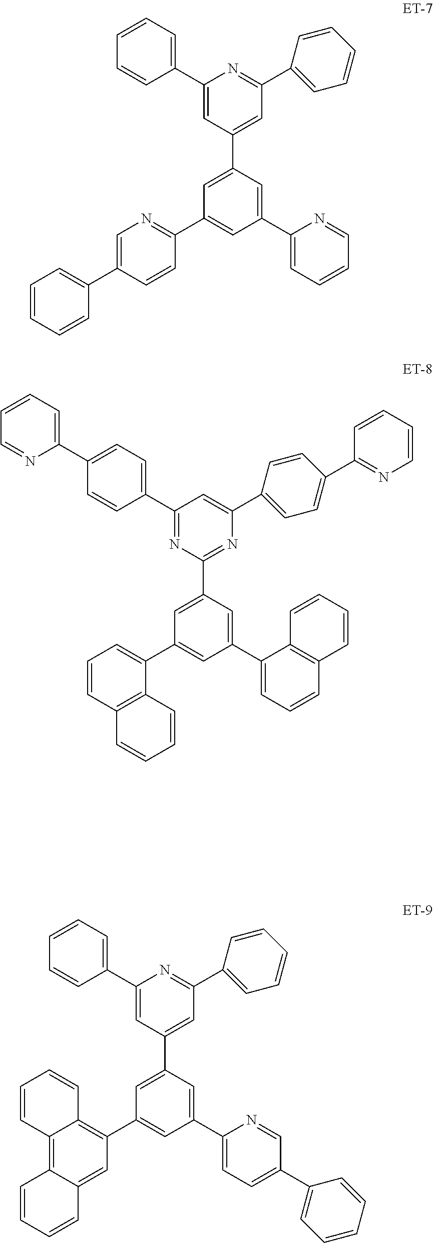 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

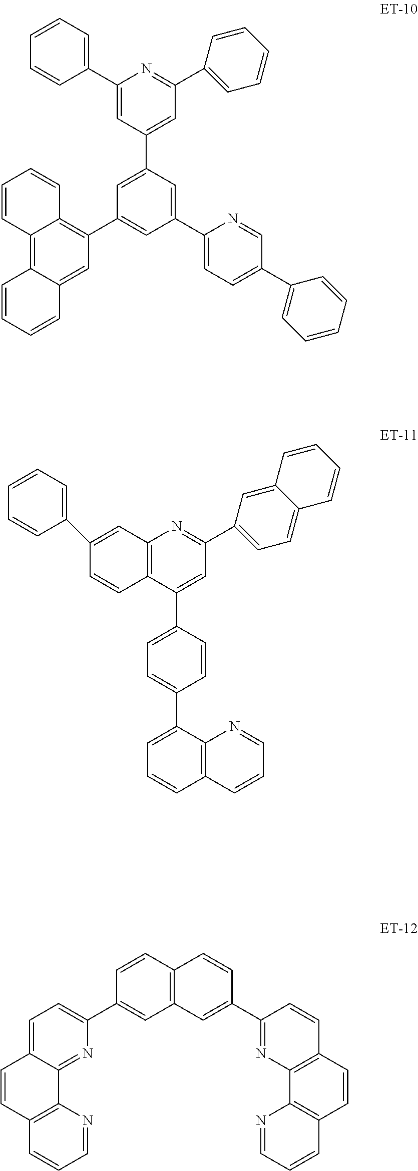 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

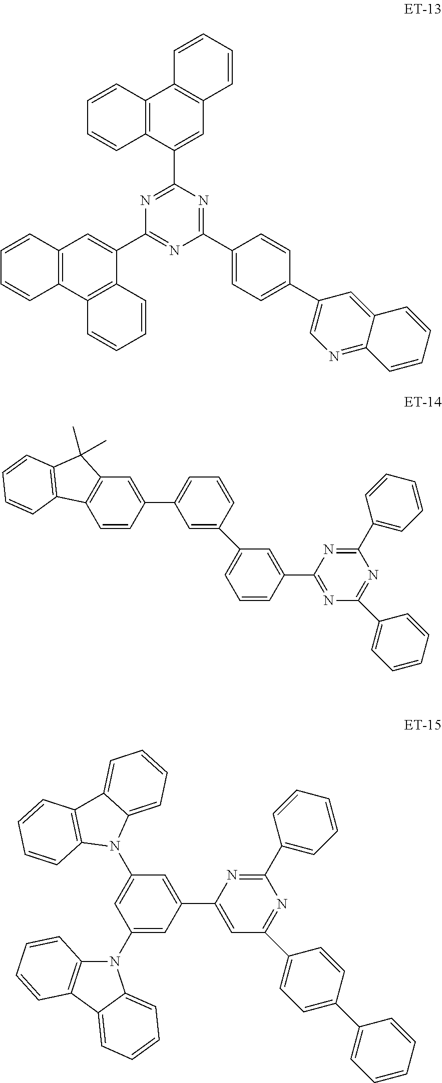 [SMILES: c1ccc2ncc(-c3ccc(-c4nc(-c5cc6ccccc6c6ccccc56)nc(-c5cc6ccccc6c6ccccc56)n4)cc3)cc2c1 ; CC1(C)c2ccccc2-c2ccc(-c3cccc(-c4cccc(-c5nc(-c6ccccc6)nc(-c6ccccc6)n5)c4)c3)cc21 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

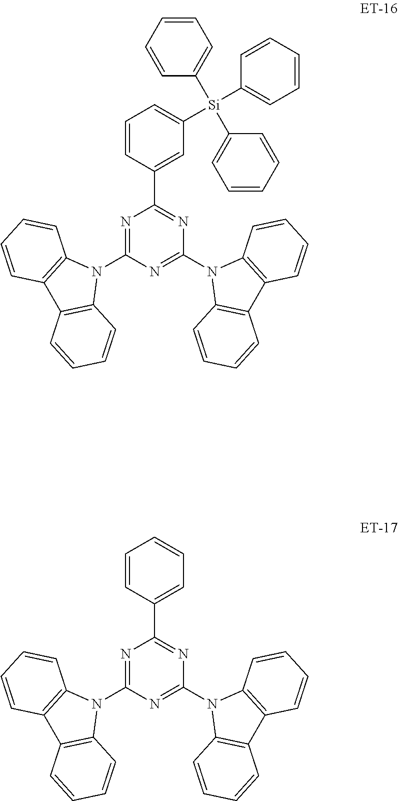 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2nc(-n3c4ccccc4c4ccccc43)nc(-n3c4ccccc4c4ccccc43)n2)cc1]

For example, the electron transfer region 140 may include an anthracene compound, tris(8-hydroxyquinolinato) aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and/or the like. The electron transfer region 140 may include one selected from among the electron transfer materials as described in one or more embodiments or a combination thereof.

The foregoing material may be included in at least one selected from among the electron injection layer 142, the electron transport layer 144, and the hole blocking layer 146.

The electron transfer region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof. In one or more embodiments, the foregoing material may be included in electron injection layer 142.

The alkali metal may include lithium (Li), sodium (Na), potassium (K), rubidium (Rb), cesium (Cs), or any combination thereof. The alkaline earth metal may include magnesium (Mg), calcium (Ca), strontium (Sr), barium (Ba), or any combination thereof. The rare earth metal may include scandium (Sc), yttrium (Y), cerium (Ce), terbium (Tb), ytterbium (Yb), gadolinium (Gd), or any combination thereof.

The alkali metal-containing compound, the alkaline earth metal-containing compound, and the rare earth metal-containing compound may include an oxide, a halide (e.g., a fluoride, a chloride, a bromide, an iodide, and/or the like), a telluride, or a combination thereof of the alkali metal, the alkaline earth metal, and the rare earth metal, respectively.

The alkali metal complex, the alkaline earth metal complex, and the rare earth metal complex may include a metal ion, such as an alkali metal ion, an alkaline earth metal ion, or a rare earth metal ion, and a ligand bonded to the metal ion. The ligand may include, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzoimidazole, hydroxyphenylbenzothiazole, bipyridine, phenanthroline, cyclopentadiene, or a combination thereof.

A thickness of the electron transfer region 140 may be in a range from about 100 Å to about 1,000 Å, for example, from about 150 Å to about 500 Å.

If (e.g., when) the electron transfer region 140 includes an electron injection layer 142 or an electron transport layer 144, a thickness of the electron injection layer 142 may be in a range from about 1 Å to about 100 Å, from about 1 Å to about 90 Å or from about 5 Å to about 50 Å, and a thickness of the electron transport layer 144 may be in a range from about 10 Å to about 900 Å, from about 10 Å to about 500 Å or from about 100 Å to about 400 Å.

Within any of the thickness ranges as described in one or more embodiments, electron injection and electron transport properties may be further improved or enhanced without an excessive increase in driving voltage, and stability of the electron transfer region 140 may be improved or enhanced.

Each layer of the electron transfer region 140 may be formed or provided by a process, such as a vacuum deposition, a spin coating, an inkjet printing, a laser printing, a casting, a laser thermal transfer, and/or the like.

The light-emitting device ED may further include a capping layer. Light emission efficiency to an outside of the light-emitting device ED may be improved or enhanced through the capping layer.

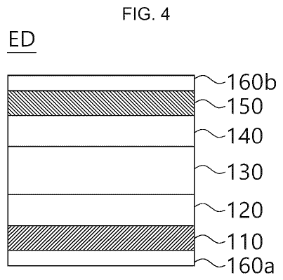

As illustrated in FIG. 4, a second capping layer 160b may be on an outer surface of the second electrode 150. In one or more embodiments, a first capping layer 160a may be on an outer surface of the first electrode 110.

A refractive index of the first capping layer 160a and/or the second capping layer 160b may be about 1.6 or more. For example, the refractive index of the first capping layer 160a and/or the second capping layer 160b may be about 1.6 or more, about 1.8 or more, or about 2.0 or more for a light in a wavelength range of about 550 nm to about 660 nm.

The first capping layer 160a and the second capping layer 160b may each be formed or provided as an organic capping layer including an organic material, an inorganic capping layer including an inorganic material, or an organic-inorganic hybrid capping layer including both (e.g., simultaneously) an organic material and an inorganic material.

The first capping layer 160a and/or the second capping layer 160b may each have a single-layered structure or a multi-layered structure including different materials.

In one or more embodiments, the first capping layer 160a and the second capping layer 160b may each independently include a carbocyclic compound, a heterocyclic compound, an amine group-containing compound, a porphine derivative, a phthalocyanine derivative, a naphthalocyanine derivative, an alkaline metal complex, an alkaline earth metal complex, and/or the like. The first capping layer 160a and the second capping layer 160b may each independently include one selected from among the materials or a combination thereof.

In one or more embodiments, the first capping layer 160a and/or the second capping layer 160b may each independently include an amine group-containing compound.

In a non-limiting example, the first capping layer 160a and/or the second capping layer 160b may include at least one selected from among the compounds represented by Chemical Formulae P1 to P4 and/or at least one selected from among the compounds HT-7, HT-8, HT-14, HT-15, and HT-16.

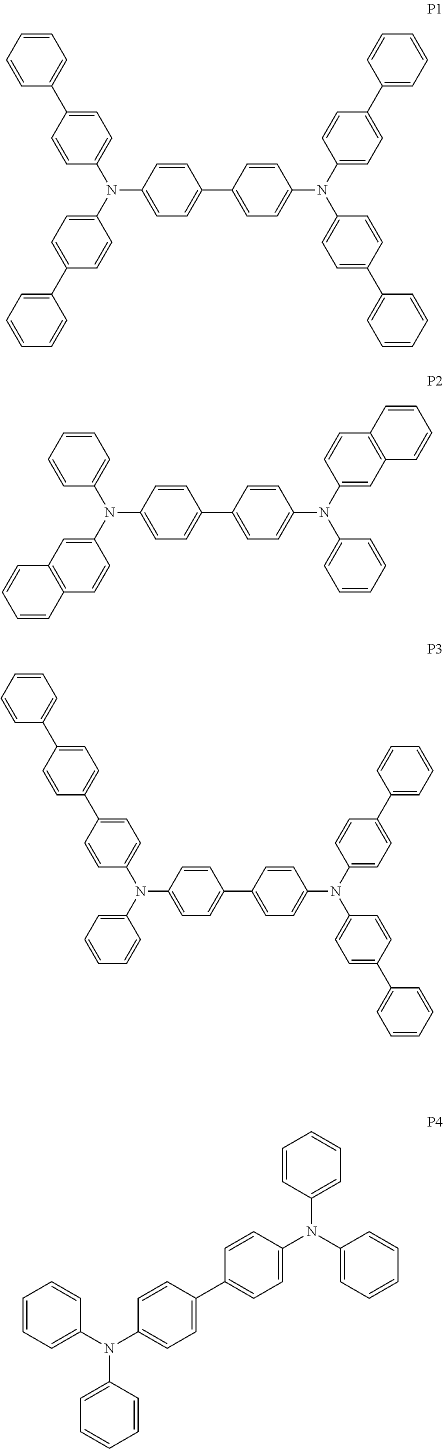 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccccc2)c2ccc(-c3ccc(N(c4ccccc4)c4ccccc4)cc3)cc2)cc1]

Referring to FIG. 5, the light-emitting device ED may include a plurality of light-emitting structures (e.g., the light-emitting structures ES1, ES2, and ES3). The light-emitting structures ES1, ES2, and ES3 may each include a stacked structure of the hole transfer region 120, the emission layer 130, and the electron transfer region 140, as described with reference to FIGS. 1 to 4. In one or more embodiments, the light-emitting device ED of FIG. 5 may be a light-emitting device having a tandem structure.

Charge generation layers CGL1 and CGL2 may each be between adjacent structures selected from among the light-emitting structures ES1, ES2, and ES3. Charge generation layers CGL1 and CGL2 may each independently include a p-type charge generation layer and/or an n-type charge generation layer.

The p-type charge generation layer may include a hole transport host compound, such as NPB. For example, the p-type charge generation layer may include a compound represented by Chemical Formula HT as described in one or more embodiments. The p-type charge generation layer may further include a p-dopant, such as TCNQ.

The n-type charge generation layer may include an electron transport host compound. For example, the n-type charge generation layer may include a compound represented by Chemical Formula ET as described in one or more embodiments. In one or more embodiments, the n-type charge generation layer may include a phenanthroline-based compound.

The charge generation layers CGL1 and CGL2 may include a first charge generation layer CGL1 between the first light-emitting structure ES1 and the second light-emitting structure ES2 and a second charge generation layer CGL2 between the second light-emitting structure ES2 and the third-light emitting structure ES3.

In one or more embodiments, the first light-emitting structure ES1, the first charge generation layer CGL1, the second light-emitting structure ES2, the second charge generation layer CGL2, the third light-emitting structure ES3, and the second electrode 150 may be sequentially stacked on a top surface of the first electrode 110.

Colors emitted from the first light-emitting structure ES1, the second light-emitting structure ES2, and the third light-emitting structure ES3 may be the same as or different from each other. In one or more embodiments, the first light-emitting structure ES1, the second light-emitting structure ES2, and the third light-emitting structure ES3 may include a red light-emitting layer, a green light-emitting layer, and a blue light-emitting layer, respectively, and a white light-emitting structure may be implemented through the tandem structure, but embodiments of the present disclosure are not limited thereto.

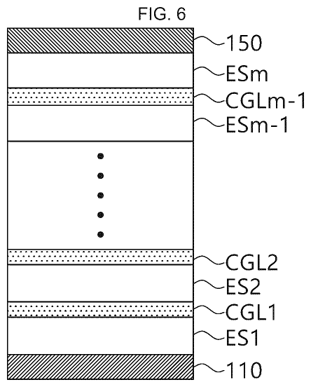

In FIG. 5, the 3-stack tandem structure in which three light-emitting structures are stacked is illustrated as an example, but the tandem structure of the light-emitting device of the present disclosure is not limited to the structure as illustrated in FIG. 5. For example, a 2-stack structure, a 4-stack structure, a 5-stack structure, or more stacked structures as will be described in more detail with reference FIG. 6 may also be implemented.

Referring to FIG. 6, as described in more detail with reference to FIG. 5, a tandem structure in which the light-emitting structure and a charge generation layer are alternately and repeatedly stacked may be between the first electrode 110 and the second electrode 150.

In one or more embodiments, a first light-emitting structure ES1 to an mth light-emitting structure ESm may be sequentially stacked from the top surface of the first electrode 110 with the charge generation layer therebetween. The charge generation layer may include a first charge generation layer CGL1 to an (m−1)th charge generation layer CGLm−1 sequentially stacked from the top surface of the first electrode 110.

As illustrated in FIG. 6, the first light-emitting structure ES1, the first charge generation layer CGL1, the second light-emitting structure ES2, the second charge generation layer CGL2, an (m−1)th light-emitting structure ESm−1, an (m−1)th charge generation layer CGLm−1, an mth light-emitting structure ESm, and the second electrode 150 may be sequentially stacked from the top surface of the first electrode 110.

In one or more embodiments, m may be 4, and an intermediate layer of the light-emitting device may have a 4-stack tandem structure and may include a first light-emitting structure ES1, a second light-emitting structure ES2, a third light-emitting structure ES3, and a fourth light-emitting structure ES4 and a first charge generation layer CGL1, a second charge generation layer CGL2, and a third charge generation layer CGL3. Colors of light generated from the first light-emitting structure ES1, the second light-emitting structure ES2, the third light-emitting structure ES3, and the fourth light-emitting structure ES4 may be the same as or different from each other.

In one or more embodiments, the first light-emitting structure ES1, the second light-emitting structure ES2, the third light-emitting structure ES3, and the fourth light-emitting structure ES4 may include at least one blue light-emitting structure and at least one green-light emitting structure. In a non-limiting example, the first light-emitting structure ES1, the second light-emitting structure ES2, and the third light-emitting structure ES3 may correspond to the blue light-emitting structure, and the fourth light emitting structure ES4 may correspond to the green-light emitting structure.

In one or more embodiments, m may be 5, and an intermediate layer of the light-emitting device may have a 5-stack tandem structure and may include a first light-emitting structure ES1, a second light-emitting structure ES2, a third light-emitting structure ES3, a fourth light-emitting structure ES4, and a fifth light-emitting structure ES5 and a first charge generation layer CGL1, a second charge generation layer CGL2, a third charge generation layer CGL3, and a fourth charge generation layer CGL4. Colors of light generated from the first light-emitting structure ES1, the second light-emitting structure ES2, the third light-emitting structure ES3, the fourth light-emitting structure ES4, and the fifth light-emitting structure ES5 may be the same as or different from each other.

In one or more embodiments, the first light-emitting structure ES1, the second light-emitting structure ES2, the third light-emitting structure ES3, the fourth light-emitting structure ES4, and the fifth light-emitting structure ES5 may include at least one blue light emitting structure and at least one green light emitting structure. In a non-limiting example, the first light-emitting structure ES1, the second light-emitting structure ES2, the third light-emitting structure ES3, the fourth light-emitting structure ES4, and the fifth light-emitting structure ES5 may include three blue light-emitting structures and two green light-emitting structures. For example, the first light-emitting structure ES1, the third light-emitting structure ES3, and the fifth light-emitting structure ES5 may correspond to the blue light-emitting structure, and the second light-emitting structure ES2 and the fourth light-emitting structure ES4 may correspond to the green light-emitting structure.

### Electronic Device

The light-emitting device ED as described in one or more embodiments may be applied to an electronic device and may be provided as a light-emitting portion or a light-emitting unit of the electronic device.

The electronic device may include a light-emitting device (ED) including the polycyclic compound of Chemical Formula 1 as described in one or more embodiments, thereby achieving improved or enhanced color properties, luminous efficiency, and life-span properties.

The electronic device may further include, for example, a functional layer on the light-emitting device and may include a sensor layer, a polarizing layer, a color conversion layer, a color filter layer, or a combination of at least two thereof.

Examples of an electronic device may include a display device, a billboard, a signboard, a light source, a lighting device, a personal computer, such as a laptop computer and/or a desktop computer, a mobile phone, an electronic book, an electronic dictionary, an electronic notebook, a health-care device including a diagnostic device and one or more suitable sensors, one or more suitable display parts for transportation means (e.g., automobile, aircraft, ship, train, and/or the like).

In one or more embodiments, the light-emitting device ED may be applied to an organic light emitting diode (OLED) display device or a quantum dot (QD)-OLED display device.

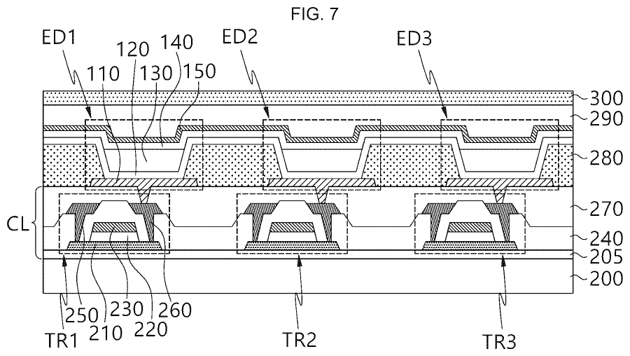

FIG. 7 is a schematic cross-sectional view illustrating a display device according to one or more embodiments.

Referring to FIG. 7, the display device may include a circuit layer CL on a base substrate 200 and light-emitting devices ED1, ED2, and ED3 on the circuit layer CL.

The base substrate 200 may serve as a supporting substrate or as a back-plane substrate of a display device. The base substrate 200 may be a glass substrate and/or a plastic substrate.

In one or more embodiments, the base substrate 200 may include a polymer material having transparent (e.g., substantially transparent) and flexible properties. If (e.g., when) the base substrate 200 includes a polymer material, the base substrate 200 may be used in a transparent (e.g., substantially transparent) flexible display device. For example, the base substrate 200 may include a polymer material, such as polyimide, polysiloxane, an epoxy resin, an acrylic resin, polyester, and/or the like. In one or more embodiments, the base substrate 200 may include polyimide.

The circuit layer CL may include transistors TR1, TR2, and TR3. The circuit layer CL may include wiring layers and insulating (e.g., electrically insulating) layers that form a thin film transistor array (TFT-Array).

The circuit layer CL may further include a buffer layer 205 on a top surface of the base substrate 200. The buffer layer 205 may block the penetration of moisture (or reduce a degree or occurrence of the penetration of moisture) through the base substrate 200 and may also block the diffusion of impurities (or reduce a degree or occurrence of the diffusion of impurities) between the base substrate 200 and the structures formed thereon.

The buffer layer 205 may include, for example, silicon oxide, silicon nitride, and/or silicon oxynitride. The buffer layer 205 may include one selected from among the materials as described in one or more embodiments or a combination thereof. In one or more embodiments, the buffer layer 205 may have a stacked structure that includes a silicon oxide layer and a silicon nitride layer.

The transistors TR1, TR2, and TR3 may be on the buffer layer 205. A first transistor TR1, a second transistor TR2, and a third transistor TR3 may be electrically connected to a first light-emitting device ED1, a second light-emitting device ED2, and a third light-emitting device ED3, respectively.

The transistors TR1, TR2, and TR3 may each include an active layer 210, a gate insulation layer 220, and a gate electrode 230.

The active layer 210 may be on the buffer layer 205 and may be patterned for each pixel area. The active layer 210 may include silicon, such as amorphous (e.g., non-crystalline) silicon and/or polysilicon. A p-type dopant or an n-type dopant may be doped in a region of the active layer 210, and the active layer 210 may include a source region, a drain region, and a channel region.

The active layer 210 may include an oxide semiconductor, such as indium gallium zinc oxide (IGZO), zinc tin oxide (ZTO), and/or ITZO.

The gate insulation layer 220 may be on the active layer 210, and the gate electrode 230 may be stacked on the gate insulation layer 220. As illustrated in FIG. 7, the gate insulation layer 220 may be patterned to partially cover each active layer 210. In one or more embodiments, the gate insulation layer 220 may extend continuously (e.g., substantially continuously) over two or more pixels or light-emitting regions and may be provided as a common layer for the first transistor TR1, the second transistor TR2, and the third transistor TR3.

The gate electrode 230 may overlap the channel region of the active layer 210 in a thickness direction.

An insulating interlayer 240 may be on the active layer 210 to cover the gate electrode 230 and the gate insulation layer 220. Connection electrodes 250 and 260 which may be in contact with or electrically connected to the active layer 210 may each be on the insulating interlayer 240.

The connection electrodes 250 and 260 may extend through the insulating interlayer 240 to be in contact with or electrically connected to the active layer 210. If (e.g., when) the gate insulation layer 220 is provided as a common layer for two or more light-emitting regions, the connection electrodes 250 and 260 may also extend through the gate insulation layer 220.

The connection electrodes 250 and 260 may include a source electrode 250 that may be in contact with or connected to the source region of the active layer 210 and a drain electrode 260 that may be in contact with or connected to the drain region of the active layer 210.

The gate insulation layer 220 and the insulating interlayer 240 may each independently include silicon oxide, silicon nitride, and/or silicon oxynitride and may each have a stacked structure that includes a silicon oxide layer and a silicon nitride layer.

The gate electrode 230 and the connection electrodes 250 and 260 may include a metal, such as Ag, Mg, Al, W, Cu, Ni, Cr, Mo, Ti, Pt, Ta, Nd, Sc, an alloy thereof, or a nitride thereof.

A via insulation layer 270 may be on the insulating interlayer 240 to cover the connection electrodes 250 and 260.

The via insulation layer 270 may accommodate a via structure that electrically connects the first electrode 110 and the drain electrode 260. The via insulation layer 270 may serve as a planarization layer of the circuit layer CL. In one or more embodiments, the via insulation layer 270 may include an organic material, such as polyimide, an epoxy resin, an acrylic resin, polyester, and/or the like.

The light-emitting devices ED1, ED2, and ED3 may be on the via insulation layer 270. For example, as described in more detail with reference to FIGS. 1 to 4, the light-emitting devices ED1, ED2, and ED3 may include the first electrode 110, the hole transfer region 120, the emission layer 130, the electron transfer region 140, and the second electrode 150 which are sequentially stacked from the via insulation layer 270.

The first electrode 110 may be electrically connected to the transistors TR1, TR2, and TR3 or the connection electrodes 250 and 260 in the circuit layer CL through the via structure. As illustrated in FIG. 7, the first electrode 110 may be in contact with or connected to the drain electrode 260 to serve as a pixel electrode patterned for each light-emitting region or pixel.

A pixel defining layer 280 may be on the via insulation layer 270 to define each light-emitting region or pixel. A blue light-emitting region, a red light-emitting region, and a green light-emitting region may be separated and defined by the pixel defining layer 280, and the light-emitting devices ED1, ED2, and ED3 may respectively correspond to a blue light-emitting device, a red light-emitting device, and a green light-emitting device.

The pixel defining layer 280 may partially cover the first electrode 110 of each light-emitting region.

As illustrated in FIG. 7, the hole transfer region 120 and the electron transfer region 140 may each be provided as a common layer that continuously (e.g., substantially continuously) extends over the pixel defining layer 280 and the first electrodes 110. The emission layer 130 may be within each light emitting-region or pixel and may be separated by the pixel defining layer 280.

In one or more embodiments, the emission layer 130 may also be provided as a common layer that continuously (e.g., substantially continuously) extends over the light emitting-regions or pixels. In one or more embodiments, the hole transfer region 120, the emission layer 130, and the electron transfer region 140 may each be patterned and separately formed or provided for each light-emitting region or pixel.

The second electrode 150 may be provided as a common electrode that continuously (e.g., substantially continuously) extends over the light-emitting regions or the pixels.

An encapsulation layer 290 may be on the pixel defining layer 280 and the light-emitting devices ED1, ED2, and ED3 to protect the light-emitting devices ED1, ED2, and ED3 from moisture and/or oxygen. The encapsulation layer 290 may be a thin film encapsulation (TFE) having a single-layered structure or a multi-layered structure.

The encapsulation layer 290 may include an inorganic layer that includes silicon nitride (e.g., Si₃N₄ or SiNₓ, wherein 0<X≤2), silicon oxide (e.g., SiOₓ, wherein 0<X≤2; e.g., SiO₂), indium tin oxide, indium zinc oxide, or any combination thereof; an organic layer that includes polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, and/or the like), an epoxy resin (e.g., an aliphatic glycidyl ether (AGE)) or any combination thereof; or a combination of the inorganic layer and the organic layer.

The display device may further include a functional layer 300 on the encapsulation layer 290. The functional layer 300 may include a sensor layer, such as a touch sensor layer, an optical layer, such as a polarizing layer, a color conversion layer, a color filter layer, a window film, or any combination thereof.

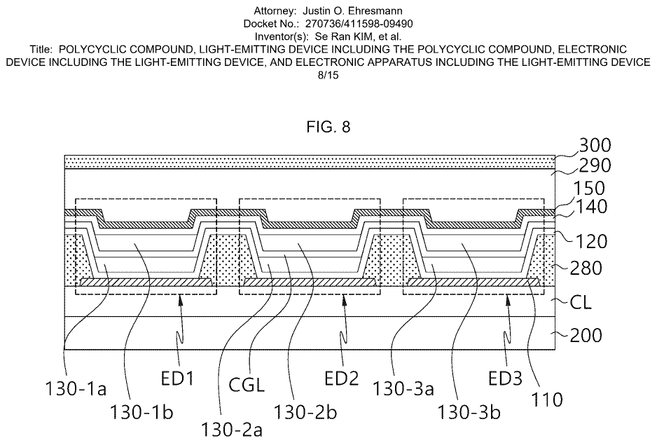

FIG. 8 is a schematic cross-sectional view illustrating a display device according to one or more embodiments.

Referring to FIG. 8, each of the light-emitting devices ED1, ED2, and ED3 may have a tandem structure, e.g., a 2-stack tandem structure.

In one or more embodiments, the hole transfer region 120 and the electron transfer region 140 may be continuously (e.g., substantially continuously) and commonly formed or provided and included in an intermediate layer of each light-emitting structure. In one or more embodiments, a charge generation layer CGL may continuously (e.g., substantially continuously) extend across a plurality of pixels and may be commonly included in the intermediate layer of each light-emitting structure.

The first light-emitting device ED1 may include a first lower emission layer 130-1a between the hole transfer region 120 and the charge generation layer CGL and a first upper emission layer 130-1b between the charge generation layer CGL and the electron transfer region 140.

The second light-emitting device ED2 may include a second lower emission layer 130-2a between the hole transfer region 120 and the charge generation layer CGL and a second upper emission layer 130-2b between the charge generation layer CGL and the electron transfer region 140.

The third light-emitting device ED3 may include a third lower emission layer 130-3a between the hole transfer region 120 and the charge generation layer CGL and a third upper emission layer 130-3b between the charge generation layer CGL and the electron transfer region 140.

The lower emission layer and the upper emission layer that are included in each light-emitting structure may generate light of substantially the same color. In one or more embodiments, each of the first lower emission layer 130-1a and the first upper emission layer 130-1b included in the first light-emitting device ED1 may correspond to a red emission layer. Each of the second lower emission layer 130-2a and the second upper emission layer 130-2b included in the second light-emitting device ED2 may correspond to a green emission layer. Each of the third lower emission layer 130-3a and the third upper emission layer 130-3b included in the third light-emitting device ED3 may correspond to a blue emission layer.

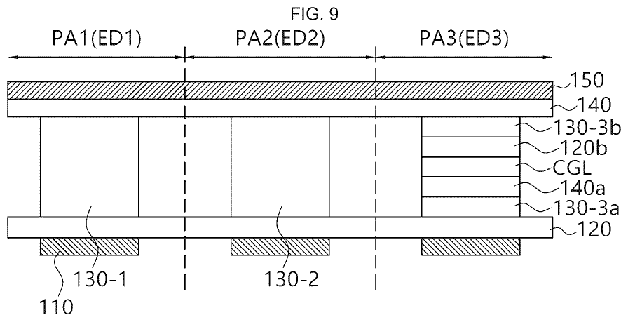

FIG. 9 is a schematic cross-sectional view illustrating a stack construction of light-emitting structure in a display device according to one or more embodiments. For convenience of illustration and description, illustration of the circuit layer, the base substrate, the pixel defining layer, and/or the like is not provided in FIG. 9, and a shape of each layer or element in the light-emitting structure is briefly illustrated as a rectangle (e.g., a substantially rectangle).

Referring to FIG. 9, at least one selected from among the light-emitting devices ED1, ED2, ED3 or pixel areas PA1, PA2, and PA3 may have a tandem structure including a plurality of emission layers, and at least one of the remainder may have a single emission layer structure.

In one or more embodiments, one selected from among the light-emitting devices ED1, ED2, ED3 or the pixel areas PA1, PA2, and PA3 may have a tandem structure, and the remainder may have a single emission layer structure.

As illustrated in FIG. 9, the first light-emitting device ED1, the second light-emitting device ED2, and the third light-emitting device ED3 may be included in the first pixel area PA1, the second pixel area PA2, and the third pixel area PA3, respectively. In one or more embodiments, the first pixel area PA1, the second pixel area PA2, and the third pixel area PA3 may correspond to a red pixel area, a green pixel area, and a blue pixel area, respectively.

The hole transfer region 120, the electron transfer region 140, and the second electrode 150 may each be provided as a common layer that continuously (e.g., substantially continuously) extends over the first pixel area PA1, the second pixel area PA2, and the third pixel area PA3.

The first-light emitting device ED1 included in the first pixel area PA1 may include a first emission layer 130-1, and the second light-emitting device ED2 included in the second pixel area PA2 may include a second emission layer 130-2. Each of the first emission layer 130-1 and the second emission layer 130-2 may be a single-layered emission layer.

The third light-emitting device ED3 included in the third pixel area PA3 may have, for example, a 2-stack tandem structure. The third light-emitting device ED3 may include a third lower emission layer 130-3a and a third upper emission layer 130-3b separated with the charge generation layer CGL therebetween. Each of the third lower emission layer 130-3a and the third upper emission layer 130-3b may correspond to a blue emission layer.

A lower electron transfer region 140a may be between the charge generation layer CGL and the third lower emission layer 130-3a. An upper hole transfer region 120b may be between the charge generation layer CGL and the third upper emission layer 130-3b.

Accordingly, a tandem light-emitting structure in which the first electrode 110, the hole transfer region 120, the third lower emission layer 130-3a, the lower electron transfer region 140a, the charge generation layer CGL, the upper hole transfer region 120b, the third upper emission layer 130-3b, the electron transfer region 140, and the second electrode 150 are sequentially stacked may be in the third pixel area PA3.

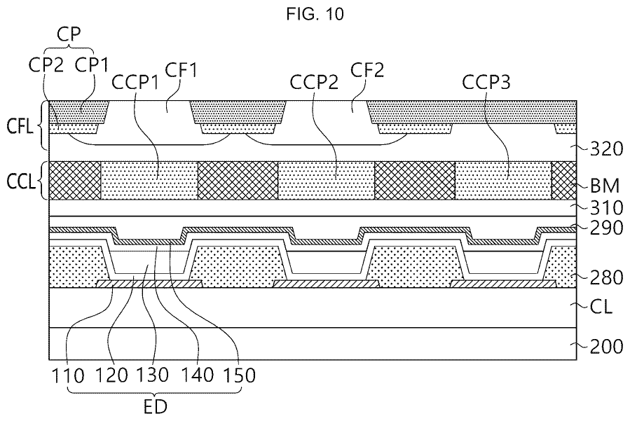

FIG. 10 is a schematic cross-sectional view illustrating a display device according to one or more embodiments.

FIG. 10 illustrates a display device having a QD-OLED structure according to one or more embodiments. More detailed descriptions with respect to elements and structures that are substantially the same as or substantially similar to those described with reference to FIG. 7 may not be repeated herein.

Referring to FIG. 10, the pixel defining layer 280 and the light-emitting device ED may be on the circuit layer CL, as described in one or more embodiments with reference to FIG. 7. In one or more embodiments, each pixel may emit light of substantially the same wavelength region. In one or more embodiments, each light-emitting device ED may emit a blue light.

In one or more embodiments, each light-emitting region may include the light-emitting device having the tandem structure, as described in one or more embodiments with respect to FIG. 5. In one or more embodiments, the intermediate layer of each light-emitting device ED may be provided as a common layer that continuously (e.g., substantially continuously) extends over a plurality of the light-emitting regions.

A color control layer CCL may be on the encapsulation layer 290, and the color control layer CCL may include color control portions CCP1, CCP2, and CCP3.

The color control portions CCP1, CCP2, and CCP3 may each include a light transformer, such as a quantum dot and/or a phosphor. In each of the color control portions CCP1, CCP2, and CCP3, the light transformer may convert a wavelength of a provided light and emit a resulting light.

The color control portions CCP1, CCP2, and CCP3 may be spaced and/or apart (e.g., spaced apart or separated) from each other by a bank BM. The bank BM may substantially overlap the pixel defining layer 280, and the color control portions CCP1, CCP2, and CCP3 may substantially overlap each of the emission layers 130.

The color control layer CCL may include a first color control portion CCP1 including a first quantum dot that converts a first color light provided from the light-emitting device ED into a second color light, a second color control portion CCP2 including a second quantum dot that converts the first color light into a third color light, and a third color control portion CCP3 that transmits the first color light.

In one or more embodiments, the first color light, the second color light, and the third color light may be a blue light, a red light, and a green light, respectively. The first quantum dot and the second quantum dot may respectively be a red quantum dot and a green quantum dot.

The color control portions CCP1, CCP2, and CCP3 may each further include a scattering material (e.g., a light scattering material), such as inorganic particles. The third color control portion CCP3 may not include quantum dots and may include the scattering material. The scattering material (e.g., the light scattering material) may include TiO₂, ZnO, Al₂O₃, SiO₂, hollow silica, and/or the like. The scattering material may be one selected from among the materials as described in one or more embodiments or a combination thereof.

The color control portions CCP1, CCP2, and CCP3 may each further include a binder resin that disperses the quantum dot and the scattering material (e.g., the light scattering material). The binder resin may include an acrylic resin, a urethane resin, a silicone resin, an epoxy resin, and/or the like.

A color filter layer CFL that includes color filters CF1 and CF2 and a light-shielding portion CP may be on the color control layer CCL.

The color filter layer CFL may include a first filter CF1 that transmits the second color light, a second filter CF2 that transmits the third color light, and a third filter that transmits the first color light. For example, the first filter CF1 may be a red filter, the second filter CF2 may be a green filter, and the third filter may be a blue filter.

The color filters CF1 and CF2 may each include a photosensitive binder resin and a colorant including a pigment and/or a dye. The first filter CF1 may include a red pigment and/or a red dye, and the second filter CF2 may include a green pigment and/or a green dye.

The light-shielding portion CP may be between the color filters. In one or more embodiments, the light-shielding portion may include a first light-shielding portion CP1 and a second light-shielding portion CP2 that includes colorants of different colors.

In one or more embodiments, the first light-shielding portion CP1 may include a blue colorant, and the second light-shielding portion CP2 may include a red colorant and/or a black colorant. In one or more embodiments, in the blue light-emitting region, a portion of the first light-shielding portion CP1 may be provided as a blue color filter and may be exposed between the second light-shielding portions CP2, so that an additional color filter (e.g., the third filter) may not be provided.

A first barrier layer 310 may be between the color control layer CCL and the light-emitting device ED (or the encapsulation layer 290). A second barrier layer 320 may be between the color control layer CCL and the color filter layer CFL.

The barrier layers 310 and 320 may each include at least one inorganic layer. For example, the barrier layers 310 and 320 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or the like.

In one or more embodiments, the barrier layers 310 and 320 may each have a multi-layered structure that further includes an organic layer.

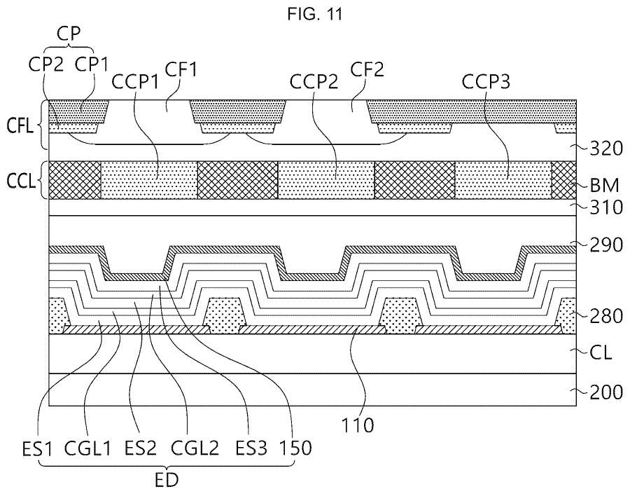

FIG. 11 is a schematic cross-sectional view illustrating a display device according to one or more embodiments. More detailed descriptions of elements and structures substantially the same as or similar to those described with reference to FIG. 10 may not be provided herein.

Referring to FIG. 11, the light-emitting device ED that corresponds to the color control portions CCP1, CCP2, and CCP3 may be on the first electrode 110 serving as the pixel electrode, and the light-emitting device ED may have a tandem structure.

In one or more embodiments, as described in more detail with reference to FIG. 5, the first light-emitting structure ES1, the first charge generation layer CGL1, the second light-emitting structure ES2, the second charge generation layer CGL2, and the third light-emitting structure ES3 may be sequentially stacked between the first electrode 110 and the second electrode 150. The first light-emitting structure ES1, the first charge generation layer CGL1, the second light-emitting structure ES2, the second charge generation layer CGL2, and the third light-emitting structure ES3 may be continuously (e.g., substantially continuously) and commonly formed or provided in a plurality of pixel areas or light-emitting regions.

In one or more embodiments, the first light-emitting structure ES1, the second light-emitting structure ES2, and the third light-emitting structure ES3 may generate different color lights, and the light-emitting device ED may generate a white light. In one or more embodiments, the first light-emitting structure ES1, the second light-emitting structure ES2, and the third light-emitting structure ES3 may all generate blue lights.

In one or more embodiments, as described in more detail with reference to FIG. 6, the light-emitting device ED may include a tandem structure of four stacks, five stacks, or more of the stacked number (e.g., a 4-stack tandem structure, a 5-stack tandem structure, or more).

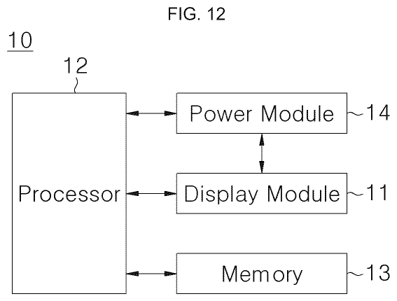

FIG. 12 is a block diagram of an electronic device according to one or more embodiments.

Referring to FIG. 12, an electronic device 10 according to one or more embodiments may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

Data information for an operation of the processor 12 or the display module 11 may be stored in the memory 13. If (e.g., when) the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter and/or a battery device, and a power conversion module that converts a power supplied by the power supply module to a generate power desired or required for the operation of the electronic device 10.

At least one selected from among the components of the electronic device 10 as described in one or more embodiments may be included in the display device according to one or more embodiments. In one or more embodiments, one or more of individual modules functionally included in one module may be included in the display device, and others may be provided separately from the display device. For example, the display module 11 may include the display device, and the processor 12, the memory 13, and the power module 14 may be provided in the form of another device in the electronic device 10 different from the display device.

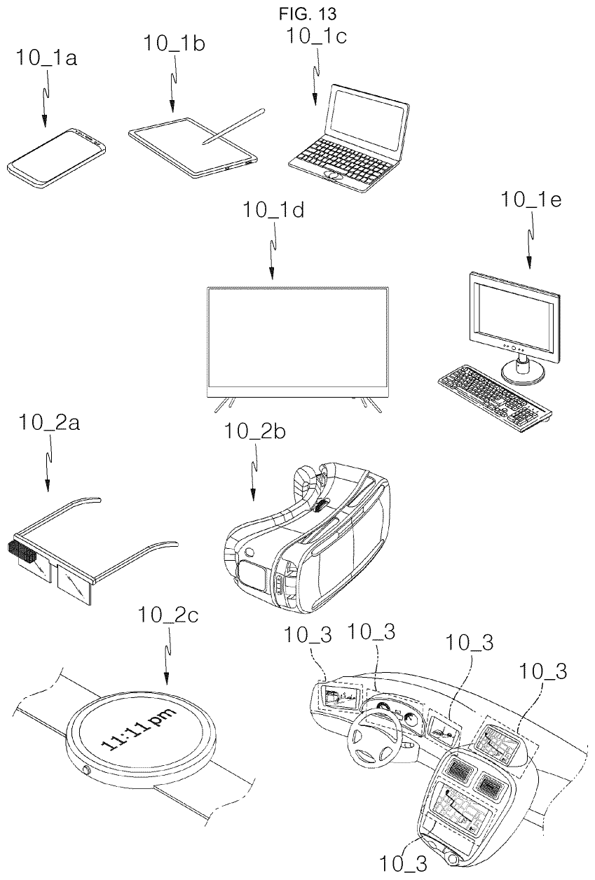

FIG. 13 is a view of electronic devices according to one or more embodiments.

Referring to FIG. 13, non-limiting examples of one or more suitable electronic devices to which the display device according to one or more embodiments is applied include an electronic device to display an image, such as a smartphone 10_1a, a tablet PC 10_1b, a laptop 10_1c, a TV 10_1d, a desk monitor 10_1e, and/or the like; a wearable electronic device including a display module, such as smart glasses 10_2a, a head mounted display 10_2b, a smart watch 10_2c, and/or the like; a vehicle electronic device 10_3 including a display module, such as a center information display (CID) at a vehicle instrument panel, a center fascia, a dashboard, and/or the like, a room mirror display, and/or the like. The electronic device may include a virtual reality glass and/or an augmented reality glass.

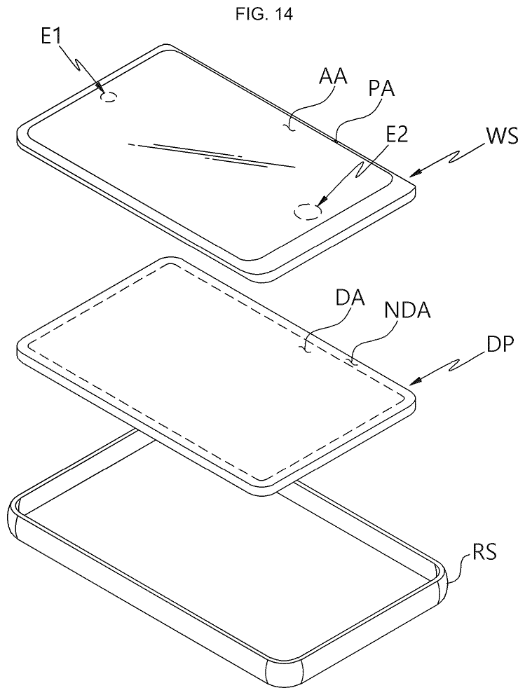

FIG. 14 is a schematic exploded perspective view illustrating an electronic device according to one or more embodiments.

According to one or more embodiments, the electronic device may be implemented in the form of a mobile phone (e.g., a smart phone), a tablet, a PC, and/or the like, including the display device as described in one or more embodiments.

Referring to FIG. 14, the electronic device may include a window structure WS, a display panel DP, and a rear structure RS.

The window structure WS may provide an external display surface recognized by a user, such as a viewing surface of a mobile phone, and may include a transparent (e.g., substantially transparent) material film. For example, the window structure WS may include glass (e.g., ultra-thin glass (UTG)), a hard coating film, a plastic film, and/or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device.

The display panel DP may include the display device as described in one or more embodiments and may have a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In one or more embodiments, functional device areas E1 and E2 may be included in the active area AA of the window structure WS. For example, a first functional device area E1 may be included at one end portion of the active area AA and may be implemented, for example, in the form of a camera hole. The second functional device area E2 may serve as a fingerprint sensing area.

For example, a sensor structure for a touch sensing and/or a fingerprint sensing may be in the display panel DP or between the window structure WS and the display panel DP.

The rear structure RS may serve as a frame structure and/or a housing of the display device and/or the electronic device. A cover panel may be between the rear structure RS and the display panel DP.

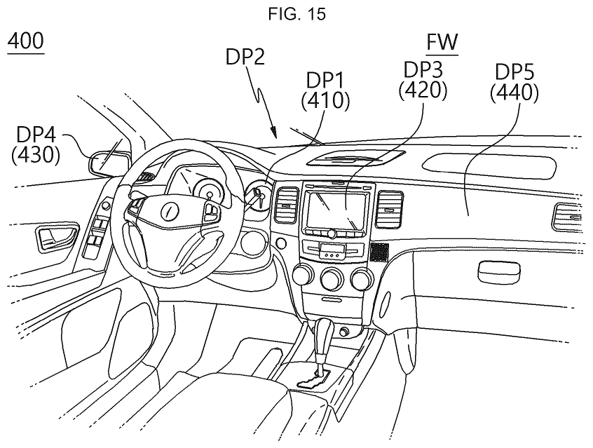

FIG. 15 is a view illustrating a vehicle in which electronic devices according to one or more embodiments are provided.

The electronic device may be installed in, embedded in, attached to, and/or integrated with a vehicle 400. However, the vehicle 400 is not limited to the embodiment illustrated in FIG. 12. Further examples of the vehicle 400 may include a transportation means, such as a three-wheeled vehicle, a four-wheeled vehicle, a construction machine, a two-wheeled vehicle, a motor vehicle, a bicycle, a train, and/or the like. Other examples of the vehicle 400 may include an electric vehicle, a hybrid vehicle, and/or the like.

Referring to FIG. 15, at least one selected from among a first display device DP1, a second display device DP2, a third display device DP3, a fourth display device DP4, and a fifth display device DP5 may be applied to the vehicle 400.

In one or more embodiments, the first display device DP1 may be in a cluster area 410. Driving information, such as a driving distance and speed, and one or more suitable warning lights may be displayed in the cluster area 410.

The second display device DP2 may be on a front window FW of the vehicle 400. For example, the second display device DP2 may be installed as a head-up display (HUD).

The third display device DP3 may be on a center fascia 420 of the vehicle 400. In the center fascia 420, a button and/or a switch to control an image display and/or a music player, an air conditioner, a heater, and/or the like may be disposed, and vehicle information may be displayed thereon.

The fourth display device DP4 may be applied to side mirrors 430 of the vehicle 400. A side mirror 430 may be installed at each of both sides (e.g., two opposing sides) of an exterior of the vehicle 400, and the fourth display device DP4 may be applied to at least one selected from the side mirrors 430 installed at each of the both sides (e.g., two opposing sides).

The fifth display device DP5 may be on a passenger seat dashboard 440. Information/image that is substantially identical to or different from information/image displayed on the cluster area 410 and/or the center fascia 420 may be displayed at the passenger seat dashboard 440.

### Electronic Apparatus

The light-emitting device ED as described in one or more embodiments may be applied to an electronic apparatus and may serve as a light-emitting portion or a light-emitting unit of the electronic apparatus.

The electronic apparatus may include the light-emitting device ED including the polycyclic compound of Chemical Formula 1 as described in one or more embodiments, thereby achieving improved or enhanced color properties, light emission efficiency, and life-span properties.

In one or more embodiments, the electronic apparatus may include the electronic device as described in one or more embodiments.

The electronic apparatus may include, for example, a flat panel display, a curved display, a computer monitor, a medical monitor, a television, a billboard, a light for indoor lighting, a light for outdoor lighting, a light for signals, a head-up display, a fully transparent display, a partially transparent display, a flexible display, a rollable display, a foldable display, a stretchable display, a laser printer, a phone, a mobile phone, a tablet, a phablet, a personal information terminal (e.g., personal digital assistant (PDA)), a wearable device, a laptop computer, a digital camera, a camcorder, a viewfinder, a micro display, a 3D display, a virtual reality display, an augmented reality display, a vehicle, a video wall including two or more displays tiled together, a theater screen, a stadium screen, a phototherapy device, and/or a signboard.

Hereinafter, a polycyclic compound according to one or more embodiments will be described in more detail with reference to the Examples and the Comparative Examples. The Examples are provided to assist in understanding the present disclosure, but they are provided as non-limiting examples, and the scope of the present disclosure is not limited thereto. It will be clear to those skilled in the art that one or more suitable changes and modifications to disclosed examples can be made within the scope of the present disclosure.

### Synthesis Example 1: Synthesis of Compound 27

The compound 27 was synthesized by the following scheme.

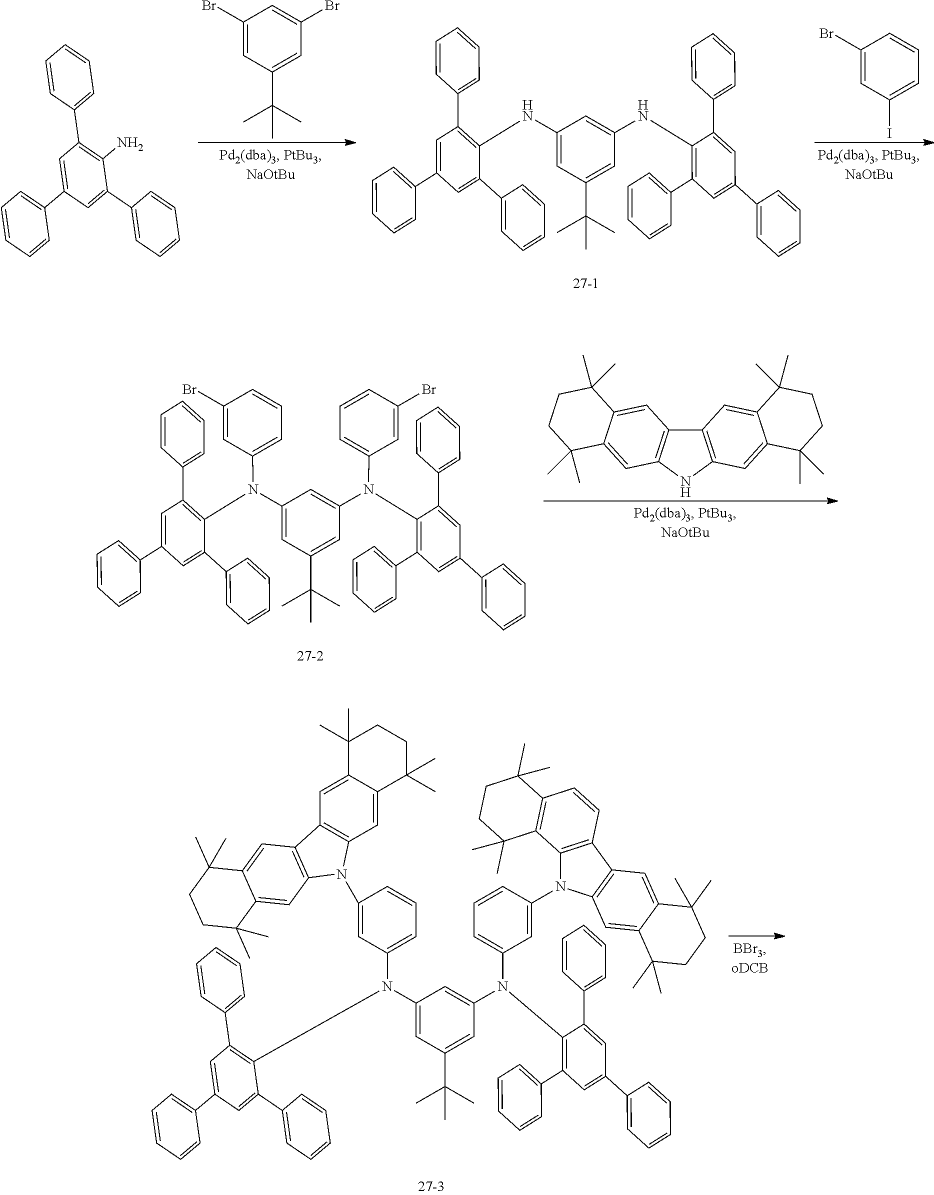

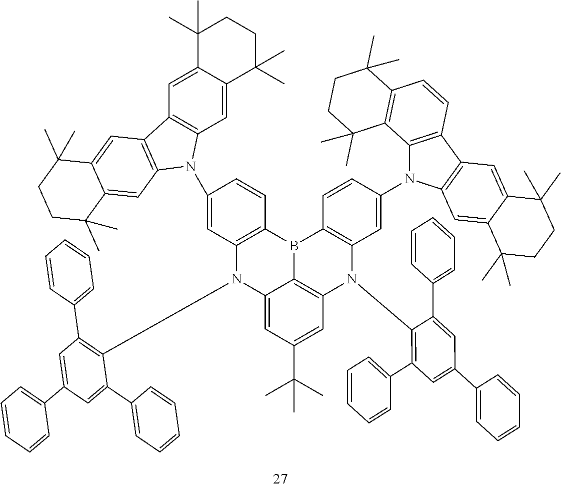 [SMILES: CC(C)(C)c1cc2c3c(c1)N(c1c(-c4ccccc4)cc(-c4ccccc4)cc1-c1ccccc1)c1cc(-n4c5cc6c(cc5c5ccc7c(c54)C(C)(C)CCC7(C)C)C(C)(C)CCC6(C)C)ccc1B3c1ccc(-n3c4cc5c(cc4c4cc6c(cc43)C(C)(C)CCC6(C)C)C(C)(C)CCC5(C)C)cc1N2c1c(-c2ccccc2)cc(-c2ccccc2)cc1-c1ccccc1]

### Synthesis of intermediate 27-1

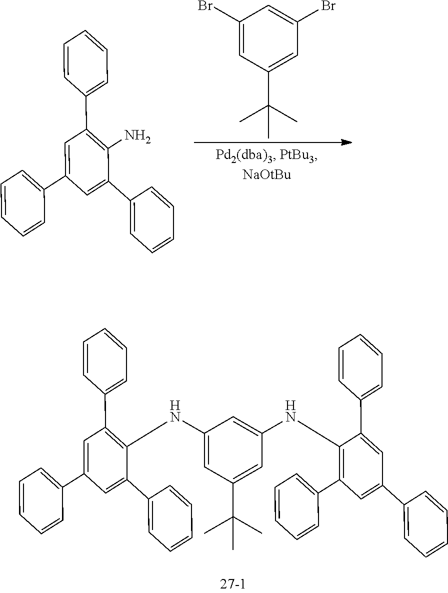 [SMILES: Nc1c(-c2ccccc2)cc(-c2ccccc2)cc1-c1ccccc1 ; CC(C)(C)c1cc(Br)cc(Br)c1 ; CC(C)(C)c1cc(Nc2c(-c3ccccc3)cc(-c3ccccc3)cc2-c2ccccc2)cc(Nc2c(-c3ccccc3)cc(-c3ccccc3)cc2-c2ccccc2)c1]

1,3-Dibromo-5-(tert-butyl)benzene (1 eq), 5′-phenyl-[1,1′:3′,1″-terphenyl]-2′-amine (2 eq), Pd₂(dba)₃ (0.05 eq), tri-tert-butylphosphine (0.1 eq), and sodium tert-butoxide (1.5 eq) were dissolved in toluene to prepare a reaction solution. The reaction solution was stirred at 100° C. for 12 hours. After being cooled to room temperature, the stirred solution was washed three times with ethyl acetate and water, and an organic layer was extracted and separated. The separated organic layer was dried over MgSO₄ and filtered. The solvent was removed from the filtered solution under reduced pressure.

The obtained solid was purified and separated by silica gel column chromatography using dichloromethane (CH₂Cl₂) and hexane as developing solvents to obtain an intermediate 27-1 (yield: 61%).

### Synthesis of Intermediate 27-2

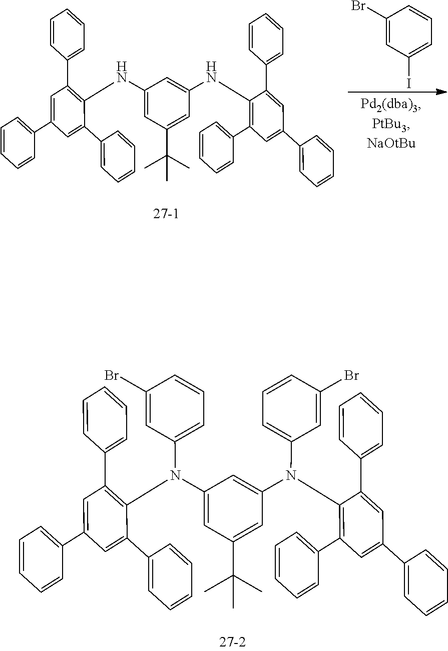 [SMILES: CC(C)(C)c1cc(Nc2c(-c3ccccc3)cc(-c3ccccc3)cc2-c2ccccc2)cc(Nc2c(-c3ccccc3)cc(-c3ccccc3)cc2-c2ccccc2)c1 ; Brc1cccc(I)c1 ; CC(C)(C)c1cc(N(c2cccc(Br)c2)c2c(-c3ccccc3)cc(-c3ccccc3)cc2-c2ccccc2)cc(N(c2cccc(Br)c2)c2c(-c3ccccc3)cc(-c3ccccc3)cc2-c2ccccc2)c1]

The intermediate 27-1 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After being cooled to room temperature, the stirred solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as developing solvents to obtain an intermediate 27-2 (yield: 66%).

### Synthesis of Intermediate 27-3

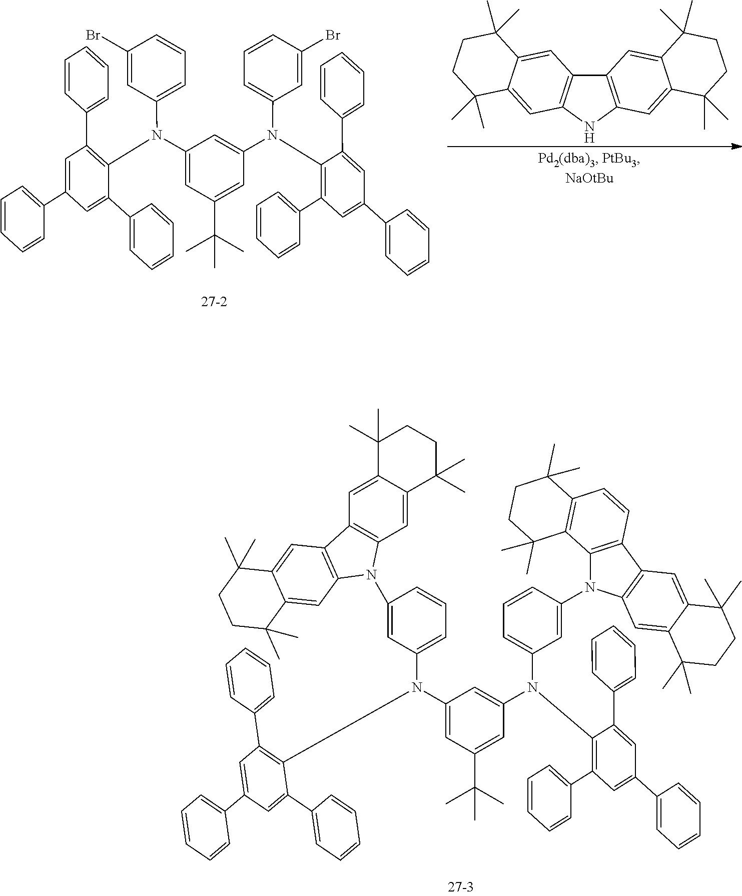

The intermediate 27-2 (1 eq), 1,1,4,4,8,8,11,11-octamethyl-2,3,4,6,8,9,10,11-octahydro-1H-dibenzo[b,h]carbazole (2 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After being cooled to room temperature, the stirred solution was washed three times with ethyl acetate and water, and the organic layer was extracted and separated. The separated organic layer was dried over MgSO₄ and filtered. The solvent was removed from the filtered solution under reduced pressure. The obtained solid was purified and separated by silica gel column chromatography using CH₂Cl₂ and hexane as developing solvents to obtain an intermediate 27-3 (yield: 61%).

### Synthesis of Compound 27

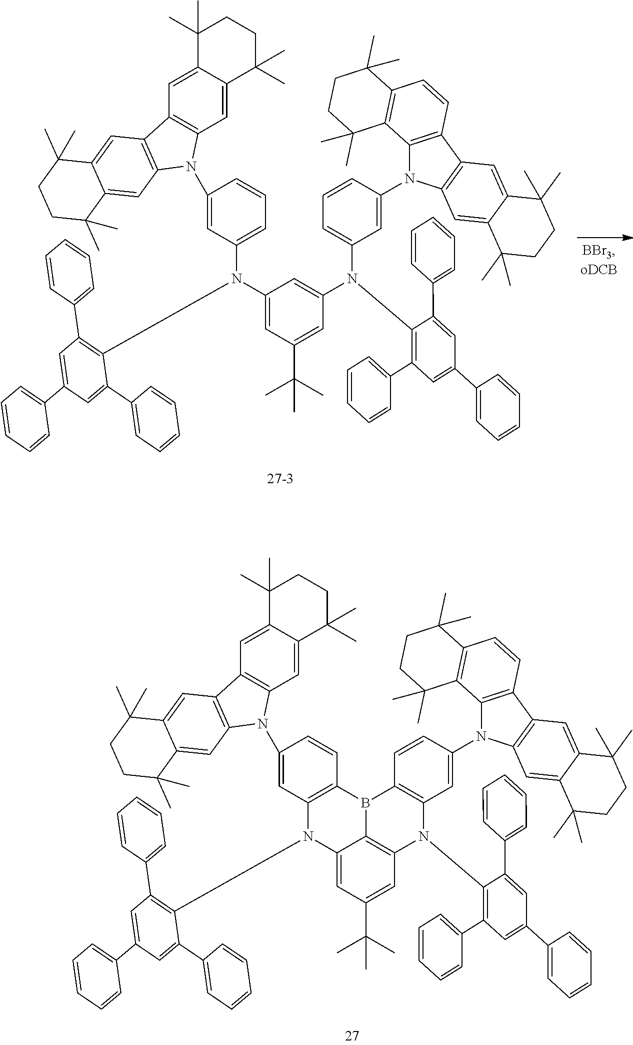 [SMILES: CC(C)(C)c1cc(N(c2cccc(-n3c4cc5c(cc4c4cc6c(cc43)C(C)(C)CCC6(C)C)C(C)(C)CCC5(C)C)c2)c2c(-c3ccccc3)cc(-c3ccccc3)cc2-c2ccccc2)cc(N(c2cccc(-n3c4cc5c(cc4c4ccc6c(c43)C(C)(C)CCC6(C)C)C(C)(C)CCC5(C)C)c2)c2c(-c3ccccc3)cc(-c3ccccc3)cc2-c2ccccc2)c1 ; CC(C)(C)c1cc2c3c(c1)N(c1c(-c4ccccc4)cc(-c4ccccc4)cc1-c1ccccc1)c1cc(-n4c5cc6c(cc5c5ccc7c(c54)C(C)(C)CCC7(C)C)C(C)(C)CCC6(C)C)ccc1B3c1ccc(-n3c4cc5c(cc4c4cc6c(cc43)C(C)(C)CCC6(C)C)C(C)(C)CCC5(C)C)cc1N2c1c(-c2ccccc2)cc(-c2ccccc2)cc1-c1ccccc1]

The intermediate 27-3 (1 eq) was dissolved in o-dichlorobenzene, cooled to 0° C., and BBr₃ (3 eq) was slowly added dropwise to the cooled solution under a nitrogen atmosphere. The reaction solution after the injection of BBr₃ was heated to 180° C., and the heated solution was stirred for 48 hours. The stirred solution was cooled to room temperature, and triethylamine was slowly added dropwise to the cooled solution to terminate the reaction. Thereafter, ethyl alcohol was added, and a solid was obtained by precipitation and filtration. The obtained solid was purified and separated by silica gel column chromatography using CH₂Cl₂ and hexane as a developing solvent, and then the compound 27 (yield: 1.5%) was obtained by recrystallization.

The fast-atom bombardment mass spectrometry (MS/FAB) analysis results (in mass-to-charge ratio (m/z)) of the obtained compound 27 are as follows.

C₁₂₆H₁₂₃BN₄ cal. 1702.98, found 1702.99.

### Synthesis Example 2: Synthesis of Compound 71

The compound 71 was synthesized by the following scheme.

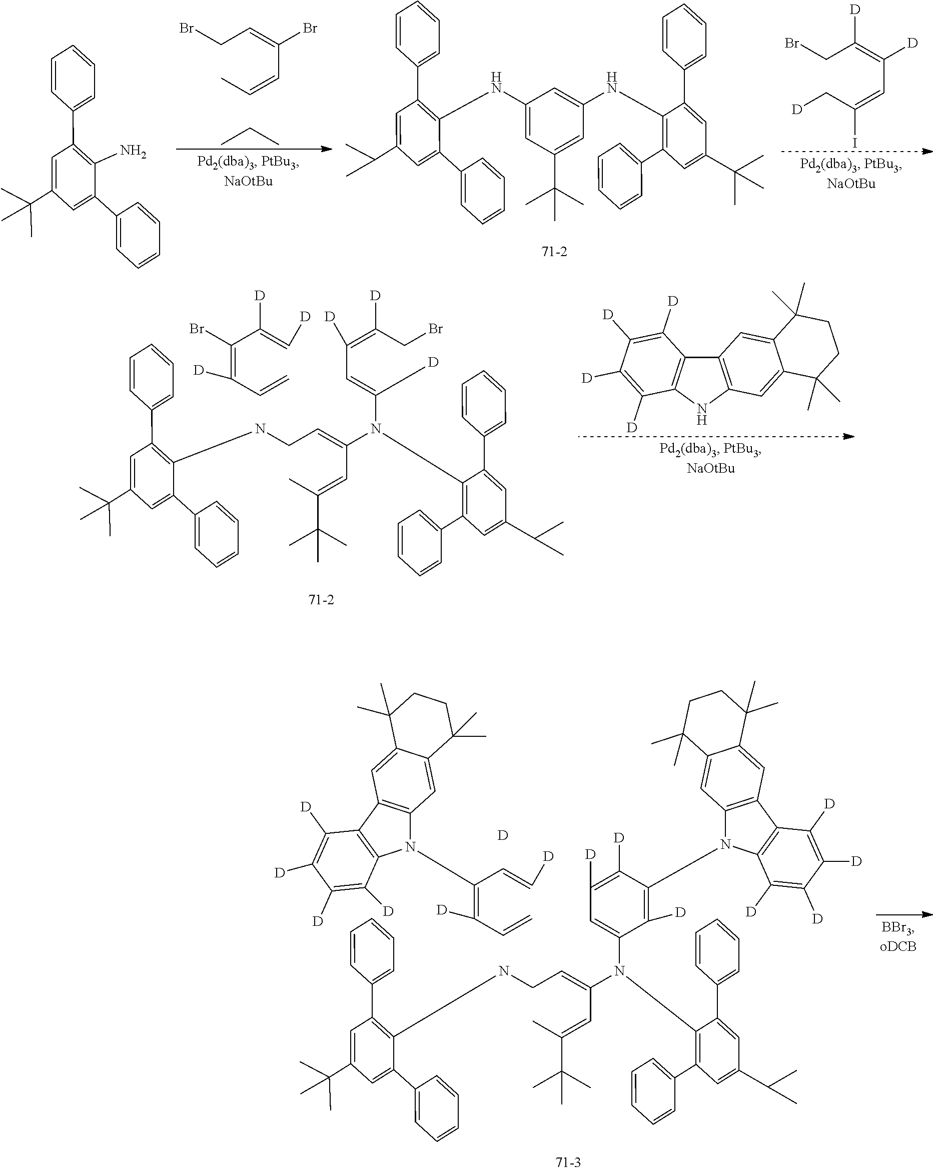

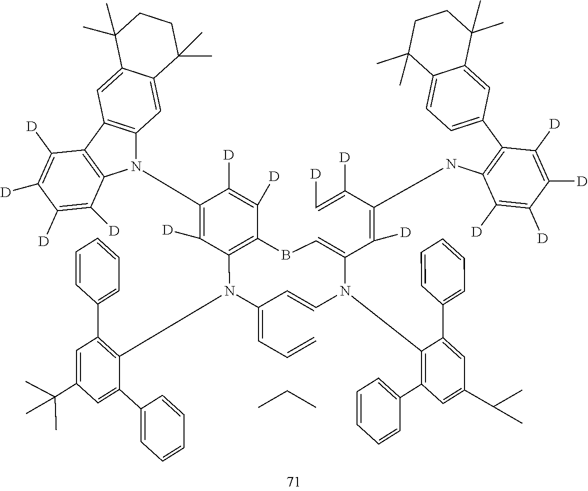

### Synthesis of Intermediate 71-1

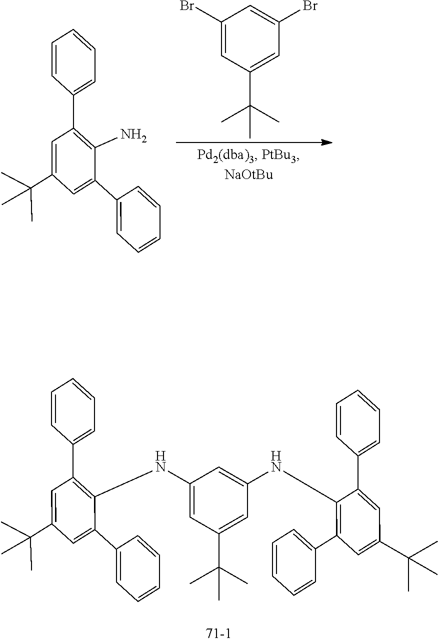 [SMILES: CC(C)(C)c1cc(-c2ccccc2)c(N)c(-c2ccccc2)c1 ; CC(C)(C)c1cc(Br)cc(Br)c1 ; CC(C)(C)c1cc(Nc2c(-c3ccccc3)cc(C(C)(C)C)cc2-c2ccccc2)cc(Nc2c(-c3ccccc3)cc(C(C)(C)C)cc2-c2ccccc2)c1]

1,3-Dibromo-5-(tert-butyl)benzene (1 eq), 5′-(tert-butyl)-[1,1′:3′,1″-terphenyl]-2′-amine (2 eq), Pd₂(dba)₃ (0.05 eq), tri-tert-butylphosphine (0.1 eq), and sodium tert-butoxide (1.5 eq) were dissolved in toluene to prepare a reaction solution. The reaction solution was stirred at 100° C. for 12 hours. After cooling the stirred solution, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as a developing solvent to obtain an intermediate 71-1 (yield: 60%).

### Synthesis of Intermediate 71-2

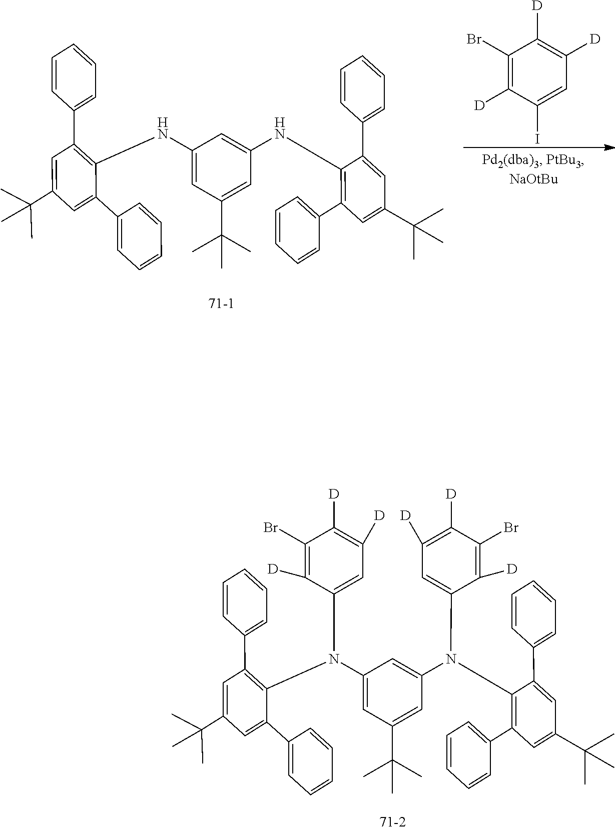

The intermediate 71-1 (1 eq), 1-bromo-3-iodobenzene-2,5,6-d3 (2 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as a developing solvent to obtain an intermediate 71-2 (yield: 65%).

### Synthesis of Intermediate 71-3

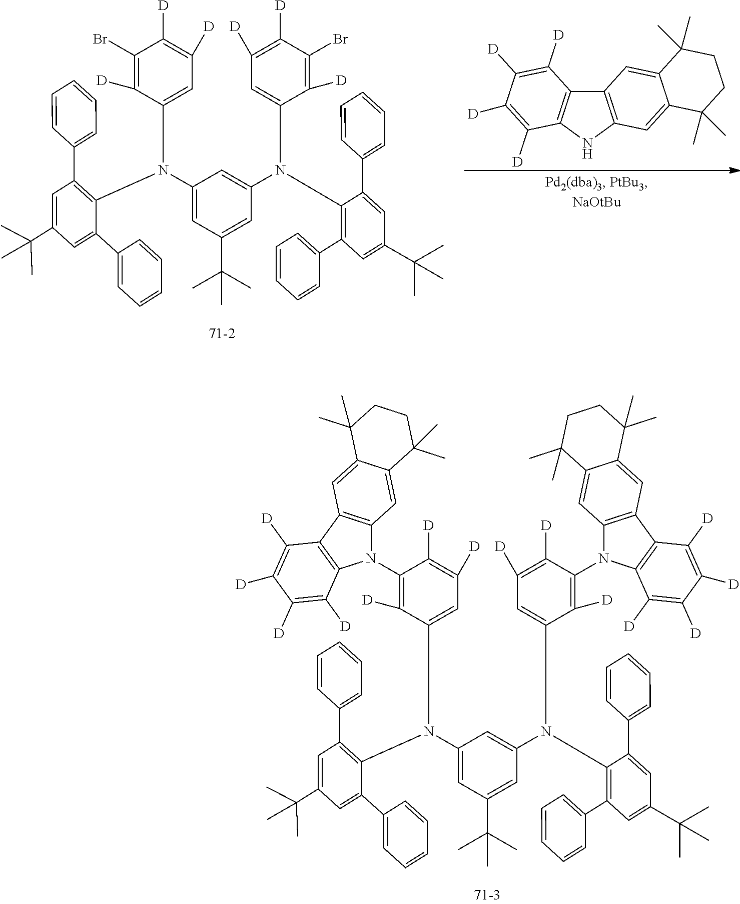

The intermediate 71-2 (1 eq), 7,7,10,10-tetramethyl-7,8,9,10-tetrahydro-5H-benzo[b]carbazole-1,2,3,4-d4 (2 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as a developing solvent to obtain an intermediate 71-3 (yield: 59%).

### Synthesis of Compound 71

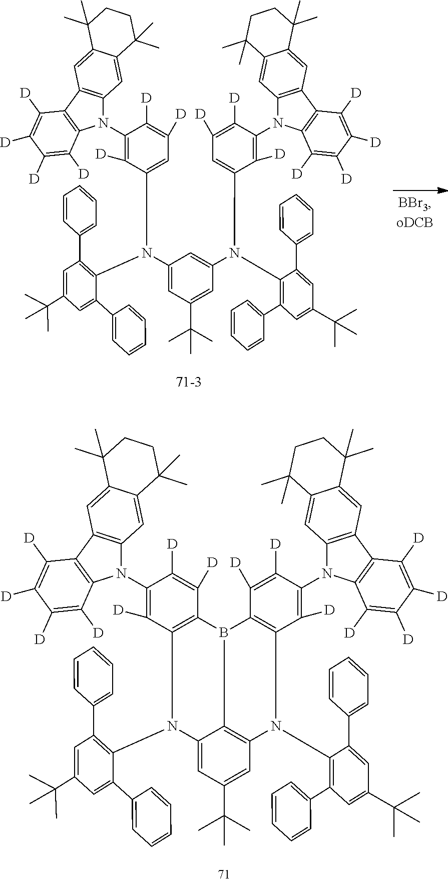

The intermediate 71-3 (1 eq) was dissolved in o-dichlorobenzene, cooled to 0° C., and BBr₃ (3 eq) was slowly added dropwise to the cooled solution under a nitrogen atmosphere. The reaction solution after the injection of BBr₃ was heated to 180° C., and the heated solution was stirred for 48 hours. The stirred solution was cooled to room temperature, and triethylamine was slowly added dropwise to the cooled solution to terminate the reaction.

Thereafter, ethyl alcohol was added, and a solid was obtained by precipitation and filtration. The obtained solid was purified and separated by silica gel column chromatography using CH₂Cl₂ and hexane as developing solvents, and then the compound 71 (yield: 1.3%) was obtained by recrystallization.

The MS/FAB analysis results (in mass-to-charge ratio (m/z)) of the obtained compound 71 are as follows.

C₁₀₆H₈₉D₁₄BN₄ cal. 1456.92, found 1456.93.

### Synthesis Example 3: Synthesis of Compound 102

The compound 102 was synthesized by the following scheme.

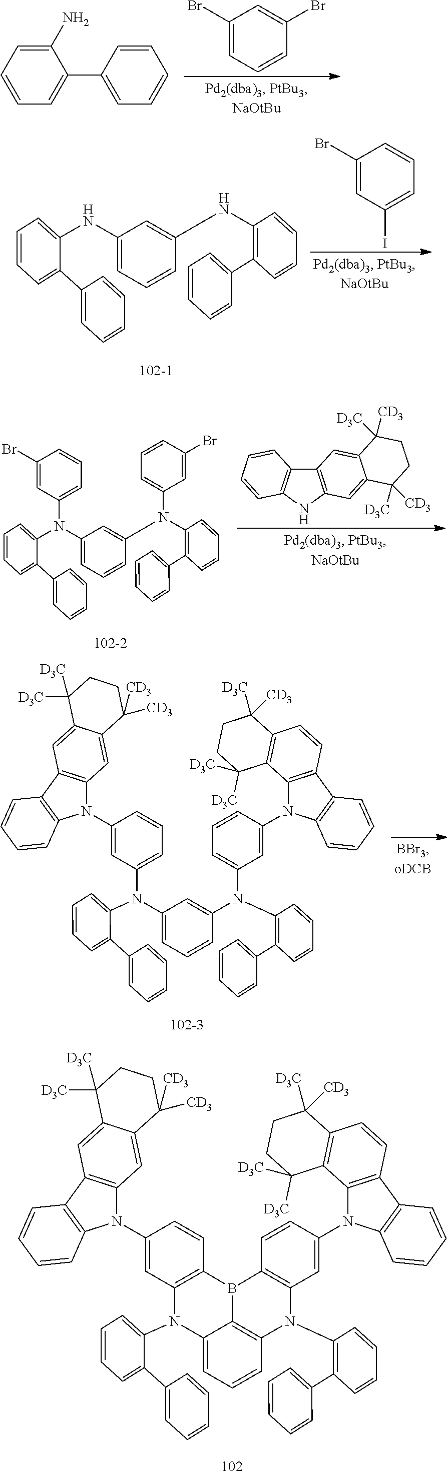

### Synthesis of Intermediate 102-1

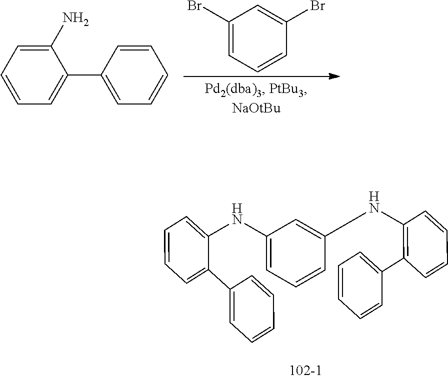 [SMILES: Nc1ccccc1-c1ccccc1 ; Brc1cccc(Br)c1 ; c1ccc(-c2ccccc2Nc2cccc(Nc3ccccc3-c3ccccc3)c2)cc1]

1,3-Dibromobenzene (1 eq), [1,1′-biphenyl]-2-amine (2 eq), Pd₂(dba)₃ (0.05 eq), tri-tert-butylphosphine (0.1 eq), and sodium tert-butoxide (1.5 eq) were dissolved in toluene to prepare a reaction solution. The reaction solution was stirred at 100° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as developing solvents to obtain an intermediate 102-1 (yield: 68%).

### Synthesis of intermediate 102-2

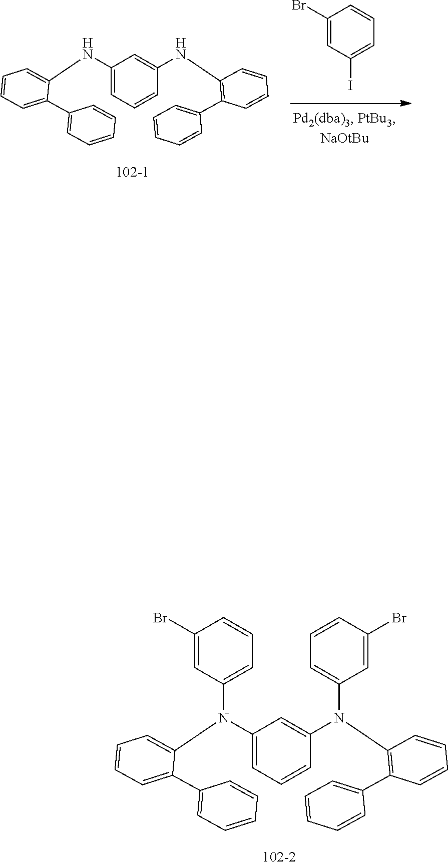 [SMILES: c1ccc(-c2ccccc2Nc2cccc(Nc3ccccc3-c3ccccc3)c2)cc1 ; Brc1cccc(I)c1 ; Brc1cccc(N(c2cccc(N(c3cccc(Br)c3)c3ccccc3-c3ccccc3)c2)c2ccccc2-c2ccccc2)c1]

An intermediate 102-1 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as developing solvents to obtain an intermediate 102-2 (yield: 71%).

### Synthesis of Intermediate 102-3

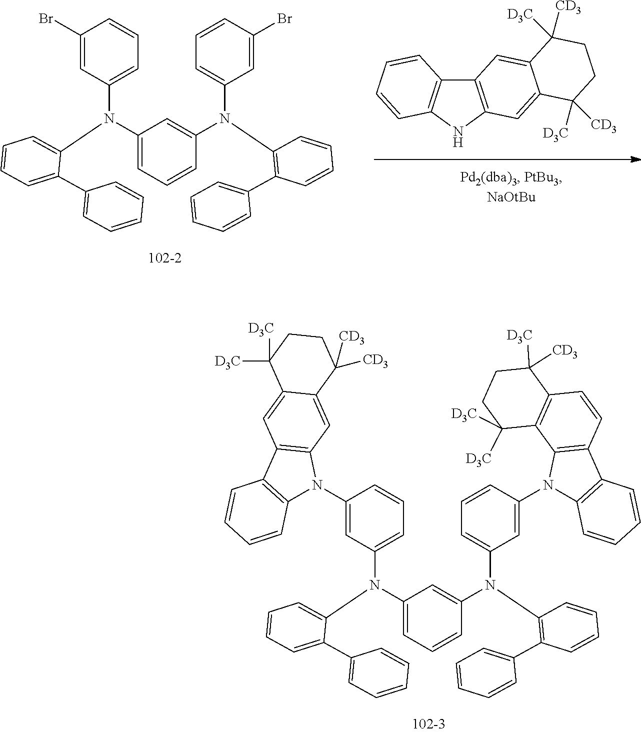 [SMILES: Brc1cccc(N(c2cccc(N(c3cccc(Br)c3)c3ccccc3-c3ccccc3)c2)c2ccccc2-c2ccccc2)c1 ; [2H]C([2H])([2H])C1(C([2H])([2H])[2H])CCC(C([2H])([2H])[2H])(C([2H])([2H])[2H])c2cc3c(cc21)[nH]c1ccccc13 ; [2H]C([2H])([2H])C1(C([2H])([2H])[2H])CCC(C([2H])([2H])[2H])(C([2H])([2H])[2H])c2cc3c(cc21)c1ccccc1n3-c1cccc(N(c2cccc(N(c3cccc(-n4c5ccccc5c5ccc6c(c54)C(C([2H])([2H])[2H])(C([2H])([2H])[2H])CCC6(C([2H])([2H])[2H])C([2H])([2H])[2H])c3)c3ccccc3-c3ccccc3)c2)c2ccccc2-c2ccccc2)c1]

The intermediate 102-2 (1 eq), 7,7,10,10-tetrakis(methyl-d3)-7,8,9,10-tetrahydro-5H-benzo[b]carbazole (2 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as developing solvents to obtain an intermediate 102-3 (yield: 65%).

### Synthesis of Compound 102

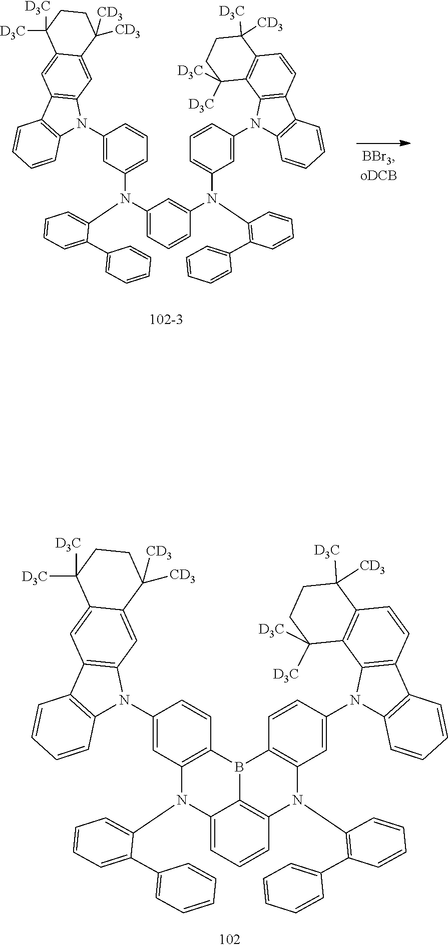

The intermediate 102-3 (1 eq) was dissolved in o-dichlorobenzene, cooled to 0° C., and BBr₃ (3 eq) was slowly added dropwise to the cooled solution under a nitrogen atmosphere. The reaction solution after the injection of BBr₃ was heated to 180° C., and the heated solution was stirred for 48 hours. The stirred solution was cooled to room temperature, and triethylamine was slowly added dropwise to the cooled solution to terminate the reaction. Thereafter, ethyl alcohol was added to the solution, and a solid was obtained by precipitation and filtration. The obtained solid was purified and separated by silica gel column chromatography using CH₂Cl₂ and hexane as developing solvents, and then the compound 102 (yield: 1.8%) was obtained by recrystallization.

The MS/FAB analysis results (in mass-to-charge ratio (m/z)) of the obtained compound 102 are as follows.

C₈₂H₄₇D₂₄BN₄ cal. 1146.73, found 1146.72.

### Synthesis Example 4: Synthesis of Compound 115

The compound 115 was synthesized by the following scheme.

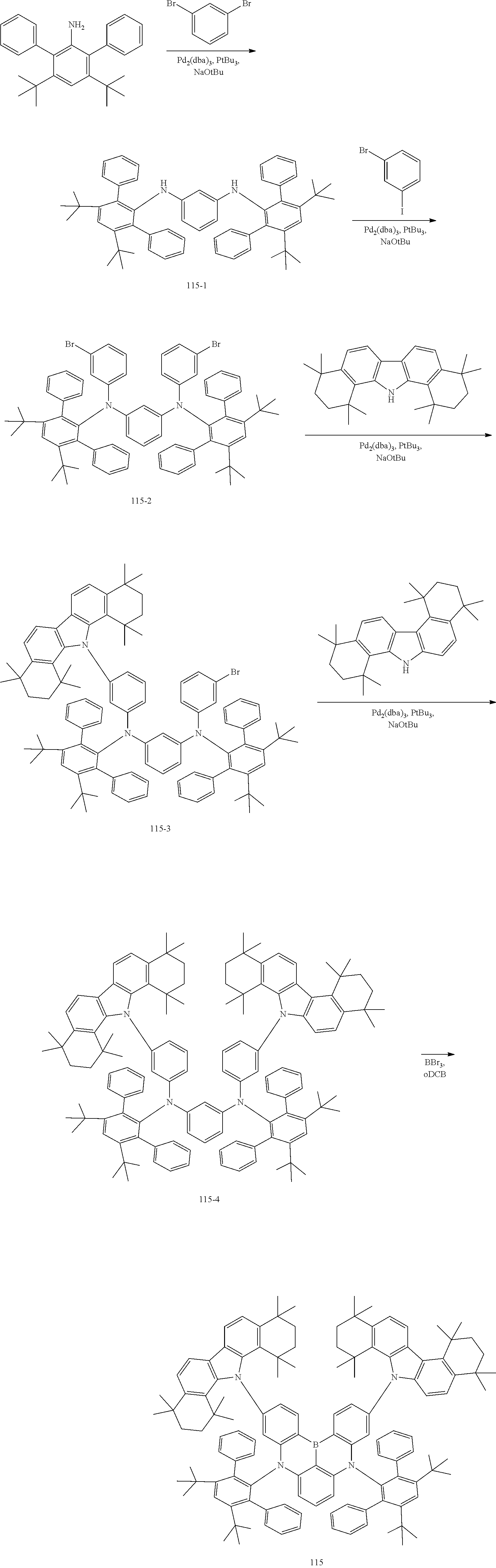

### Synthesis of Intermediate 115-1

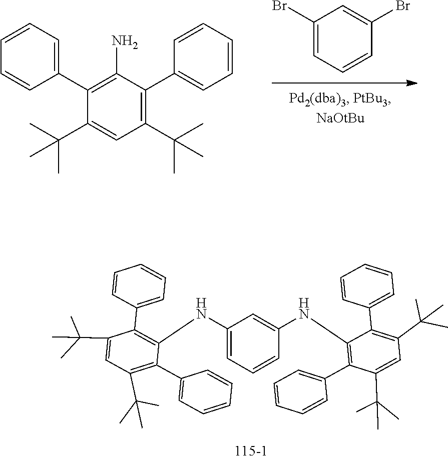 [SMILES: CC(C)(C)c1cc(C(C)(C)C)c(-c2ccccc2)c(N)c1-c1ccccc1 ; Brc1cccc(Br)c1 ; CC(C)(C)c1cc(C(C)(C)C)c(-c2ccccc2)c(Nc2cccc(Nc3c(-c4ccccc4)c(C(C)(C)C)cc(C(C)(C)C)c3-c3ccccc3)c2)c1-c1ccccc1]

1,3-Dibromobenzene (1 eq), 4′,6′-di-tert-butyl-[1,1′:3′,1″-terphenyl]-2′-amine (2 eq), Pd₂(dba)₃ (0.05 eq), tri-tert-butylphosphine (0.1 eq), and sodium tert-butoxide (1.5 eq) were dissolved in toluene to prepare a reaction solution. The reaction solution was stirred at 100° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure. The obtained solid was purified and separated by silica gel column chromatography using CH₂Cl₂ and hexane as developing solvents to obtain an intermediate 115-1 (yield: 62%).

### Synthesis of Intermediate 115-2

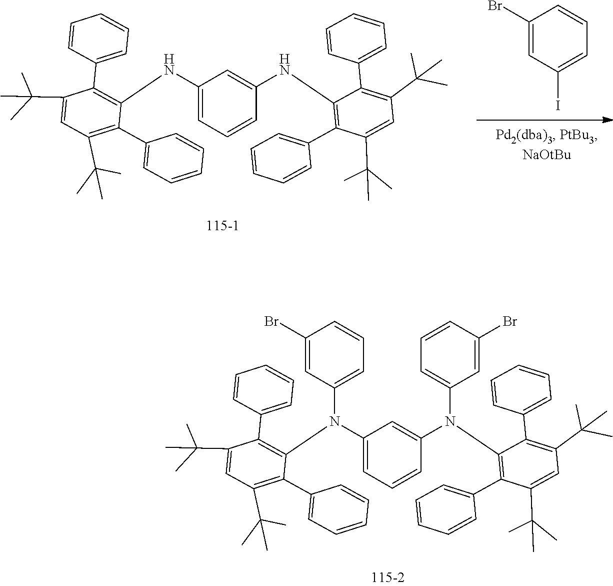

The intermediate 115-1 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as developing solvents to obtain an intermediate 115-2 (yield: 63%).

### Synthesis of Intermediate 115-3

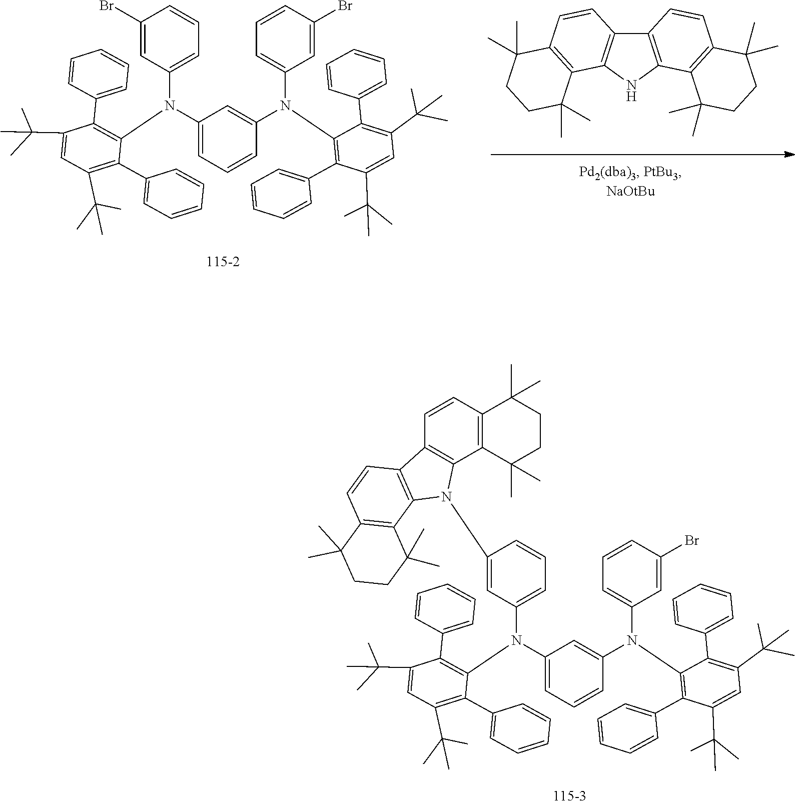

The intermediate 115-2 (1 eq), 1,1,4,4,9,9,12,12-octamethyl-2,3,4,9,10,11,12,13-octahydro-1H-dibenzo[a,i]carbazole (1 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure. The obtained solid was purified and separated by silica gel column chromatography using CH₂Cl₂ and hexane as developing solvents to obtain an intermediate 115-3 (yield: 62%).

### Synthesis of Intermediate 115-4

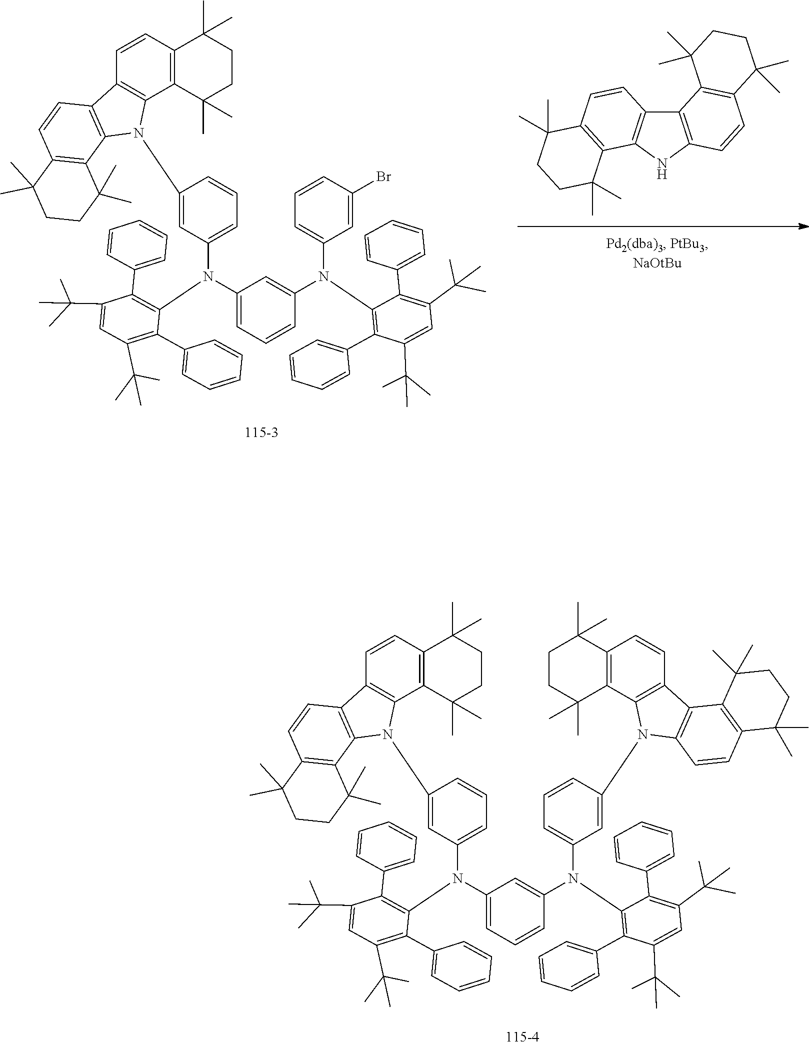

The intermediate 115-3 (1 eq), 1,1,4,4,8,8,11,11-octamethyl-2,3,4,7,8,9,10,11-octahydro-1H-dibenzo[a,g]carbazole (1 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as developing solvents to obtain an intermediate 115-4 (yield: 60%).

### Synthesis of Compound 115

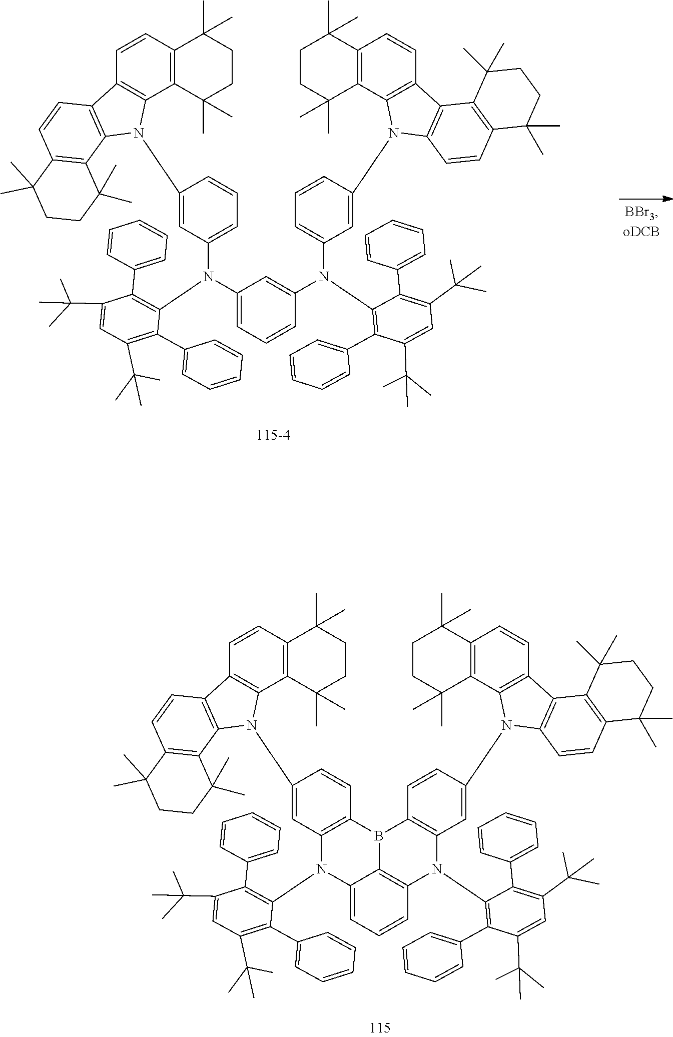

An intermediate 115-4 (1 eq) was dissolved in o-dichlorobenzene, cooled to 0° C., and BBr₃ (3 eq) was slowly added dropwise to the cooled solution under a nitrogen atmosphere. The reaction solution after the injection of BBr₃ was heated to 180° C., and the heated solution was stirred for 48 hours. The stirred solution was cooled to room temperature, and triethylamine was slowly added dropwise to the cooled solution to terminate the reaction.

Thereafter, ethyl alcohol was added, and a solid was obtained by precipitation and filtration. The obtained solid was purified and separated by silica gel column chromatography using CH₂Cl₂ and hexane as developing solvents, and then the compound 115 (yield: 1.4%) was obtained by recrystallization.

The MS/FAB analysis results (in mass-to-charge ratio (m/z)) of the obtained compound 115 are as follows.

C₁₂₆H₁₃₉BN₄ cal. 1719.11, found 1719.12.

### Synthesis Example 5: Synthesis of Compound 121

The compound 121 was synthesized by the following scheme.

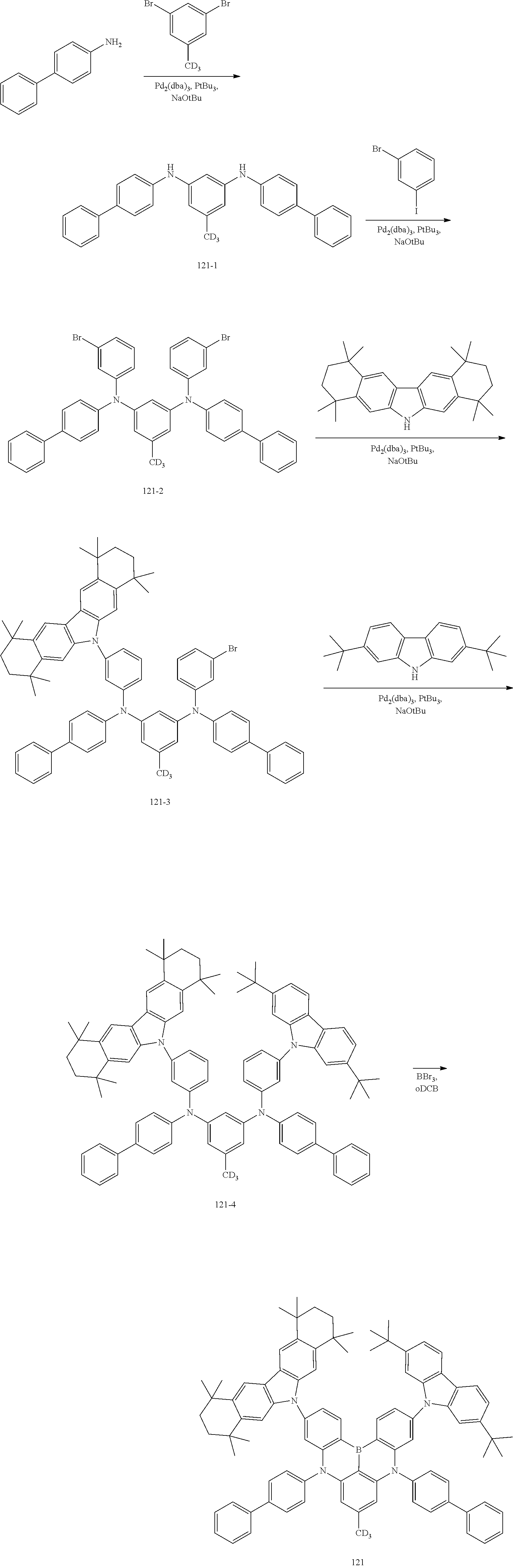

### Synthesis of Intermediate 121-1

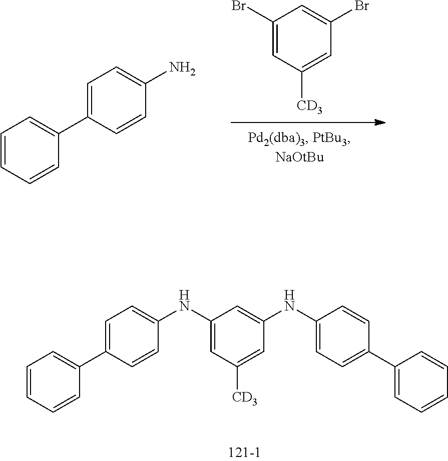 [SMILES: Nc1ccc(-c2ccccc2)cc1 ; [2H]C([2H])([2H])c1cc(Br)cc(Br)c1 ; [2H]C([2H])([2H])c1cc(Nc2ccc(-c3ccccc3)cc2)cc(Nc2ccc(-c3ccccc3)cc2)c1]

1,3-Dibromo-5-(methyl-d3)benzene (1 eq), [1,1′-biphenyl]-4-amine (2 eq), Pd₂(dba)₃ (0.05 eq), tri-tert-butylphosphine (0.1 eq), and sodium tert-butoxide (1.5 eq) were dissolved in toluene to prepare a reaction solution. The reaction solution was stirred at 100° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as developing solvents to obtain an intermediate 121-1 (yield: 65%).

### Synthesis of Intermediate 121-2

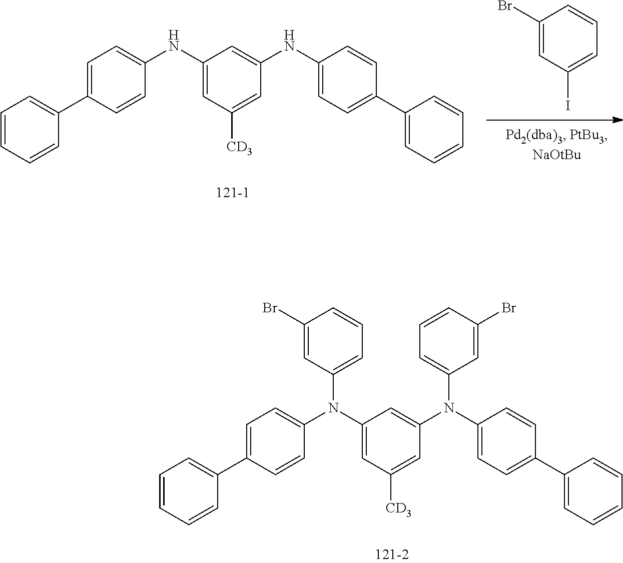 [SMILES: [2H]C([2H])([2H])c1cc(Nc2ccc(-c3ccccc3)cc2)cc(Nc2ccc(-c3ccccc3)cc2)c1 ; Brc1cccc(I)c1 ; [2H]C([2H])([2H])c1cc(N(c2ccc(-c3ccccc3)cc2)c2cccc(Br)c2)cc(N(c2ccc(-c3ccccc3)cc2)c2cccc(Br)c2)c1]

The intermediate 121-1 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂C₁₂ and hexane as developing solvents to obtain an intermediate 121-2 (yield: 67%).

### Synthesis of Intermediate 121-3

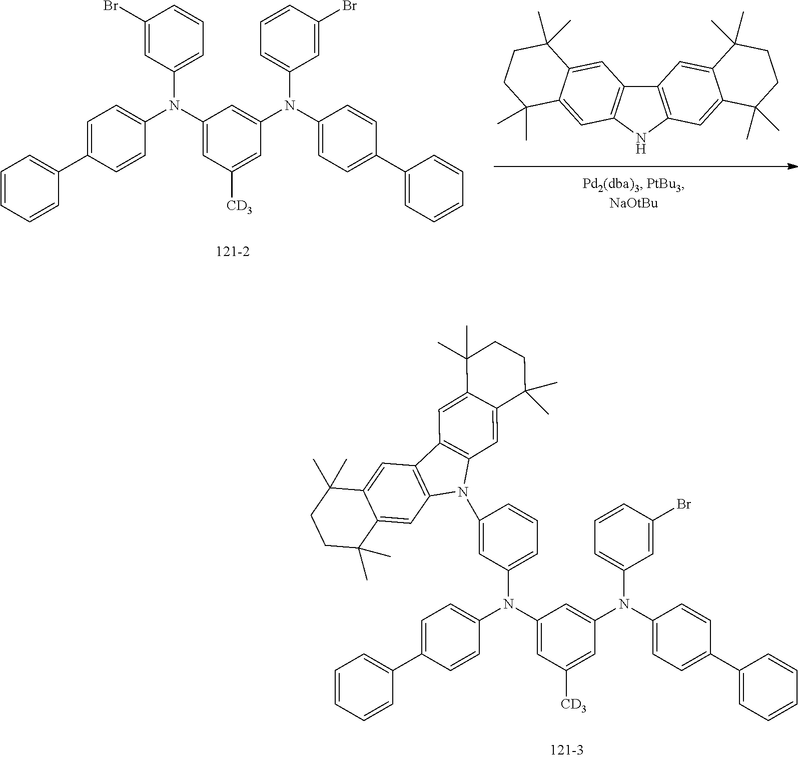

An intermediate 121-2 (1 eq), 1,1,4,4,8,8,11,11-octamethyl-2,3,4,6,8,9,10,11-octahydro-1H-dibenzo[b,h]carbazole (1 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as developing solvents to obtain an intermediate 121-3 (yield: 65%).

### Synthesis of intermediate 121-4

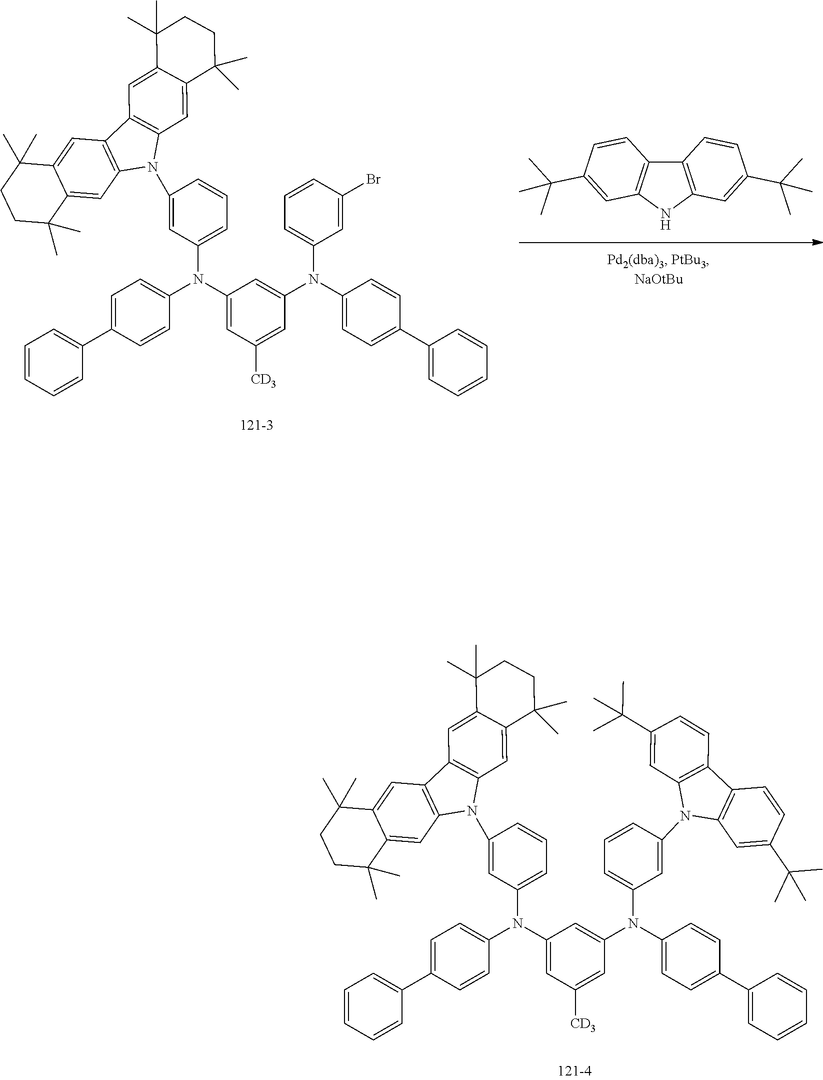 [SMILES: [2H]C([2H])([2H])c1cc(N(c2ccc(-c3ccccc3)cc2)c2cccc(Br)c2)cc(N(c2ccc(-c3ccccc3)cc2)c2cccc(-n3c4cc5c(cc4c4cc6c(cc43)C(C)(C)CCC6(C)C)C(C)(C)CCC5(C)C)c2)c1 ; CC(C)(C)c1ccc2c(c1)[nH]c1cc(C(C)(C)C)ccc12 ; [2H]C([2H])([2H])c1cc(N(c2ccc(-c3ccccc3)cc2)c2cccc(-n3c4cc(C(C)(C)C)ccc4c4ccc(C(C)(C)C)cc43)c2)cc(N(c2ccc(-c3ccccc3)cc2)c2cccc(-n3c4cc5c(cc4c4cc6c(cc43)C(C)(C)CCC6(C)C)C(C)(C)CCC5(C)C)c2)c1]

The intermediate 121-3 (1 eq), 2,7-di-tert-butyl-9H-carbazole (1 eq), Pd₂(dba)₃ (0.05 eq), tri-tert-butylphosphine (0.1 eq), and sodium tert-butoxide (3 eq) were dissolved in toluene to prepare a reaction solution. The reaction solution was stirred at 110° C. for 12 hours. After cooling the stirred solution to room temperature, the solution was washed three times with ethyl acetate and water, and the organic layer was extracted and separated. The separated organic layer was dried over MgSO₄ and filtered. The solvent was removed from the filtered solution under reduced pressure.

The obtained solid was purified and separated by silica gel column chromatography using CH₂Cl₂ and hexane as developing solvents to obtain an intermediate 121-4 (yield: 62%).

### Synthesis of Compound 121

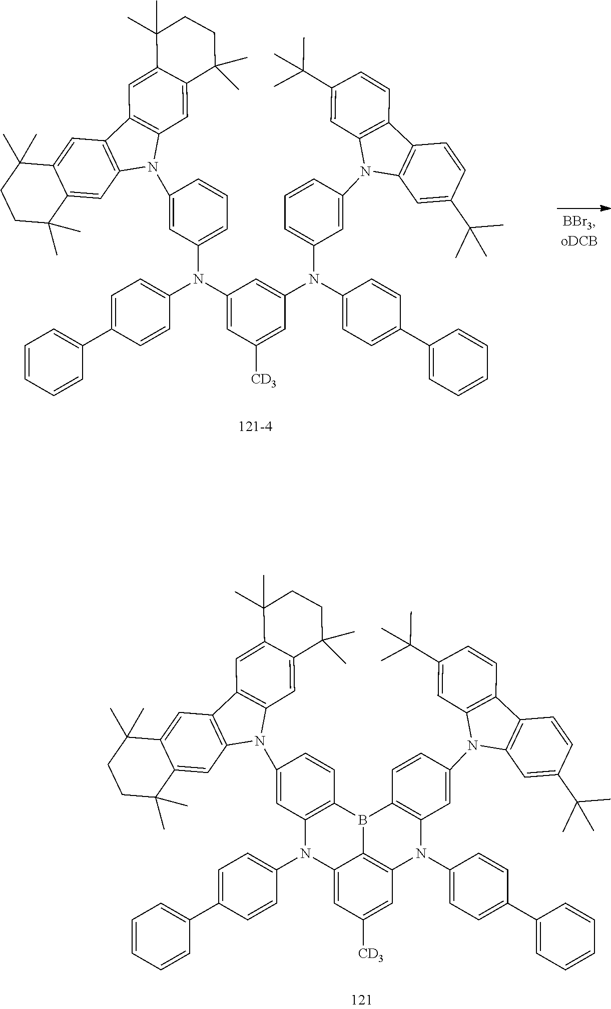 [SMILES: [2H]C([2H])([2H])c1cc(N(c2ccc(-c3ccccc3)cc2)c2cccc(-n3c4cc(C(C)(C)C)ccc4c4ccc(C(C)(C)C)cc43)c2)cc(N(c2ccc(-c3ccccc3)cc2)c2cccc(-n3c4cc5c(cc4c4cc6c(cc43)C(C)(C)CCC6(C)C)C(C)(C)CCC5(C)C)c2)c1 ; [2H]C([2H])([2H])c1cc2c3c(c1)N(c1ccc(-c4ccccc4)cc1)c1cc(-n4c5cc6c(cc5c5cc7c(cc54)C(C)(C)CCC7(C)C)C(C)(C)CCC6(C)C)ccc1B3c1ccc(-n3c4cc(C(C)(C)C)ccc4c4ccc(C(C)(C)C)cc43)cc1N2c1ccc(-c2ccccc2)cc1]

The intermediate 121-4 (1 eq) was dissolved in o-dichlorobenzene, cooled to 0° C., and BBr₃ (3 eq) was slowly added dropwise to the cooled solution under a nitrogen atmosphere. The reaction solution after the injection of BBr₃ was heated to 180° C., and the heated solution was stirred for 48 hours. The stirred solution was cooled to room temperature, and triethylamine was slowly added dropwise to the cooled solution to terminate the reaction.

Thereafter, ethyl alcohol was added, and a solid was obtained by precipitation and filtration. The obtained solid was purified and separated by silica gel column chromatography using CH₂Cl₂ and hexane as developing solvents, and then the compound 121 (yield: 1.8%) was obtained by recrystallization.

The MS/FAB analysis results (in mass-to-charge ratio (m/z)) of the obtained compound 121 are as follows.

C₉₁H₈₆D₃BN₄ cal. 1251.74, found 1251.73.

### Fabrication of Light-Emitting Device

As the first electrode, a glass substrate (Corning product) on which a 15 Ω/cm² (1200 Å) ITO electrode was formed was cut into a size of 50 mm×50 mm×0.7 mm, and the cut substrate was ultrasonically cleaned for 5 minutes using isopropyl alcohol and pure water. The ultrasonically cleaned substrate was irradiated with an ultraviolet ray for 30 minutes and exposed to ozone, and then mounted on a vacuum deposition device.

Thereafter, N,N′-di(naphthalene-I-yl)-N,N′-diphenyl-benzidine (NPB) was deposited on the first electrode to form or provide a hole injection layer having a thickness of 300 Å. HT-13 was deposited on the hole injection layer to form or provide a hole transport layer having a thickness of 200 Å. 9-(4-tert-Butylphenyl)-3,6-bis(triphenylsilyl)-9H-carbazole (CzSi) was deposited on the hole transport layer to form or provide an auxiliary emission layer having a thickness of 100 Å.

A host mixture of PH-13 and ET-17 in a weight ratio of 1:1, PD1-14, and each compound of Examples or Comparative Examples were co-deposited in a weight ratio of 82:15:3 on the auxiliary emission layer to form or provide an emission layer having a thickness of 200 Å.

Diphenyl(4-(triphenylsilyl)phenyl)phosphine oxide (TSPO1) was deposited on the emission layer to form or provide an electron blocking layer having a thickness of 200 Å. Thereafter, 1,3,5-tri(1-phenyl-1H-benzo[d]imidazol-2-yl)benzene (TPBi) was deposited on the electron blocking layer to form or provide an electron transport layer having a thickness of 300 Å, and then LiF was deposited on the electron transport layer to form or provide an electron injection layer having a thickness of 10 Å. Subsequently, Al was deposited on the electron injection layer to form or provide a second electrode having a thickness of 3000 Å, and then HT-7 was deposited on the second electrode to form or provide a capping layer having a thickness of 700 Å, thereby fabricating a light-emitting device. Each layer was formed or provided by a vacuum deposition method.

Commercially available products purified by sublimation were used for the fabrication of the device as shown below.

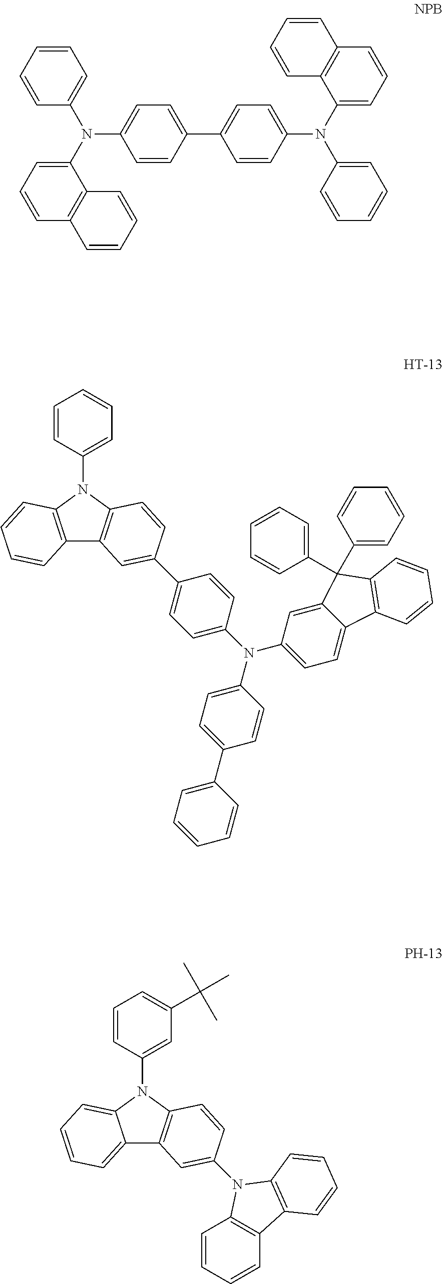 [SMILES: c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC(C)(C)c1cccc(-n2c3ccccc3c3cc(-n4c5ccccc5c5ccccc54)ccc32)c1]

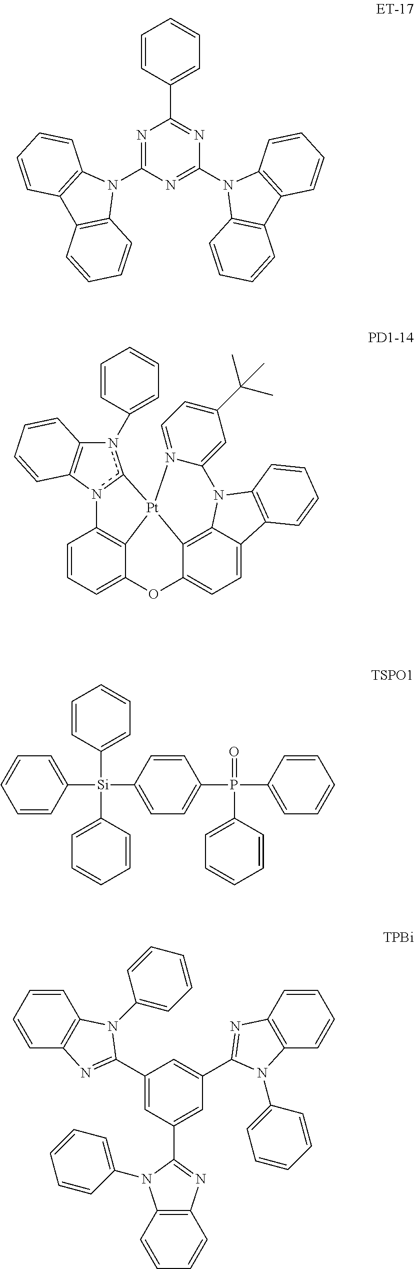

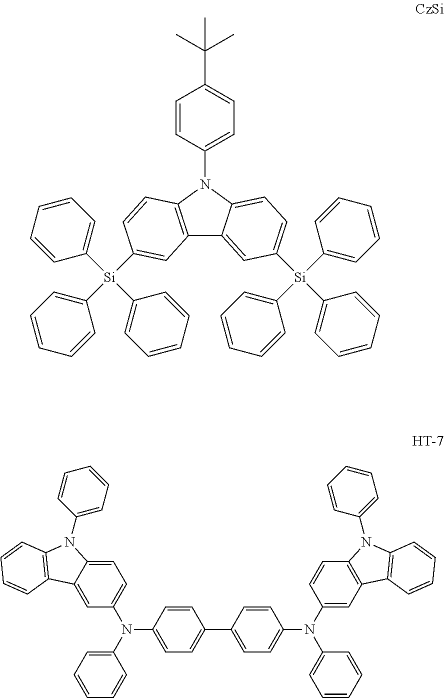 [SMILES: CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

### Evaluation Example

### Evaluation Example 1. Evaluation on Properties of Polycyclic Compounds

Properties of compounds of Examples and Comparative Examples as shown below were evaluated.

### Compounds of Examples

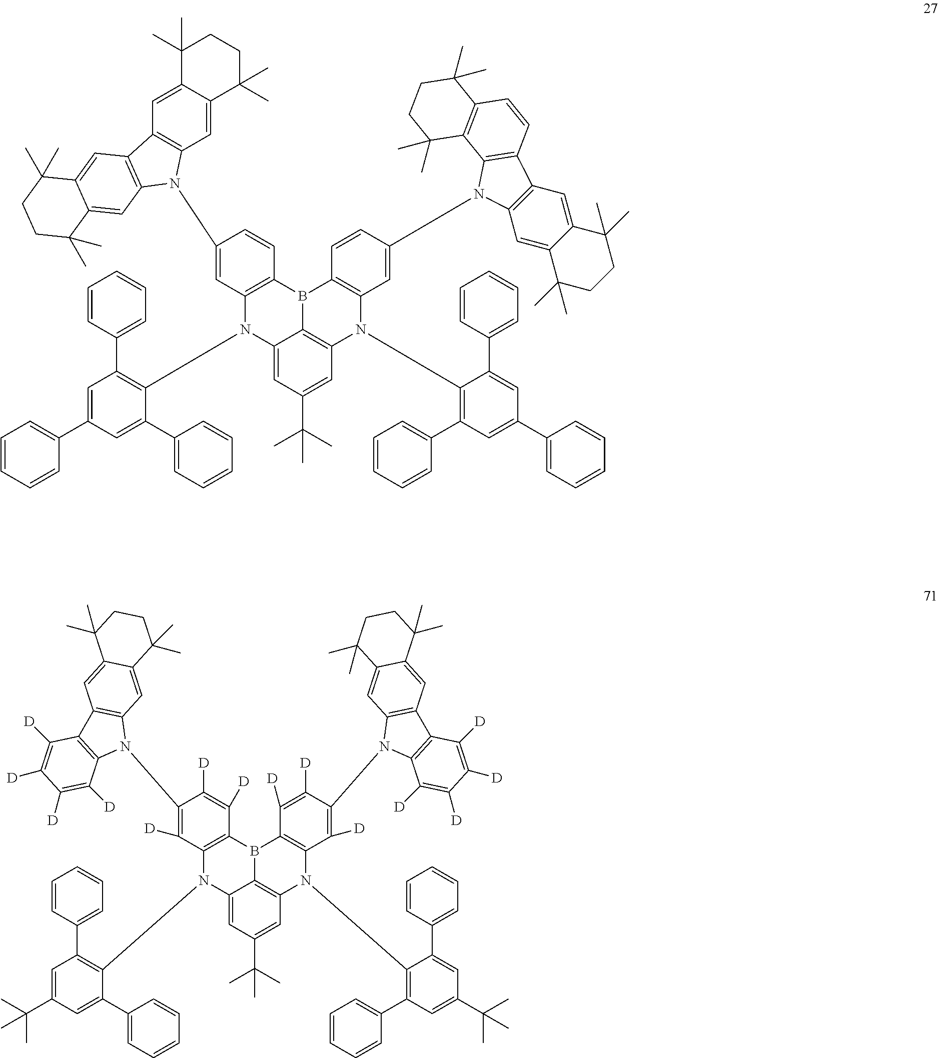

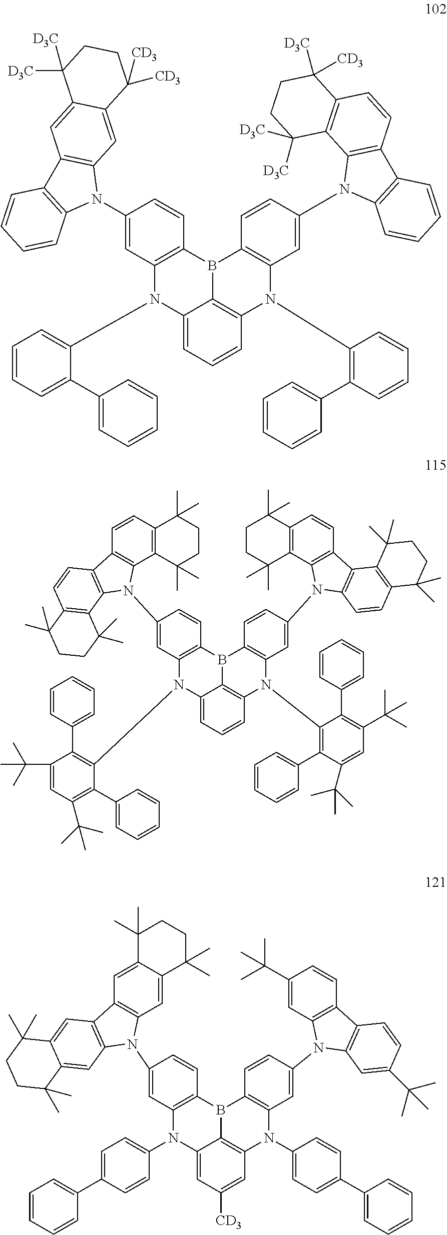

### Compounds of Comparative Examples

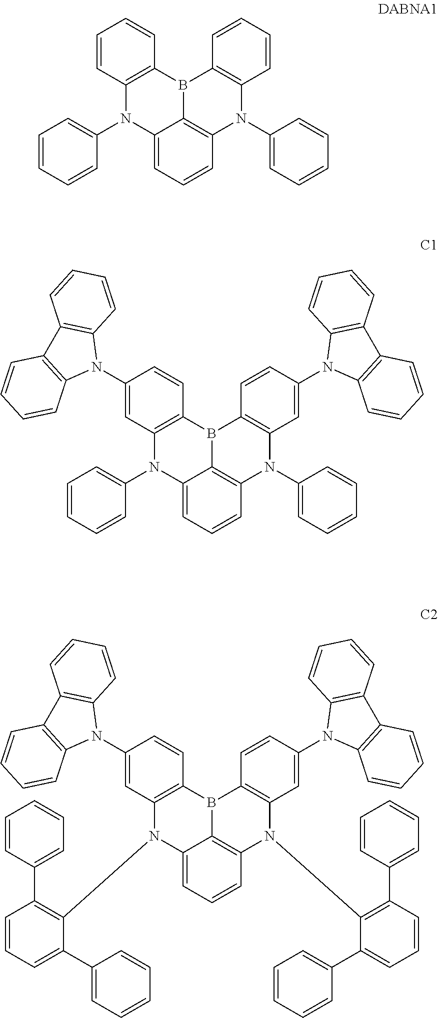 [SMILES: c1ccc(N2c3ccccc3B3c4ccccc4N(c4ccccc4)c4cccc2c43)cc1 ; c1ccc(N2c3cc(-n4c5ccccc5c5ccccc54)ccc3B3c4ccc(-n5c6ccccc6c6ccccc65)cc4N(c4ccccc4)c4cccc2c43)cc1 ; c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cccc2c43)cc1]

The highest occupied molecular orbital (HOMO) and lowest unoccupied molecular orbital (LUMO) energy levels (eV), an oscillator strength (f), an up-conversion rate constant (k_{RISC}, s⁻¹) from a triplet state to a singlet state, and energy levels (eV) of triplet and singlet states of the above compounds were evaluated by a density functional theory (DFT) method of Gaussian 09 program with a structure optimization at B3LYP/6-311 G** level.

The results are shown in Table 1.

TABLE 1

| | E_{HOMO} | E_{LUMO} | E_{S1} | E_{T1} | ΔE_{ST} | oscillator | |
|---|---|---|---|---|---|---|---|
| | [eV] | [eV] | [eV] | [eV] | [eV] | strength | K_{RISC} [s⁻¹] |
| Example 1 | −5.14 | −1.63 | 2.99 | 2.62 | 0.37 | 0.45 | 5.33E+05 |
| Example 2 | −5.17 | −1.64 | 2.99 | 2.62 | 0.37 | 0.39 | 3.58E+05 |
| Example 3 | −5.16 | −1.64 | 2.99 | 2.61 | 0.38 | 0.36 | 1.74E+05 |
| Example 4 | −5.15 | −1.64 | 3.00 | 2.63 | 0.37 | 0.42 | 4.62E+05 |
| Example 5 | −5.15 | −1.63 | 3.00 | 2.62 | 0.38 | 0.41 | 1.87E+05 |
| Comparative | −5.00 | −1.37 | 3.10 | 2.62 | 0.48 | 0.20 | 2.26E+03 |
| Example 1 | | | | | | | |
| Comparative | −5.27 | −1.73 | 2.99 | 2.57 | 0.42 | 0.35 | 2.79E+04 |
| Example 2 | | | | | | | |
| Comparative | −5.26 | −1.71 | 2.99 | 2.59 | 0.40 | 0.34 | 3.13E+04 |
| Example 3 | | | | | | | |

Referring to Table 1, in the polycyclic compounds according to Examples, small energy level (eV) difference (ΔE_{ST}) between the triplet and singlet states and high oscillator strength were provided. In the polycyclic compounds according to Example 1, K_{Risc} was also increased.

In the polycyclic compounds according to Comparative Examples, ΔE_{ST} was increased.

### Evaluation Example 2. Performance Evaluation of Light-Emitting Device

Properties of the light-emitting device manufactured according to the method as described in one or more embodiments were measured at a current density of 10 mA/cm² based on V7000 OLED IVL Test System, (Polaronix). For example, a driving voltage (V), a luminous efficiency (Cd/A), and an emission wavelength at a luminance of 1000 cd/m² were measured using Keithley MU 236 and a luminance meter PR650. The light-emitting device was continuously (e.g., substantially continuously) driven at a current density of 10 mA/cm², and a time until the luminance dropped from the initial value to 95% of the initial value was measured. A relative value based on the time measured in the light-emitting device using the compound of Comparative Example 1 was expressed as a life-span (T95) of each light-emitting device.

TABLE 2

| | | | emission | driving | | emission | life-span |
|---|---|---|---|---|---|---|---|
| | host | sensitizer | material | voltage | efficiency | wavelength | ratio |
| | (PH:ET = 1:1) | (15 wt %) | (3 wt %) | (V) | (cd/A) | (nm) | (T95, %) |
| Example 1 | PH-13:ET-17 | PD1-14 | 27 | 4.1 | 37.4 | 455 | 8.8 |
| Example 2 | PH-13:ET-17 | PD1-14 | 71 | 4.0 | 34.5 | 456 | 8.1 |
| Example 3 | PH-13:ET-17 | PD1-14 | 102 | 4.3 | 30.8 | 456 | 6.7 |
| Example 4 | PH-13:ET-17 | PD1-14 | 115 | 4.2 | 35.7 | 455 | 8.4 |
| Example 5 | PH-13:ET-17 | PD1-14 | 121 | 4.3 | 33.2 | 455 | 7.3 |
| Comparative | PH-13:ET-17 | PD1-14 | DABNA1 | 4.8 | 19.2 | 457 | 1 |
| Example 1 | | | | | | | |
| Comparative | PH-13:ET-17 | PD1-14 | C1 | 4.5 | 23.2 | 458 | 2.2 |
| Example 2 | | | | | | | |
| Comparative | PH-13:ET-17 | PD1-14 | C2 | 4.4 | 24.1 | 460 | 4.5 |
| Example 3 | | | | | | | |

Referring to Table 2, the polycyclic compounds according to Examples having improved or enhanced multiple (e.g., two or more) resonance effect provided enhanced luminous efficiency and color properties of the light-emitting device. Also, in the polycyclic compounds according to Examples, an alicyclic ring was condensed to an aromatic ring of a carbazole group introduced into an aromatic core containing boron, so that Foster energy transfer was induced rather than Dexter energy transfer. Thus, luminous efficiency and life-span properties of the light-emitting device were enhanced.

In the polycyclic compounds according to Comparative Examples, energy transfer between triplet excitons due to Dexter energy transfer occurred more easily. Accordingly, luminous efficiency and life-span properties of the light-emitting device were deteriorated.

While the subject matter of the present disclosure has been described in connection with what is presently considered to be practical example embodiments, it is to be understood that the present disclosure is not limited to the disclosed embodiments, but, in one or more embodiments, is intended to cover one or more suitable modifications and equivalent arrangements included within the spirit and scope of the appended claims and equivalents thereof. It therefore will be understood that one or more embodiments described herein are just illustrative but not limitative in all aspects.

1. A polycyclic compound represented by Chemical Formula 1: 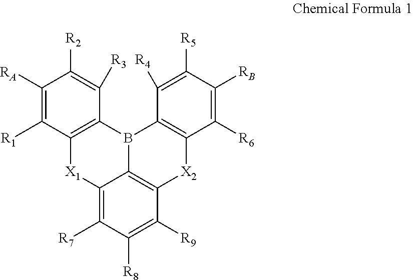
wherein, in Chemical Formula 1, X₁ and X₂ are each independently N(R₁₀), S, O, or Se,
R₁ to R₁₀ are each independently hydrogen, deuterium, a hydroxyl group, a cyano group, —F, —Cl, —Br, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₆-C₆₀ arylalkyl group, a substituted or unsubstituted C₂-C₆₀ heteroaryl group, a substituted or unsubstituted C₂-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group,
two or more adjacent groups selected from among R₁ to R₉ are optionally combined with each other to form a saturated ring or an unsaturated ring,
R_{A} and R_{B} are the same as or different from each other and are each independently a substituted or unsubstituted carbazole group, and
at least one selected from R_{A} and R_{B} is selected from the group consisting of carbazole groups having a structure in which an alicyclic hydrocarbon ring group is condensed to one or two of two six-membered benzene rings fused at both sides of one five-membered nitrogen-containing ring of the carbazole group.

2. The polycyclic compound as claimed in claim 1, wherein the alicyclic hydrocarbon ring group is selected from among a 5-membered ring to a 9-membered ring.

3. The polycyclic compound as claimed in claim 1, wherein the alicyclic hydrocarbon ring group is selected from among a substituted or unsubstituted cycloalkane, a substituted or unsubstituted bicycloalkane, and a substituted or unsubstituted spiroalkane.

4. The polycyclic compound as claimed in claim 1, wherein R_{A} is represented by Chemical Formula 2-1, and R_{B} is represented by Chemical Formula 2-2: 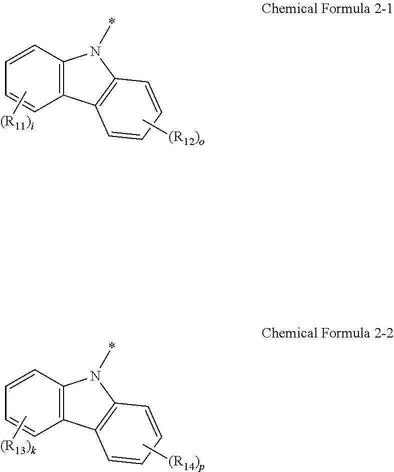
wherein, in Chemical Formulae 2-1 and 2-2, R₁₁ to R₁₄ are the same as or different from each other and are each independently hydrogen, deuterium, —F, —Cl, —Br, —CD₃, —CD₂H, —CDH₂, —CF₃, —CF₂H, —CFH₂, a substituted or unsubstituted C₁-C₆₀ alkyl group, a substituted or unsubstituted C₃-C₆₀ cycloalkyl group, a substituted or unsubstituted C₆-C₆₀ arylalkyl group, a substituted or unsubstituted C₂-C₆₀ heteroarylalkyl group, or a substituted or unsubstituted silyl group, and
i, o, k, and p are each independently an integer of 0 to 4,
wherein two or more adjacent R₁₁ are optionally combined with each other to form an alicyclic hydrocarbon ring group,
two or more adjacent R₁₂ are optionally combined with each other to form an alicyclic hydrocarbon ring group,
two or more adjacent R₁₃ are optionally combined with each other to form an alicyclic hydrocarbon ring group, and
two or more adjacent R₁₄ are optionally combined with each other to form an alicyclic hydrocarbon ring group,
wherein R_{A} comprises at least one selected from the alicyclic hydrocarbon ring group formed by two or more R₁₁ and the alicyclic hydrocarbon ring group formed by two or more R₁₂; R_{B} comprises at least one selected from the alicyclic hydrocarbon ring group formed by two or more R₁₃ and the alicyclic hydrocarbon ring group formed by two or more R₁₄; or R_{A} comprises at least one selected from the alicyclic hydrocarbon ring group formed by two or more R₁₁ and the alicyclic hydrocarbon ring group formed by two or more R₁₂, and R_{B} comprises at least one selected from the alicyclic hydrocarbon ring group formed by two or more R₁₃ and the alicyclic hydrocarbon ring group formed by two or more R₁₄.

5. The polycyclic compound as claimed in claim 4, wherein at least one selected from among the alicyclic hydrocarbon ring group formed by two or more R₁₁, the alicyclic hydrocarbon ring group formed by two or more R₁₂, the alicyclic hydrocarbon ring group formed by two or more R₁₃, and the alicyclic hydrocarbon ring group formed by two or more R₁₄ is selected from among a substituted or unsubstituted C₄-C₉ cycloalkane, a substituted or unsubstituted C₅-C₃₀ bicycloalkane, and a substituted or unsubstituted C₈-C₃₀ spiroalkane.

6. The polycyclic compound as claimed in claim 5, wherein at least one selected from among the alicyclic hydrocarbon ring group formed by two or more R₁₁, the alicyclic hydrocarbon ring group formed by two or more R₁₂, the alicyclic hydrocarbon ring group formed by two or more R₁₃, and the alicyclic hydrocarbon ring group formed by two or more R₁₄ is selected from the group consisting of a substituted or unsubstituted cyclopentane, a substituted or unsubstituted cyclohexane, a substituted or unsubstituted cycloheptane, a substituted or unsubstituted bicyclo[2.1.0]pentane, a substituted or unsubstituted bicyclo[2.2.0]hexane, a substituted or unsubstituted bicyclo[4.1.0]heptane, a substituted or unsubstituted spiro[5.5]undecane, a substituted or unsubstituted spiro[4.4]nonane, a substituted or unsubstituted spiro[3.4]octane, a substituted or unsubstituted spiro[4.5]decane, and a substituted or unsubstituted spiro[6.6]tridecane.

7. The polycyclic compound as claimed in claim 4, R_{A} and R_{B} are the same as or different from each other and are each independently represented by one selected from among Chemical Formulae 3-1 to 3-6: 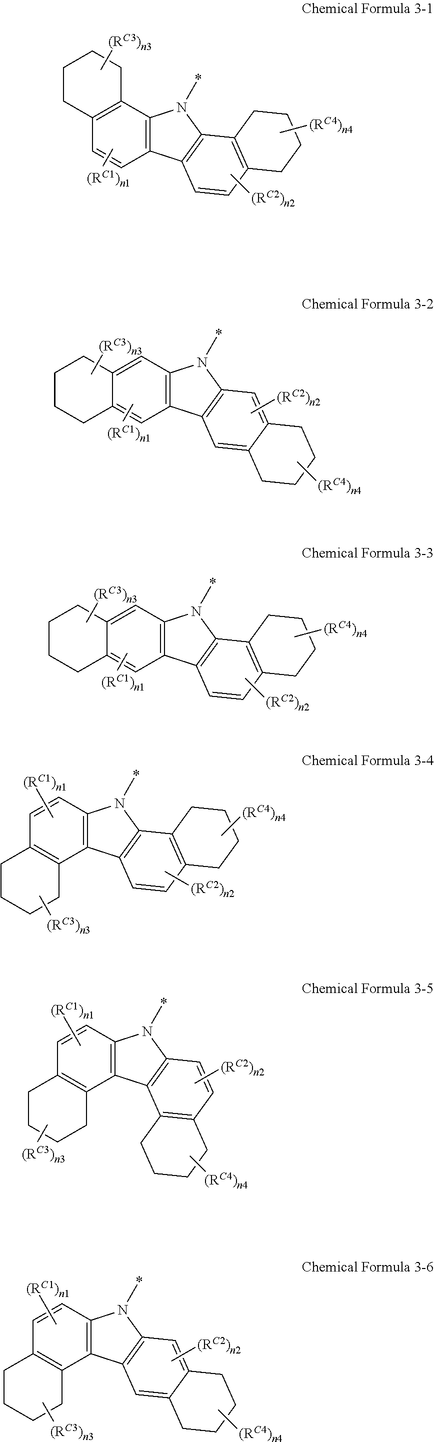
wherein, in Chemical Formulae 3-1 to 3-6, R^{c1} and R^{c2} are the same as or different from each other and are each independently hydrogen, deuterium, —F, —Cl, —Br, —CD₃, —CD₂H, —CDH₂, —CF₃, —CF₂H, —CFH₂, a substituted or unsubstituted C₁-C₃₀ alkyl group, or a substituted or unsubstituted C₃-C₃₀ cycloalkyl group,
R^{c3} and R^{c4} are the same as or different from each other and are each independently hydrogen, deuterium, —CD₃, —CD₂H, —CDH₂, a substituted or unsubstituted C₁-C₃₀ alkyl group, or a substituted or unsubstituted C₃-C₃₀ cycloalkyl group,
n1 and n2 are the same as or different from each other and are each independently an integer of 0 to 2,
n3 and n4 are the same as or different from each other and are each independently an integer of 0 to 8,
two or more adjacent R^{c3} are optionally combined with each other to form a saturated ring, and
two or more adjacent R^{c4} are optionally combined with each other to form a saturated ring.

8. The polycyclic compound as claimed in claim 7, R_{A} and R_{B} are the same as or different from each other and are each independently represented by one selected from the Chemical Formulae 3-2 and 3-3.

9. The polycyclic compound as claimed in claim 1, wherein the polycyclic compound represented by Chemical Formula 1 is represented by one selected from among Chemical Formulae 1-1 to 1-6: 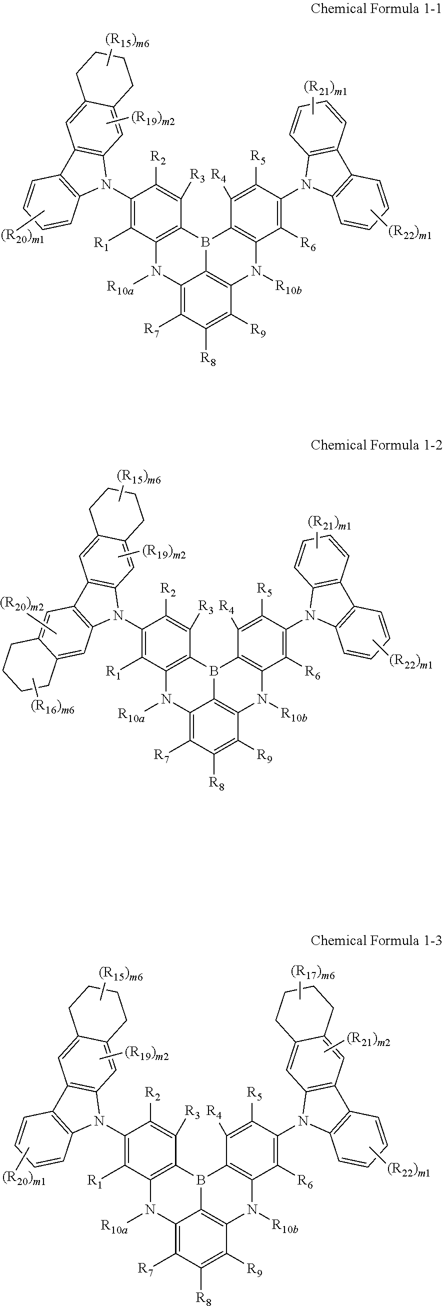 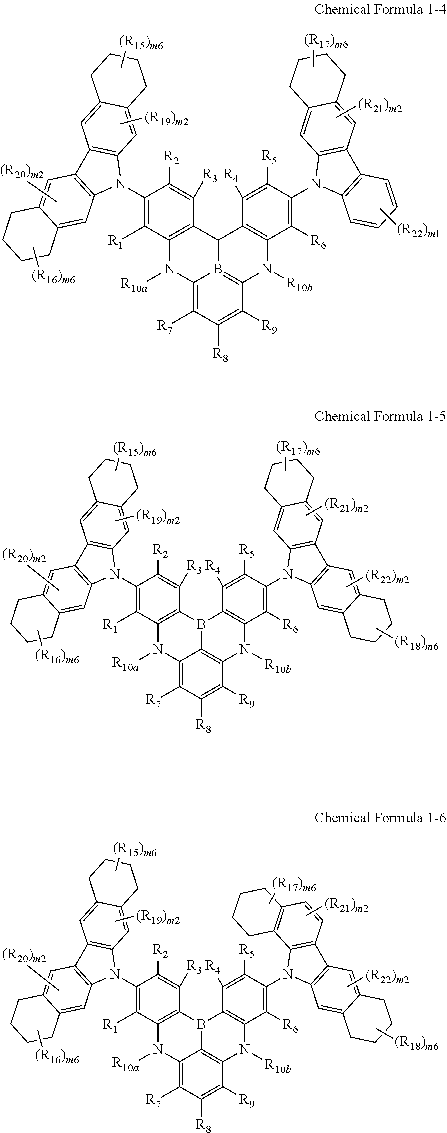
wherein, in Chemical Formulae 1-1 to 1-6, R₁ to R₉, R₁₀ₐ, and R_{10b} are each independently hydrogen, deuterium, a hydroxyl group, a cyano group, —F, —Cl, —Br, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₆-C₆₀ arylalkyl group, a substituted or unsubstituted C₂-C₆₀ heteroaryl group, a substituted or unsubstituted C₂-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group,
two or more adjacent groups selected from among R₁ to R₉ are optionally combined with each other to form a saturated ring or an unsaturated ring,
R₁₅ to R₁₈ are the same as or different from each other and are each independently hydrogen, deuterium, —CD₃, —CD₂H, —CDH₂, a substituted or unsubstituted C₁-C₃₀ alkyl group, or a substituted or unsubstituted C₃-C₃₀ cycloalkyl group,
R₁₉ to R₂₂ are the same as or different from each other and are each independently hydrogen, deuterium, —F, —Cl, —Br, —CD₃, —CD₂H, —CDH₂, a substituted or unsubstituted C₁-C₃₀ alkyl group, or a substituted or unsubstituted C₃-C₃₀ cycloalkyl group,
a plurality of m1 are each independently an integer of 0 to 4, a plurality of m2 are each independently an integer of 0 to 2, and a plurality of m6 are each independently an integer of 0 to 8, and
two or more adjacent R₁₅ are optionally combined with each other to form a saturated ring, two or more adjacent R₁₆ are optionally combined with each other to form a saturated ring, two or more adjacent R₁₇ are optionally combined with each other to form a saturated ring, and two or more adjacent R₁₈ are optionally combined with each other to form a saturated ring.

10. The polycyclic compound as claimed in claim 9, wherein the polycyclic compound is represented by one selected from the Chemical Formulae 1-5 and 1-6.

11. The polycyclic compound as claimed in claim 9, wherein R₁₀ₐ and R_{10b} are each independently represented by one selected from among Chemical Formulae 4-1 to 4-12: 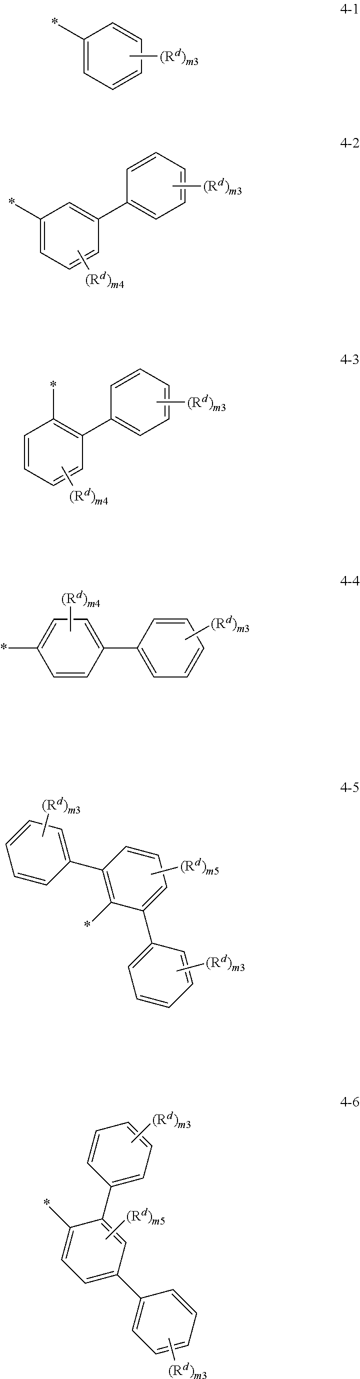 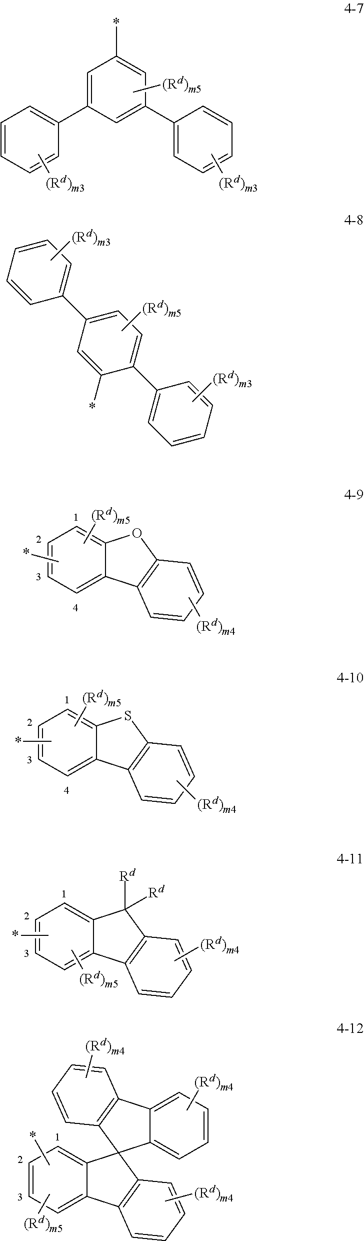
wherein, in Chemical Formulae 4-1 to 4-12, a plurality of m3 are the same as or different from each other and are each independently an integer of 0 to 5,
a plurality of m4 are the same as or different from each other and are each independently an integer of 0 to 4,
a plurality of m5 are the same as or different from each other and are each independently an integer of 0 to 3,
a single R^{d} is or two or more of R^{d} being the same as or different from each other are each independently hydrogen, deuterium, —CD₃, —CD₂H, —CDH₂, —CN, a substituted or unsubstituted C₁-C₁₀ alkyl group, a substituted or unsubstituted C₂-C₁₀ alkenyl group, a substituted or unsubstituted C₃-C₁₀ cycloalkyl group, or a substituted or unsubstituted C₆-C₁₀ aryl group,
when a plurality of R^{d} is included, two adjacent ones selected from among the plurality of R^{d} are optionally combined with each other to form a saturated or unsaturated ring, and
*- binding site in Chemical Formulae 4-9 to 4-11 is one selected from among carbons designated as the numbers of 1 to 4, and *- binding site in Chemical Formula 4-12 is one selected from among carbons designated as the numbers of 1 to 3.

12. The polycyclic compound as claimed in claim 1, wherein K_{RISC} of the polycyclic compound is 1.00×10⁵ s⁻¹ or more.

13. The polycyclic compound as claimed in claim 1, wherein an oscillator intensity (f) of the polycyclic compound is 0.36 or greater, and ΔE_{ST} of the polycyclic compound is 0.39 eV or less.

14. A light-emitting device, comprising:
a first electrode;
a second electrode; and
an emission layer provided between the first electrode and the second electrode and comprising a polycyclic compound represented by Chemical Formula 1: 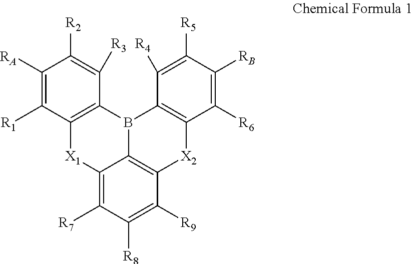
wherein, in Chemical Formula 1, X₁ and X₂ are each independently N(R₁₀), S, O, or Se,
R₁ to R₁₀ are each independently hydrogen, deuterium, a hydroxyl group, a cyano group, —F, —Cl, —Br, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₆-C₆₀ arylalkyl group, a substituted or unsubstituted C₂-C₆₀ heteroaryl group, a substituted or unsubstituted C₂-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group,
two or more adjacent groups selected from among R₁ to R₉ are optionally combined with each other to form a saturated ring or an unsaturated ring,
R_{A} and R_{B} are the same as or different from each other and are each independently a substituted or unsubstituted carbazole group, and
at least one selected from R_{A} and R_{B} is selected from the group consisting of carbazole groups having a structure in which an alicyclic hydrocarbon ring group is condensed to one or two of two six-membered benzene rings fused at both sides of one five-membered nitrogen-containing ring of the carbazole group.

15. The light-emitting device as claimed in claim 14, further comprising a charge generation layer between the first electrode and the second electrode,
wherein the emission layer further comprises a plurality of emission layers, and the charge generation layer is between adjacent emission layers,
wherein at least one selected from among the plurality of emission layers comprises the polycyclic compound of Chemical Formula 1.

16. The light-emitting device as claimed in claim 14, wherein the polycyclic compound is included as a thermally activated delayed fluorescence (TADF) dopant, a host for a phosphorescent device, or a fluorescent host.

17. The light-emitting device as claimed in claim 14, wherein the emission layer has a maximum emission central wavelength in a range from 440 nm to 490 nm.

18. The light-emitting device as claimed in claim 14, wherein R_{A} is represented by Chemical Formula 2-1, and R_{B} is represented by Chemical Formula 2-2: 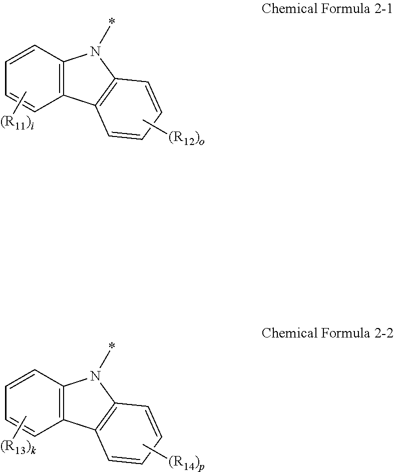
wherein, in Chemical Formulae 2-1 and 2-2, R₁₁ to R₁₄ are the same as or different from each other and are each independently hydrogen, deuterium, —F, —Cl, —Br, —CD₃, —CD₂H, —CDH₂, —CF₃, —CF₂H, —CFH₂, a substituted or unsubstituted C₁-C₆₀ alkyl group, a substituted or unsubstituted C₃-C₆₀ cycloalkyl group, a substituted or unsubstituted C₆-C₆₀ arylalkyl group, a substituted or unsubstituted C₂-C₆₀ heteroarylalkyl group, or a substituted or unsubstituted silyl group, and
i, o, k, and p are each independently an integer of 0 to 4,
wherein two or more adjacent R₁₁ are optionally combined with each other to form an alicyclic hydrocarbon ring group,
two or more adjacent R₁₂ are optionally combined with each other to form an alicyclic hydrocarbon ring group,
two or more adjacent R₁₃ are optionally combined with each other to form an alicyclic hydrocarbon ring group, and
two or more adjacent R₁₄ are optionally combined with each other to form an alicyclic hydrocarbon ring group,
wherein R_{A} comprises at least one selected from the alicyclic hydrocarbon ring group formed by two or more R₁₁ and the alicyclic hydrocarbon ring group formed by two or more R₁₂; R_{B} comprises at least one selected from the alicyclic hydrocarbon ring group formed by two or more R₁₃ and the alicyclic hydrocarbon ring group formed by two or more R₁₄; or R_{A} comprises at least one selected from the alicyclic hydrocarbon ring group formed by two or more R₁₁ and the alicyclic hydrocarbon ring group formed by two or more R₁₂, and R_{B} comprises at least one selected from the alicyclic hydrocarbon ring group formed by two or more R₁₃ and the alicyclic hydrocarbon ring group formed by two or more R₁₄.

19. (canceled)

20. An electronic apparatus comprising the light-emitting device as claimed in claim 14, wherein the electronic apparatus is one selected from among a flat panel display, a curved display, a computer monitor, a medical monitor, a television, a billboard, a light for indoor lighting, a light for outdoor lighting, a light for signals, a head-up display, a fully transparent display, a partially transparent display, a flexible display, a rollable display, a foldable display, a stretchable display, a laser printer, a phone, a mobile phone, a tablet, a phablet, a personal information terminal, a personal digital assistant (PDA), a wearable device, a laptop computer, a digital camera, a camcorder, a viewfinder, a micro display, a 3D display, a virtual reality display, an augmented reality display, a vehicle, a video wall comprising two or more displays tiled together, a theater screen, a stadium screen, a phototherapy device, and a signboard.
